(19) United States
(12) Patent Application Publication
(10) Pub. No.: US 2014/0103270 A1
(43) Pub. Date: Apr. 17, 2014

(54) RADIATION-SENSITIVE COMPOSITION, METHOD FOR FORMING PATTERN, COLOR FILTER AND METHOD OF PRODUCING THE SAME, AND SOLID-STATE IMAGE SENSOR

(71) Applicant: FUJIFILM Corporation, Tokyo (JP)

(72) Inventor: Kazuya OOTA, Shizuoka (JP)

(73) Assignee: FUJIFILM Corporation, Tokyo (JP)

(21) Appl. No.: 14/134,877

(22) Filed: Dec. 19, 2013

Related U.S. Application Data
(63) Continuation of application No. PCT/JP2012/068743, filed on Jul. 18, 2012.

(30) Foreign Application Priority Data
Aug. 31, 2011 (JP) 2011-189550
May 18, 2012 (JP) 2012-114292

(51) Int. Cl. G02B 1/04; G03F 7/00

(52) U.S. Cl. CPC G02B 1/04; G03F 7/0007
USPC 252/586; 430/7

(57) ABSTRACT

The invention provides a radiation-sensitive composition for forming pixels for a solid-state image sensor, the radiation-sensitive composition comprising: titanium dioxide particles;
an oligoimine dispersant including a nitrogen atom in at least one of a main chain or a side chain; a polymerizable compound; a photopolymerization initiator; and an organic solvent.

### CROSS-REFERENCE TO RELATED APPLICATIONS

This application is a continuation application of International Application No. PCT/JP/2012/068743, filed Jul. 18, 2012, the disclosure of which is incorporated herein by reference in its entirety. Further, this application claims priority from Japanese Patent Application No. 2011-189550, filed Aug. 31, 2011, and Japanese Patent Application No. 2012-114292, filed May 18, 2012, the disclosures of which are incorporated herein by reference in their entirety.

### BACKGROUND OF THE INVENTION

1. Technical Field

The invention relates to a radiation-sensitive composition, a method of forming a pattern, a color filter and a method of producing the same, and a solid-state image sensor.

2. Background Art

In recent years, with the aim of improving resolution of image sensors (such as CCD and SMOS), miniaturization of pixels for image sensors have developed together with an increase in the number thereof. However, such development also causes decrease in an area of opening portions, thereby lowering sensitivity. Therefore, there is a case in which a white (transparent) color filter is included in color filters of multiple colors (see Japanese Patent Application Laid-Open (JP-A) No. 2007-53153).

Regarding pixels for white (transparent) color filters, use of a photosensitive resin composition including an oxime photopolymerization initiator, an ultraviolet absorber, and a specific monomer such as a monomer having an aromatic ring or a monomer having a hydrogen bond has been proposed. It has been reported that pixels formed from the photosensitive resin composition exhibit excellent resolution even if a pattern is formed with a low amount of exposure, and that the pattern shape does not deteriorate during post baking (see JP-A No. 2010-49029 and JP-A No. 2010-78729).

Further, a photosensitive resin composition that can be used in solid-state image sensors and can form a fine pattern that is highly transparent due to a high refraction index has been proposed. The photosensitive resin composition includes titanium dioxide particles, a graft copolymer having a specific structure, a polymerizable compound, a polymerization initiator and a solvent (see JP-A No. 2011-127096).

### SUMMARY OF THE INVENTION

However, a transparent resin layer, which is used for pixels for white filters for image sensors (hereinafter, also referred to as solid-state image sensors), may have a problem in that it may be colored with a colorant such as a pigment included in colored pixels positioned adjacent to the transparent resin layer by thermal diffusion in a heated environment. In addition, a radiation-sensitive composition for forming a transparent resin layer is required to be free of generation of impurities over time and highly stable during storage.

The invention has been made in view of the circumstances as set forth above, and aims to provide a radiation-sensitive composition that can form pixels for solid-state image sensors that is highly transparent with a high refraction index, resistant to coloring caused by migration of colorant from adjacent colored pixels by thermal diffusion even under a heated environment, and highly stable during storage.

The invention also aims to provide a color filter that can display a fine and high quality image, a method of forming a pattern suitably used for production of the color filter, and a method of producing a color filter employing the method of forming a pattern.

The invention further aims to provide a solid-state image sensor that exhibits excellent sensitivity properties.

The means for solving the problems as set forth above includes the following.

<1> A radiation-sensitive composition for forming pixels for a solid-state image sensor, the radiation-sensitive composition comprising: titanium dioxide particles; an oligoimine dispersant including a nitrogen atom in at least one of a main chain or a side chain; a polymerizable compound; a photopolymerization initiator; and an organic solvent.

<2> The radiation-sensitive composition according to <1>, wherein the oligoimine dispersant is a dispersing resin that comprises: a repeating unit having a substructure X that has a functional group with a pKa of 14 or less; a side chain comprising an oligomer chain or polymer chain Y that includes from 40 atoms to 10,000 atoms; and a basic nitrogen atom in at least one of a main chain or a side chain of the dispersing resin.

<3> The radiation-sensitive composition according to <1> or <2>, wherein the oligoimine dispersant is a dispersing resin that comprises: a repeating unit that has a basic nitrogen atom that is bound to the substructure X; and a side chain comprising the oligomer chain or polymer chain Y.

<4> The radiation-sensitive composition according to any one of <1> to <3>, wherein the oligoimine dispersant is a dispersing resin that comprises:

(i) a repeating unit having a basic nitrogen atom that is at least one selected from the group consisting of a poly(lower alkyleneimine) repeating unit, a polyallylamine repeating unit, a polydiallylamine repeating unit, a metaxylenediamine-epichlorohydrin polycondensate repeating unit and a polyvinylamine repeating unit, wherein the basic nitrogen atom is bound to the substructure X; and

(ii) a side chain comprising the oligomer chain or polymer chain Y.

<5> The radiation-sensitive composition according to <4>, wherein the oligoimine dispersant is a dispersing resin that comprises:

a repeating unit represented by following Formula (I-1) and a repeating unit represented by following Formula (I-2); or

a repeating unit represented by following Formula (II-1) and a repeating unit represented by following Formula (II-2):

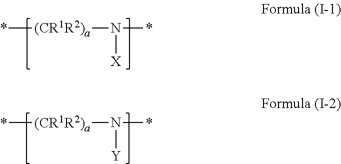

wherein, in Formula (I-1) and Formula (I-2), each of R¹ and R² independently represents a hydrogen atom, a halogen atom or an alkyl group; each “a” independently represents an integer from 1 to 5; * represents a linking moiety between repeating units; X represents a group that has a functional group with a pKa of 14 or less; and Y represents an oligomer chain or polymer chain that includes from 40 atoms to 10,000 atoms:

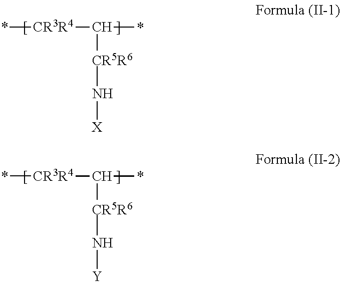

wherein, in Formula (II-1) and Formula (II-2), each of R³, R⁴, R⁵ and R⁶ independently represents a hydrogen atom, a halogen atom or an alkyl group; * represents a linking moiety between repeating units; X represents a group that has a functional group with a pKa of 14 or less; and Y represents an oligomer chain or polymer chain that includes from 40 atoms to 10,000 atoms.

<6> The radiation-sensitive composition according to any one of <1> to <5>, wherein the polymerizable compound is a polymerizable compound having at least two terminal ethylenically unsaturated bonds.

<7> The radiation-sensitive composition according to any one of <1> to <6>, wherein the photopolymerization initiator comprises an oxime compound.

<8> The radiation-sensitive composition according to any one of <1> to <7>, used for forming pixels of a color filter for a solid-state image sensor.

<9> A color filter obtained by using the radiation-sensitive composition according to any one of <1> to <8>.

<10> A method of forming a pattern, the method comprising: forming a coating layer by applying the radiation-sensitive composition according to any one of <1> to <8> onto a substrate; exposing the coating layer to light; and forming a pattern by developing the coating layer that has been exposed, thereby obtaining a cured film having a patterned shape.

<11> A method of producing a color filter, the method comprising forming, on a substrate, a cured film having a patterned shape by the method of forming a pattern according to <10>.

<12> A color filter produced by the method of producing a color filter according to <11>.

<13> A solid-state image sensor comprising the color filter according to <9> or the color filter according to <12>.

According to the invention, it is possible to provide a radiation-sensitive composition that can form pixels for solid-state image sensors that is highly transparent with a high refraction index, resistant to coloring caused by migration of colorant from adjacent colored pixels by thermal diffusion even under a heated environment, and highly stable during storage.

According to the invention, it is possible to provide a color filter that can display a fine and high quality image, a method of forming a pattern suitably used for production of the color filter, and a method of producing a color filter employing the method of forming a pattern.

According to the invention, it is possible to provide a solid-state image sensor that exhibits excellent sensitivity properties.

### DETAILED DESCRIPTION OF THE INVENTION

Radiation-Sensitive Composition

In the following, the radiation-sensitive composition will be explained.

In the specification, groups (atomic groups) that are not described as substituted or unsubstituted include groups not having a substituent and groups having a substituent. For example, “alkyl group” refers to both “unsubstituted alkyl group” and “substituted alkyl group”.

Further, “actinic ray” or “radiation ray” refers to, for example, emission line spectrum of mercury lamps, far-ultraviolet ray represented by excimer laser, extreme ultraviolet (EUV) ray, X ray, electron beam and the like. Further, “light” refers to actinic ray or radiation ray. Unless otherwise specified, “exposure” refers not only to a process using emission line spectrum of mercury lamps, far-ultraviolet ray represented by excimer laser, extreme ultraviolet (EUV) ray or X ray, but also to an imaging process using electron beam, ion beam or the like.

There may be cases in which components of the invention are explained based on representative embodiments, but the invention is not limited to the embodiments.

The numerical range represented by A to B includes A and B as the lowest value and the highest value.

The total solid component of the radiation-sensitive composition refers to the total mass of the components excluding organic solvents.

When plural kinds of substances that correspond to the same component exist in the composition, the amount of the component refers to the total mass of the substances.

In the specification, “(meth)acrylate” refers to acrylate and methacrylate, “(meth)acrylic” refers to acrylic and methacrylic, and “(meth)acryloyl” refers to acryloyl and methacryloyl. In the invention, “monomer” refers to a compound having a weight average molecular weight of 2,000 or less, which is distinguished from an oligomer or a polymer. In the invention, “polymerizable compound” refers to a compound having a polymerizable group, and the polymerizable compound may be a monomer or a polymer. The polymerizable group refers to a group that can be involved in polymerization reaction.

The radiation-sensitive composition according to the invention includes titanium dioxide particles, an oligoimine dispersant that includes a nitrogen atom in at least one of a main chain or a side chain, a polymerizable compound, a photopolymerization initiator, and an organic solvent.

The radiation-sensitive composition can form pixels that is highly transparent with a high refraction index and is resistant to coloring caused by migration of colorant from adjacent colored pixels even in a heated environment. Further, the radiation-sensitive composition exhibits excellent storage stability because generation of impurities is suppressed even after a long period of time. Therefore, the radiation-sensitive composition can be suitably used for pixels of a white filter in color filters of solid-state image sensors.

The mechanism of the invention has not been elucidated, but is presumed as follows.

Specifically, the oligoimine dispersant is highly adsorptive with respect to inorganic particles such as titanium dioxide particles, due to a nitrogen atom included in at least one of a main chain or a side chain thereof, and exhibits excellent dispersion stability. Therefore, it is presumed that the inorganic particles exist in the radiation-sensitive composition in a fine and stable manner as compared with cases in which other dispersants are used. Further, it is presumed that a pattern in which fine inorganic particles are densely packed can be formed, whereby coloring caused by migration of colorant from adjacent colored pixels can be suppressed. Moreover, it is presumed that due to high adsorbability of the oligoimine dispersant to inorganic particles, their state of stable dispersion does not deteriorate, whereby generation of impurities can be suppressed even after a long period of time.

Typically, the radiation-sensitive composition is preferably a negative-type composition (composition that forms a negative pattern).

In the following, the components included in the radiation-sensitive composition will be described.

(A) Titanium Dioxide Particles

The radiation-sensitive composition includes (A) titanium dioxide particles (hereinafter, also simply referred to as “titanium dioxide”).

In the present invention, the titanium dioxide particles may be selected as appropriate from known titanium dioxide particles.

The average primary particle size of the titanium dioxide particles (hereinafter, also simply referred to as “primary particle size”) is preferably from 1 nm to 100 nm, more preferably from 1 nm to 80 nm, particularly preferably from 1 nm to 50 nm.

By controlling the primary particle size of the titanium dioxide particles to be in the above-described range, the refraction index and the transmittance of pixels formed from the radiation-sensitive composition can be further improved.

The average primary particle size of the titanium dioxide particles can be determined from a photograph of titanium dioxide particles in a dispersed state observed with a transmission electron microscope. Specifically, projected areas of the titanium dioxide particles are determined and an average of equivalent circle diameters corresponding to the projected areas is defined as the average primary particle size of the titanium dioxide particles. In the present invention, the average primary particle size is defined as an arithmetic average value of the equivalent circle diameters of 300 titanium dioxide particles.

In the present invention, the refraction index of the titanium dioxide particles is not particularly restricted; however, from the standpoint of attaining a high refraction index, it is preferably from 1.70 to 2.70, more preferably from 1.90 to 2.70.

The specific surface area of the titanium dioxide particles is preferably from 10 m²/g to 400 m²/g, more preferably from 20 m²/g to 200 m²/g, most preferably from 30 m²/g to 150 m²/g.

The shape of the titanium dioxide particles is not particularly restricted, and it may be, for example, riziform, spherical, cubic, spindle-form or irregular-shape.

In the present invention, the titanium dioxide particles may be subjected to a surface treatment with an organic compound. Examples of the organic compound used for the surface treatment of the titanium dioxide particles include polyols, alkanolamines, stearic acid, silane coupling agents and titanate coupling agents. Among these, a silane coupling agent is preferred.

The surface treatment may be performed with a single surface treatment agent, or with two or more surface treatment agents in combination.

It is also preferred that the surfaces of the titanium dioxide particles be coated with an oxide of aluminum, silicon, zirconia or the like. In that case, antiweatherability is further improved.

In the present invention, a commercially available product may be used as the titanium dioxide. Specific examples of the commercially available product include TTO Series (such as TTO-51(A), TTO-51(C) and TTO-55(C)), TTO-S and TTO-V Series (such as TTO-S-1, TTO-S-2 and TTO-V-3) (trade names and manufactured by Ishihara Sangyo Kaisha, Ltd.); and MT Series (such as MT-01 and MT-05) (trade names, manufactured by Tayca Corporation).

In the present invention, the titanium dioxide particles may be used singly or as a combination of two or more kinds.

In the present invention, inorganic particles other than titanium dioxide particles may also be used in combination. Examples of other inorganic particles that may be used in combination include particles of an inorganic oxide such as ZrO₂, SiO₂, BeO, MgO, CaO, SrO, BaO, Sc₂O₃, Y₂O₃, La₂O₃, Ce₂O₃, Gd₂O₃, Tb₂O₃, Dy₂O₃, Yb₂O₃, Lu₂O₃, HfO₂, Nb₂O₅, MoO₃, WO₃, ZnO, B₂O₃, Al₂O₃, GeO₂, SnO₂, PbO, Bi₂O₃ and TeO₂, and complex oxides including these inorganic oxides.

The inorganic particles including titanium dioxide particles may be prepared as a dispersion of inorganic particles including the inorganic particles and a dispersant including the oligoimine dispersant (details will be described later), and the dispersion may be added to the radiation-sensitive composition. In that case, the content of the inorganic particles in the dispersion is preferably from 10% by mass to 50% by mass, more preferably from 15% by mass to 40% by mass, still more preferably from 15% by mass to 35% by mass.

The content of the titanium dioxide particles with respect to total solid components of the radiation-sensitive composition is preferably from 10% by mass to 95% by mass, more preferably from 15% by mass to 90% by mass, still more preferably from 20% by mass to 80% by mass.

(B) Oligoimine Dispersant

The radiation-sensitive composition according to the present invention includes an oligoimine dispersant that includes a nitrogen atom in at least one of a main chain or a side chain.

The oligoimine dispersant is preferably a dispersing resin that includes a repeating unit having a substructure X that has a functional group with a pKa of 14 or less (also referred to as “substructure X”) and a side chain including an oligomer chain or a polymer chain Y that consists of from 40 atoms to 10,000 atoms (also referred to as “oligomer or polymer chain Y”), the dispersing resin also having a basic nitrogen atom in at least one of the main chain or the side chain (hereinafter, also referred to as a “specific dispersing resin (B)”).

The basic nitrogen atom is not particularly restricted, as long as it exhibits basicity. Specific dispersing resin (B) preferably includes a nitrogen atom-containing structure having a pKb of 14 or less, more preferably includes a nitrogen atom-containing structure having a pKb of 10 or less.

In the present invention, the base strength pKb is defined as a pKb measured at a water temperature of 25° C. The base strength pKb is an index that quantitatively indicates the strength of basicity, and is synonymous with a basicity constant. The base strength pKb and the acid strength pKa satisfy the relationship of pKb=14-pKa.

The substructure X in specific dispersing resin (B) has the same definitions as substructure X that will be described later with regard to specific dispersing resin (B1), which is a preferred embodiment of specific dispersing resin (B).

The oligomer or polymer chain Y in a side chain of specific dispersing resin (B) has the same definitions as the oligomer or polymer chain Y that will be described later with regard to specific dispersing resin (B1).

An example of specific dispersing resin (B) is a resin having a structure as described below, which includes a group having a functional group having a pKa of 14 or less, a repeating unit having a basic nitrogen atom, and a repeating unit having an oligomer or polymer chain consisting of from 40 to 10,000 atoms. The repeating units correspond to the following structures in the order of from left to right, respectively.

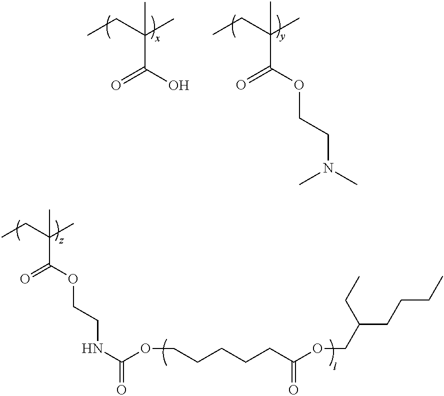

In the above structure, x, y and z represent polymerization molar ratios of the repeating units. A combination in which x is from 5 to 50, y is from 5 to 60 and z is from 10 to 90 is preferred. Further, 1 represents the number of linked polyester chains and is an integer at which an oligomer or polymer chain consisting of from 40 atoms to 10,000 atoms, preferably from 70 atoms to 2,000 atoms, can be formed.

A preferred embodiment of specific dispersing resin (B) is a dispersing resin including a repeating unit having a basic nitrogen atom that is bound to a substructure X as described above, and a side chain including an oligomer or polymer chain Y as described above.

A more preferred embodiment of specific dispersing resin (B) is a dispersing resin (also referred to as a “specific dispersing resin (B1)”) that includes:

(i) a repeating unit having a basic nitrogen atom, which is at least one selected from a group consisting of a poly(lower alkyleneimine) repeating unit, a polyallylamine repeating unit, a polydiallylamine repeating unit, a metaxylenediamine-epichlorohydrin polycondensate repeating unit and a polyvinylamine repeating unit, and includes a substructure X that is bound to the basic nitrogen atom; and

(ii) a side chain including an oligomer or polymer chain Y.

Repeating Unit (i)

Specific dispersing resin (B1) includes a repeating unit having a basic nitrogen atom, which is at least one selected from a group consisting of a poly(lower alkyleneimine) repeating unit, a polyallylamine repeating unit, a polydiallylamine repeating unit, a metaxylenediamine-epichlorohydrin polycondensate repeating unit and a polyvinylamine repeating unit, and includes the substructure X that is bound to the basic nitrogen atom (also referred to as “repeating unit (i)”). By including repeating unit (i), adsorbability of the dispersing resin to surfaces of titanium dioxide particles can be improved, and interaction among the titanium dioxide particles can be reduced.

The poly(lower alkyleneimine) may have a linear or reticular shape. In the present invention, the “lower alkyleneimine” refers to an alkyleneimine including a C₁-C₅ alkylene chain.

The repeating unit (i) preferably forms a main chain of specific dispersing resin (B1). The number average molecular weight of the main chain, i.e., the number average molecular weight of specific dispersing resin (B1) from which side chains including the oligomer or polymer chain Y are excluded, is preferably from 100 to 10,000, more preferably from 200 to 5,000, most preferably from 300 to 2,000. The number average molecular weight of the main chain can be determined based on the ratio of hydrogen atom integrated values at the terminal group and the main chain as measured by a nuclear magnetic resonance spectroscopic method, or by measuring the molecular weight of an amino group-containing oligomer or polymer that is used as a starting material.

Repeating unit (i) is preferably a poly(lower alkyleneimine) repeating unit or a polyallylamine repeating unit.

Specific dispersing resin (B1) is preferably a dispersing resin that includes a repeating unit represented by the following Formula (I-1) and a repeating unit represented by Formula (I-2), or a dispersing resin that includes a repeating unit represented by Formula (II-1) and a repeating unit represented by Formula (II-2).

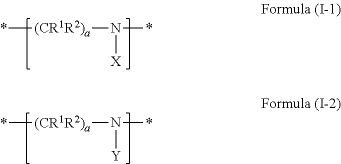

In Formulae (I-1) and (I-2), each of R¹ and R² independently represents a hydrogen atom, a halogen atom or an alkyl group, each of “a” independently represents an integer from 1 to 5, and * represents a linking moiety between repeating units.

X represents a group having a functional group with a pKa of 14 or less.

Y represents an oligomer or polymer chain consisting of from 40 atoms to 10,000 atoms.

Specific dispersing resin (B1) preferably further includes, in addition to the repeating units represented by Formulae (I-1) and (I-2), a repeating unit represented by following Formula (I-3) as a copolymerizable component. By including a repeating unit represented by Formula (I-3), the ability of dispersing of specific dispersing resin (B1) in the radiation-sensitive composition can be further improved.

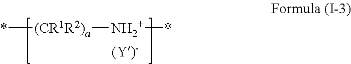

In Formula (I-3), each of R¹, R² and “a” has the same definitions as R¹, R² and “a” in Formula (I-1).

Y′ represents an oligomer chain or a polymer chain that has an anionic group and consists of from 40 from to 10,000 atoms (also referred to as an oligomer or polymer chain Y′).

The repeating unit represented by Formula (I-3) can be formed by adding an oligomer or a polymer, which has a group capable of forming a salt by reaction with an amine, to a resin having a primary or secondary amino group in a main-chain thereof, and allowing the same to react.

In Formulae (I-1), (I-2) and (I-3), R¹ and R² are particularly preferably a hydrogen atom. From the standpoint of availability of the starting material, the integer represented by “a” is preferably 2.

In addition to the repeating units represented by Formulae (I-1), (I-2) and (I-3), specific dispersing resin (B1) may include, as a repeating unit, a lower alkyleneimine including a primary or tertiary amino group. The nitrogen atom in such a lower alkyleneimine repeating unit may be bound to a group represented by X, Y or Y′, as described above. A resin having a main chain structure including both a repeating unit that is bound to a group represented by X and a repeating unit that is bound to Y is also an embodiment of specific dispersing resin (B1).

The repeating unit represented by Formula (I-1) is a repeating unit having a basic nitrogen atom that is bound to the substructure X. From the standpoints of storage stability and developability, specific dispersing resin (B1) preferably includes a repeating unit represented by Formula (I-1) in an amount of from 1 mol % to 80 mol %, more preferably from 3 mol % to 50 mol %, with respect to the total repeating units.

The repeating unit represented by Formula (I-2) has an oligomer or polymer chain Y. From the standpoint of storage stability, the specific dispersing resin (B1) preferably includes a repeating unit represented by Formula (I-2) in an amount of from 10 mol % to 90 mol %, more preferably from 30 mol % to 70 mol %, with respect to the total repeating units.

From the standpoints of dispersion stability and a balance between hydrophilicity and hydrophobicity, the content ratio of repeating unit (I-1) and repeating unit (I-2), represented by (I-1):(I-2) in terms of molar ratio, is preferably from 10:1 to 1:100, more preferably from 1:1 to 1:10.

The repeating unit represented by Formula (I-3), which is optionally included in combination, has a structure in which the oligomer or polymer chain Y′ is ionically bound to the nitrogen atom in the main chain. From the standpoint of achieving an effect derived from a repeating unit represented by Formula (I-3), specific dispersing resin (B1) preferably includes a repeating unit represented by Formula (I-3) in an amount of from 0.5 mol % to 20 mol %, more preferably from 1 mol % to 10 mol %, with respect to the total repeating units.

Whether or not the oligomer or polymer chain Y′ is ionically bound to the nitrogen atom can be verified by infrared spectroscopy or base titration.

In the following repeating units represented by Formulae (II-1) and (II-2) will be described in detail.

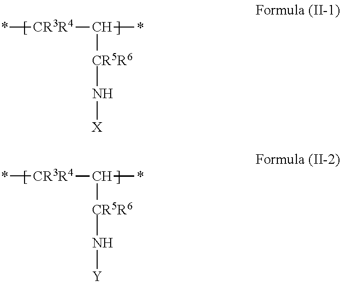

In Formulae (II-1) and (II-2), R³, R⁴, R⁵ and R⁶ each independently represent a hydrogen atom, a halogen atom or an alkyl group, and *, X and Y have the same definitions as *, X and Y in Formulae (I-1) and (I-2).

Specific dispersing resin (B1) preferably further includes, in addition to the repeating units represented by Formulae (II-1) and (II-2), a repeating unit represented by the following Formula (II-3) as a copolymerizable component. By including a repeating unit represented by Formula (II-3) in combination, the ability of dispersing of specific dispersing resin (B) in the radiation-sensitive composition can be further improved.

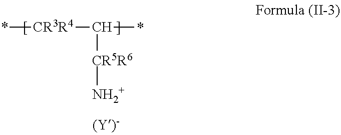

In Formula (II-3), R³, R⁴, R⁵ and R⁶ have the same definitions as R³, R⁴, R⁵ and R⁶ in Formula (II-1). Y′ have the same definitions as Y′ in Formula (I-3).

In Formulae (II-1), (II-2) and (II-3), from the standpoint of availability of a starting material, R³, R⁴, R⁵ and R⁶ are preferably a hydrogen atom.

The repeating unit represented by Formula (II-1) has a basic nitrogen atom bound to the substructure X. From the standpoints of storage stability and developability, specific dispersing resin (B1) preferably includes a repeating unit represented by (II-1) in an amount of preferably from 1 mol % to 80 mol %, most preferably from 3 mol % to 50 mol %, with respect to the total repeating units.

Formula (II-2) represents a repeating unit which has oligomer or polymer chain Y. From the standpoint of storage stability, specific dispersing resin (B1) preferably includes a repeating unit represented by (II-2) in an amount of from 10 mol % to 90 mol %, most preferably from 30 mol % to 70 mol %, with respect to the total repeating units.

From the standpoints of dispersion stability and a balance between hydrophilicity and hydrophobicity, the content ratio of repeating unit (II-1) and repeating unit (II-2), represented by (II-1):(II-2) in terms of molar ratio, is preferably from 10:1 to 1:100, more preferably from 1:1 to 1:10.

The repeating unit represented by Formula (II-3), which is optionally included in combination, is preferably included in an amount of from 0.5 mol % to 20 mol %, more preferably from 1 mol % to 10 mol %, with respect to the total repeating units of specific dispersing resin (B1).

From the standpoint of dispersibility, specific dispersing resin (B1) particularly preferably includes a repeating unit represented by Formula (I-1) and a repeating unit represented by Formula (I-2).

<Substructure X>

The substructure X has a functional group with a pKa of 14 or less at a water temperature of 25° C. The term “pKa” used herein is based on a definition described in Chemical Handbook (Kagaku Binran) (II) (revised 4th edition, 1993, edited by the Chemical Society of Japan, Maruzen Publishing Co., Ltd.)

The structure or the like of the functional group with a pKa of 14 or less is not particularly restricted, as long as it satisfies a pKa as specified. Examples of the functional group include known ones with a pKa is 14 or less, and a functional group having a pKa of 12 or less is preferred and a functional group having a pKa of 11 or less is more preferred. Specific examples of the functional group with a pKa of 14 or less include a carboxylic group (pKa: about 3 to 5), a sulfonic group (pKa: about −3 to −2), —COCH₂CO— (pKa: about 8 to 10), —COCH₂CN (pKa: about 8 to 11), —CONHCO—, a phenolic hydroxyl group, —R_{F}CH₂OH or —(R_{F})₂CHOH (R_{F} represents a perfluoroalkyl group, pKa: about 9 to 11) and a sulfonamide group (pKa: about 9 to 11). Among these, a carboxylic group (pKa: about 3 to 5), a sulfonic group (pKa: about −3 to −2) and —COCH₂CO— (pKa: about 8 to 10) are particularly preferred.

By including a functional group with a pKa of 14 or less in the substructure X, satisfactory interaction with titanium dioxide particles can be attained.

The substructure X is preferably directly bound to the basic nitrogen atom of the repeating unit as described above. The nitrogen atom in the repeating unit and the substructure X may be bound via a covalent bond, or via an ionic bond by forming a salt.

Preferred examples of substructure X include those having a structure represented by any one of the following Formulae (V-1), (V-2) and (V-3).

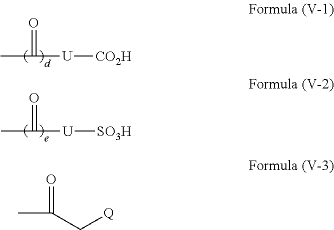

In Formulae (V-1) and (V-2), U represents a single bond or a divalent linking group, “d” and “e” independently represent 0 or 1.

In Formula (V-3), Q represents an acyl group or an alkoxycarbonyl group.

Examples of the divalent linking group represented by U include an alkylene group (more specifically, for example, —CH₂—, —CH₂CH₂—, —CH₂CHMe—, —(CH₂)₅— and —CH₂CH(n-C₁₀H₂₁)—), an oxygen-containing alkylene group (more specifically, for example, —CH₂OCH₂— and —CH₂CH₂OCH₂CH₂—), an arylene group (such as phenylene, tolylene, biphenylene, naphthylene, furanylene and pyrrolylene) and an alkyleneoxy group (such as ethyleneoxy, propyleneoxy and phenyleneoxy). The divalent linking group represented by U is preferably a C₁-C₃₀ alkylene group or a C₆-C₂₀ arylene group, more preferably a C₁-C₂₀ alkylene group or a C₆-C₁₅ arylene group. From the standpoint of productivity, “d” is preferably 1 and e is preferably 0.

Q represents an acyl group or an alkoxycarbonyl group. The acyl group represented by Q is preferably a C₁-C₃₀ acyl group (such as formyl, acetyl, n-propanoyl or benzoyl), more preferably an acetyl group. The alkoxycarbonyl group represented by Q is preferably an acyl group, and from the standpoints of ease of production and availability of a starting material (X′ as a precursor for X), an acetyl group is preferred.

In the present invention, the substructure X is preferably bound to the basic nitrogen atom of the repeating unit having a basic nitrogen atom. In that case, dispersibility and dispersion stability of titanium dioxide particles are significantly improved. Although the reason has not been elucidated, it is considered that the substructure X functions as an acid radical and is thus capable of interacting with the metal atom (Ti) of the titanium dioxide particles, whereby adsorbability to the titanium dioxide particles is improved, and dispersibility and storage stability are significantly improved.

In addition, it is considered that the substructure X also imparts solubility with respect to a solvent, whereby precipitation of the resin with time is suppressed, thereby contributing to improvement in dispersion stability.

Further, since the substructure X includes a functional group of not higher than 14 in pKa, it also functions as an alkali-soluble group. By this, it is considered that, when energy is applied to partially cure a coating film formed by the radiation-sensitive composition according to the present invention and the unexposed region is dissolved and removed to form a pattern, the developing property of the uncured region to an alkali developer is improved, and satisfactory dispersion properties, dispersion stability and developing property can be attained at the same time.

The content of the functional group with a pKa of 14 or less in the substructure X it not particularly restricted, but it is preferably from 0.01 mmol to 5 mmol, more preferably from 0.05 mmol to 1 mmol, with respect to 1 g of specific dispersing resin (B1). In that case, dispersibility and dispersion stability of titanium dioxide particles are improved, and developability of uncured portions can be improved when forming a cured film from the radiation-sensitive composition. Further, from the standpoint of the developability during formation of a cured film with the radiation-sensitive composition, the functional group with a pKa of 14 or less is preferably included by such an amount that the acid value of specific dispersing resin (B1) is from about 5 mg KOH/g to about 50 mg KOH/g.

Oligomer or Polymer Chain Y

In the following, an oligomer or polymer chain Y consisting of from 40 atoms to 10,000 atoms will be described.

Examples of the oligomer or polymer chain Y include known polymer chains capable of linking to the main chain of specific dispersing resin (B1), such as polyester, polyamide, polyimide and poly(meth)acrylate. The binding site of the oligomer or polymer chain Y with specific dispersing resin (B1) is preferably a terminal of oligomer or polymer chain Y.

The oligomer or polymer chain Y is preferably bound to a nitrogen atom of a repeating unit that is at least one selected from the group consisting of a poly(lower alkyleneimine) repeating unit, a polyallylamine repeating unit, a polydiallylamine repeating unit, a metaxylenediamine-epichlorohydrin polycondensate repeating unit and a polyvinylamine repeating unit. The oligomer or polymer chain Y is bound to the main chain via a covalent bond, an ionic bond or a combination thereof. The ratio of type of binding of the oligomer or polymer chain Y to the main chain (covalent bond: ionic bond) is from 100:0 to 0:100, preferably from 95:5 to 5:95, most preferably from 90:10 to 10:90. When the ratio is not within this range, dispersibility and dispersion stability may be impaired and solvent solubility may be lowered.

It is preferred that the oligomer or polymer chain Y be bound to the main chain of the repeating unit having a basic nitrogen atom via an amide bond, or via an ionic bond by forming a carboxylic acid salt.

From the standpoints of dispersibility, dispersion stability and developability, the number of atoms in the oligomer or polymer chain Y is preferably from 50 to 5,000, more preferably from 60 to 3,000.

When the number of atoms per oligomer or polymer chain Y is less than 40, the length of a graft chain is too short and an effect of steric repulsion may be too small, whereby dispersibility may be lowered. When the number of atoms per oligomer or polymer chain Y is greater than 10,000, the length of oligomer or polymer chain is too long, whereby adsorbability to the titanium dioxide particles may be lowered and dispersibility may be lowered.

The number average molecular weight of the oligomer or polymer chain Y can be determined by a GPC method based on polystyrene standard. The number average molecular weight of the oligomer or polymer chain Y is preferably from 1,000 to 50,000, and from the standpoints of dispersibility, dispersion stability and developability, the number average molecular weight is more preferably from 1,000 to 30,000.

The side chain structure represented by Y is linked to the main chain series in the number of preferably not less than 2, most preferably not less than 5, per molecule of the resin.

In particular, oligomer or polymer chain Y preferably has a structure represented by following Formula (III-1).

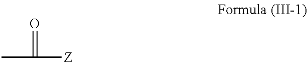

In Formula (III-1), Z represents a polymer or an oligomer having a polyester chain as a substructure, which is a residue having a structure in which a carboxyl group is excluded from a polyester having a free carboxylic acid represented by following Formula (IV).

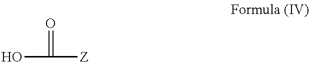

In Formula (IV), Z has the same definition as Z in Formula (III-1). In a case in which specific dispersing resin (B1) includes a repeating unit represented by Formula (I-3) or Formula (II-3), Y′ is preferably represented by following Formula (III-2).

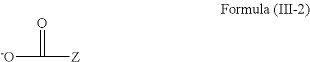

In Formula (III-2), Z has the same definition as Z in Formula (III-1).

A polyester having a carboxyl group at only one of terminals (polyester represented by Formula (IV)) can be obtained by, for example, (IV-1) polycondensation of a carboxylic acid and a lactone; (IV-2) polycondensation of a hydroxyl group-containing carboxylic acid; or (IV-3) polycondensation of a dihydric alcohol and a divalent carboxylic acid (or a cyclic acid anhydride).

Examples of the carboxylic acid used in (IV-1) polycondensation reaction of a carboxylic acid and a lactone include an aliphatic carboxylic acid (preferably a C₁-C₃₀ linear or branched carboxylic acid, such as formic acid, acetic acid, propionic acid, butyric acid, valeric acid, n-hexanoic acid, n-octanoic acid, n-decanoic acid, n-dodecanoic acid, palmitic acid, 2-ethylhexanoic acid or a cyclohexanoic acid); and a hydroxyl group-containing carboxylic acid (preferably a C₁-C₃₀ linear or branched hydroxyl group-containing carboxylic acid, such as glycolic acid, lactic acid, 3-hydroxypropionic acid, 4-hydroxydodecanoic acid, 5-hydroxydodecanoic acid, ricinoleic acid, 12-hydroxydodecanoic acid, 12-hydroxystearic acid or 2,2-bis(hydroxymethyl)butyric acid). Among these, a C₆-C₂₀ linear aliphatic carboxylic acid or a C₁-C₂₀ hydroxyl group-containing carboxylic acid is preferred. The carboxylic acid may be used in a combination of two or more kinds.

The lactone may be selected from known lactones, and examples thereof include β-propiolactone, β-butyrolactone, γ-butyrolactone, γ-hexanolactone, γ-octanolactone, δ-valerolactone, δ-hexanolactone, δ-octanolactone, ε-caprolactone, δ-dodecanolactone and α-methyl-γ-butyrolactone. From the standpoints of reactivity and availability, ε-caprolactone is preferred. The lactone may be used in a combination of two or more kinds.

The ratio of carboxylic acid to lactone for reaction depends on the intended molecular weight of the polyester chain and may not be determined to a specific ratio. However, the ratio of carboxylic acid to lactone (carboxylic acid:lactone) is preferably from 1:1 to 1:1,000, more preferably from 1:3 to 1:500.

The hydroxyl group-containing carboxylic acid used in (IV-2) polycondensation of a hydroxyl group-containing carboxylic acid may be selected from the examples as described in (IV-1), and preferred examples are also the same.

Examples of the dihydric alcohol used in (IV-3) polycondensation reaction of a dihydric alcohol and a divalent carboxylic acid (or a cyclic acid anhydride) include linear or branched aliphatic diols (preferably a C₂-C₃₀ diol, such as ethylene glycol, diethylene glycol, triethylene glycol, dipropylene glycol, 1,2-propanediol, 1,3-propanediol, 1,5-pentanediol, 1,6-hexanediol or 1,8-octanediol), and a C₂-C₂₀ aliphatic diol is preferred.

Examples of the divalent carboxylic acid include linear or branched divalent aliphatic carboxylic acids (preferably a C₁-C₃₀ divalent aliphatic carboxylic acid, such as succinic acid, maleic acid, adipic acid, sebacic acid, dodecanedioic acid, glutaric acid, suberic acid, tartaric acid, oxalic acid or malonic acid), and a C₃-C₂₀ divalent carboxylic acid is preferred. It is also possible to use an acid anhydride that is equivalent to the divalent carboxylic acids (such as succinic anhydride or glutaric anhydride).

The molar ratio of a divalent carboxylic acid to a dihydric alcohol for reaction is preferably 1:1. In that case, a carboxylic acid can be introduced to only one of the terminals.

The polycondensation in the polyester production is preferably performed with an addition of a catalyst. The catalyst is preferably selected from catalysts that function as a Lewis acid, and examples thereof include a Ti compound (such as Ti(OBu)₄ and Ti(O-Pr)₄), a Sn compound (such as tin octylate, dibutyltin oxide, dibutyltin laurate, monobutyltin hydroxybutyloxide and stannic chloride) and a protonic acid (such as sulfuric acid and p-toluenesulfonic acid). The amount of the catalyst is preferably from 0.01 mol % to 10 mol %, more preferably from 0.1 mol % to 5 mol %, with respect to the number of moles of the total monomers. The reaction temperature is preferably from 80° C. to 250° C., more preferably from 100° C. to 180° C. The reaction time depends on the reaction conditions, and is generally from 1 hour to 24 hours.

The number average molecular weight of the resulting polyester can be determined by a GPC method based on polystyrene standard. The number average molecular weight of the polyester is generally from 1,000 to 1,000,000, preferably from 2,000 to 100,000, more preferably from 3,000 to 50,000. When the molecular weight is within the range, satisfactory dispersibility and developability can be attained at the same time.

From the standpoint of ease of production, the polyester substructure that forms a polymer chain in Y is particularly preferably a polyester obtained by (IV-1) polycondensation of a carboxylic acid and a lactone or (IV-2) polycondensation of a hydroxyl group-containing carboxylic acid.

The following are specific embodiments (A-1) to (A-60) of specific dispersing resin (B) including specific dispersing resin (B1) represented by specific structures of repeating units contained in the resin and combinations thereof. However, the present invention is not restricted to these embodiments. In the following structures, k, l, m and n each represent the polymerization molar ratio of the respective repeating units, in which k is from 1 to 80, 1 is from 10 to 90, m is from 0 to 80, n is from 0 to 70, and k+1+m+n=100. In the following structures, p and q each independently represent the number of linked polyester chains, which is from 5 to 100,000. R′ represents a hydrogen atom or an alkoxycarbonyl group.

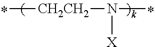

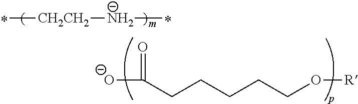

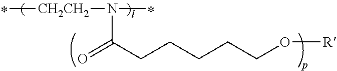

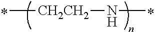

| | X |
|---|---|
| (A-1) | 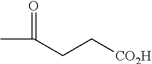 |
| (A-2) | 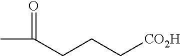 |
| (A-3) | 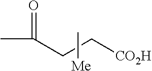 |
| (A-4) | 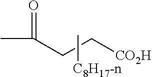 |
| (A-5) | 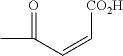 |
| (A-6) | 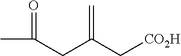 |
| (A-7) | 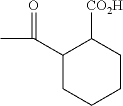 |
| (A-8) | 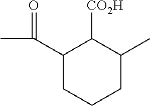 |
| (A-9) | 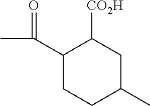 |
| (A-10) | 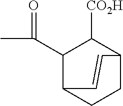 |
| (A-11) | 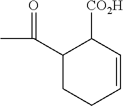 |
| (A-12) | 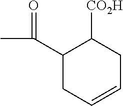 |
| (A-13) | 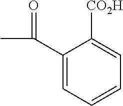 |
| (A-14) | 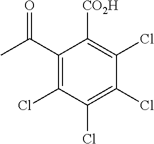 |
| (A-15) | 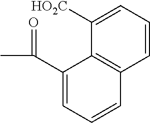 |

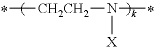

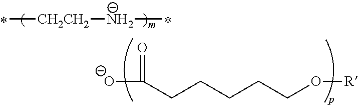

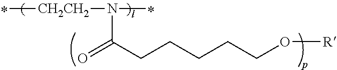

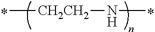

| | X |
|---|---|
| (A-16) | 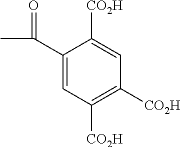 |
| (A-17) | 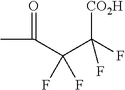 |
| (A-18) | 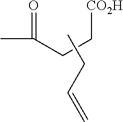 |
| (A-19) | 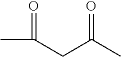 |
| (A-20) | 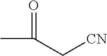 |
| (A-21) | 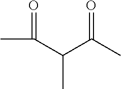 |
| (A-22) | 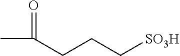 |
| (A-23) | 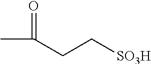 |
| (A-24) | 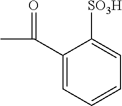 |
| (A-25) | —CH₂CO₂H |
| (A-26) | —CH₂CH₂CO₂H |
| (A-27) | 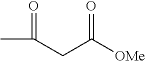 |
| (A-28) | 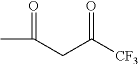 |

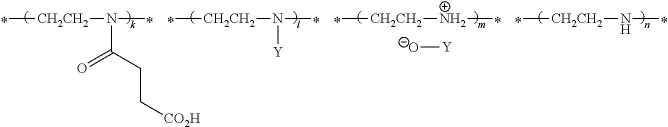

| | Y |
|---|---|
| (A-29) | 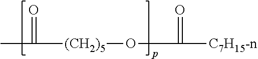 |
| (A-30) | 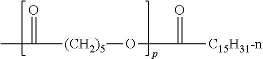 |
| (A-31) | 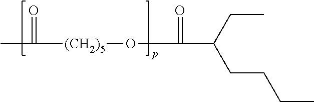 |
| (A-32) | 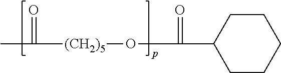 |
| (A-33) | 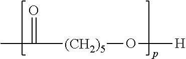 |
| (A-34) | 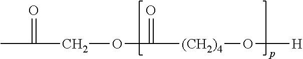 |
| (A-35) | 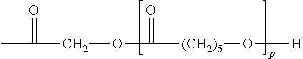 |

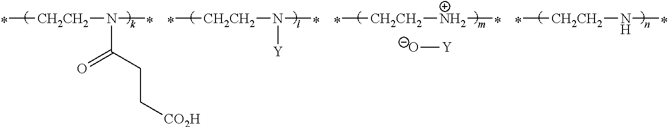

| | Y |
|---|---|
| (A-36) | 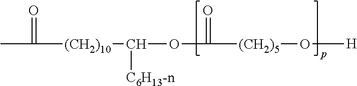 |
| (A-37) | 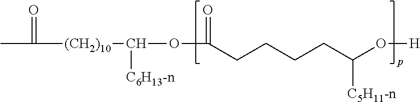 |
| (A-38) | 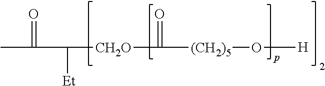 |
| (A-39) | 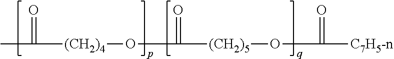 |
| (A-40) | 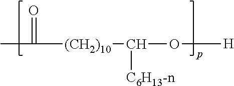 |
| (A-41) | 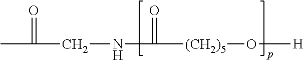 |
| (A-42) | 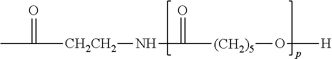 |

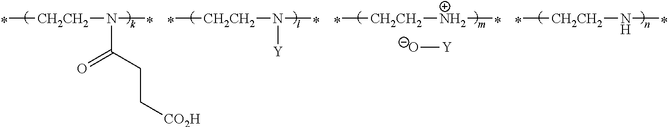

| | Y |
|---|---|
| (A-43) | 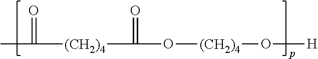 |
| (A-44) | 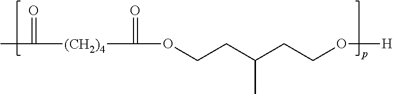 |
| (A-45) | 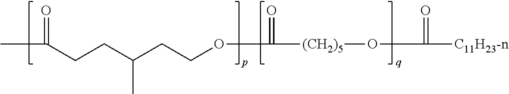 |
| (A-46) | 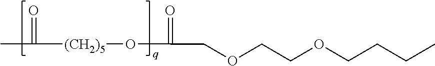 |

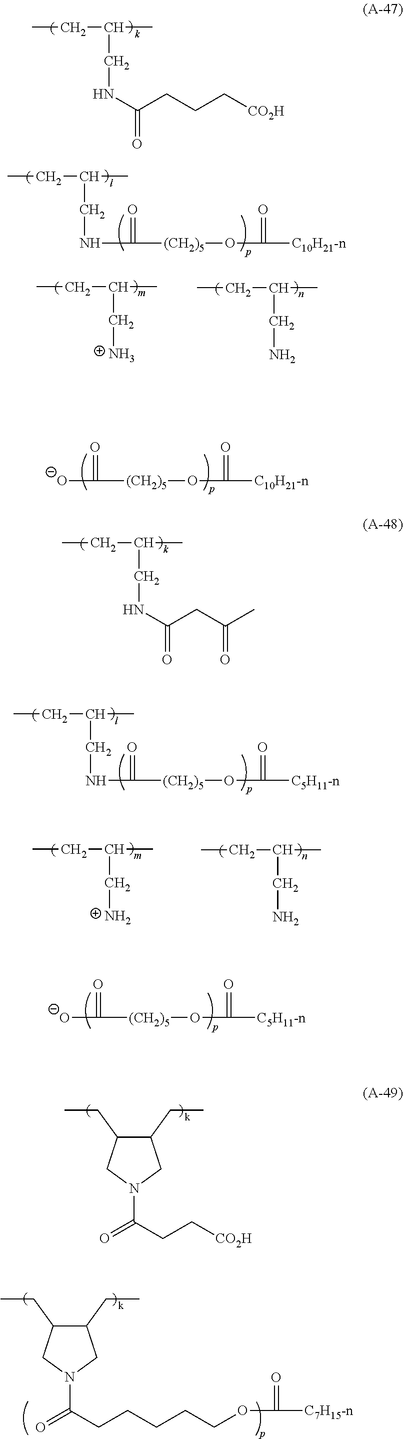

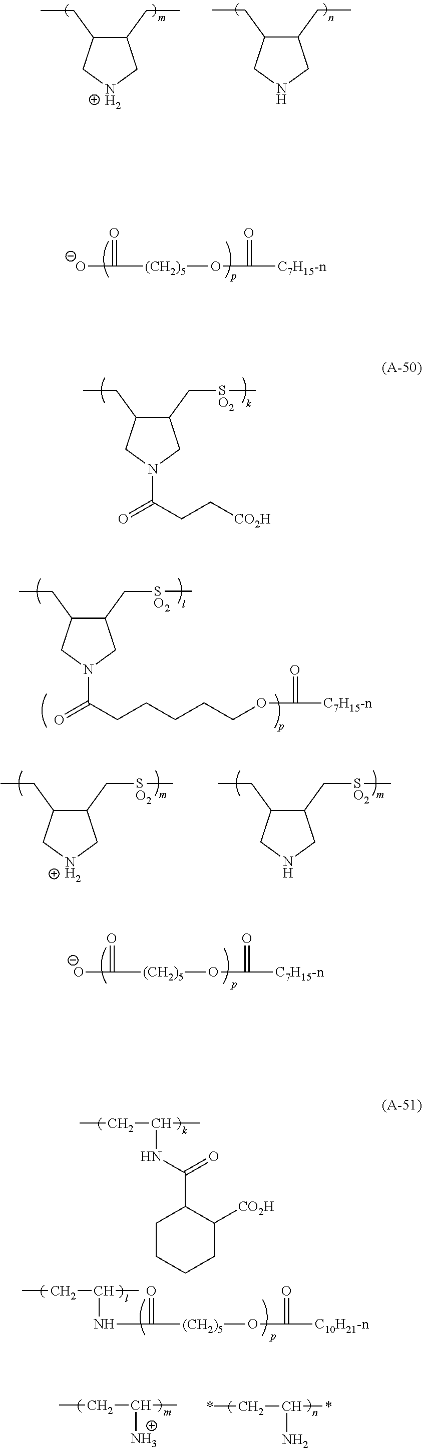

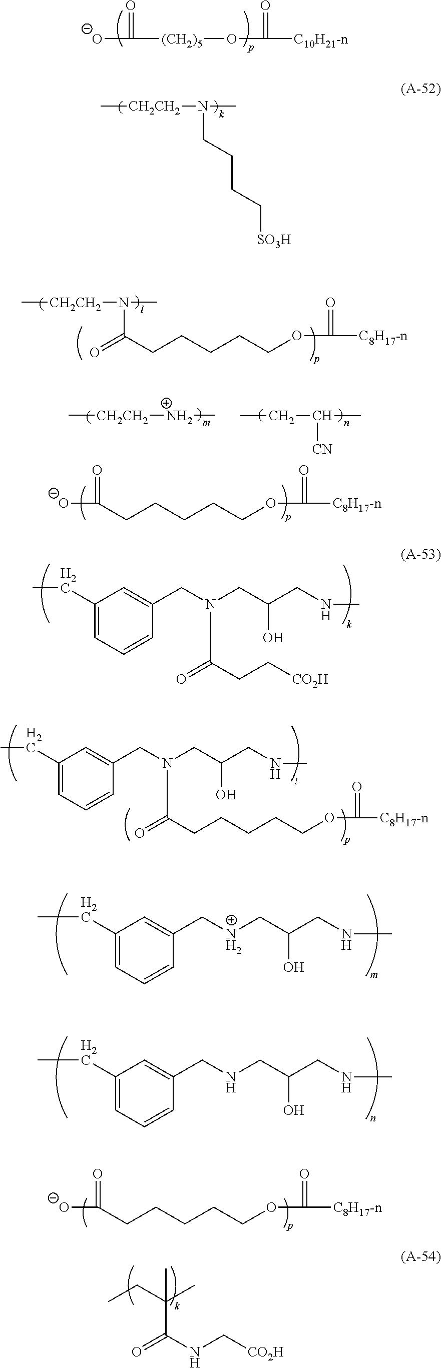

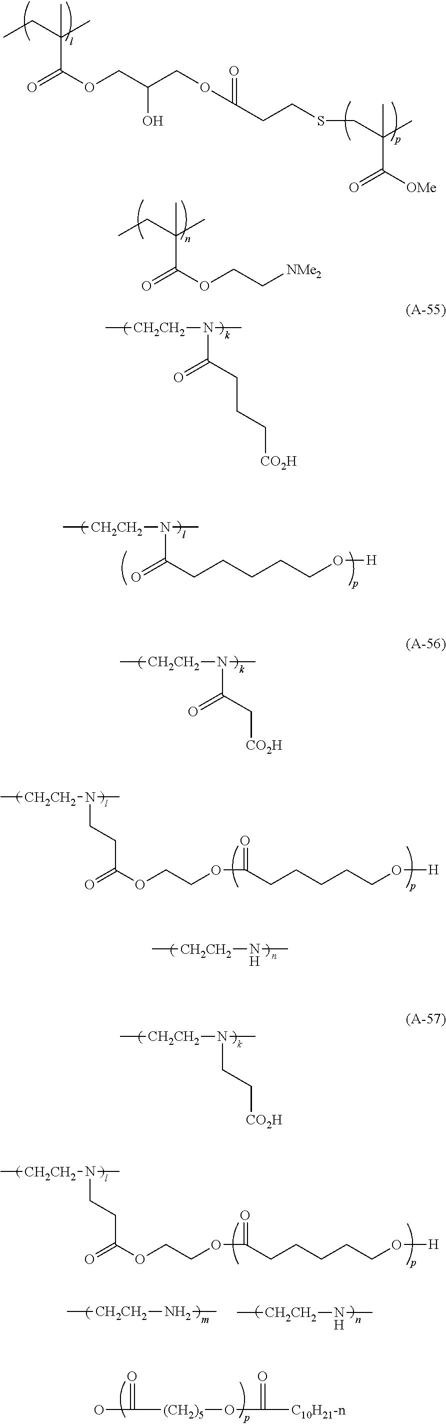

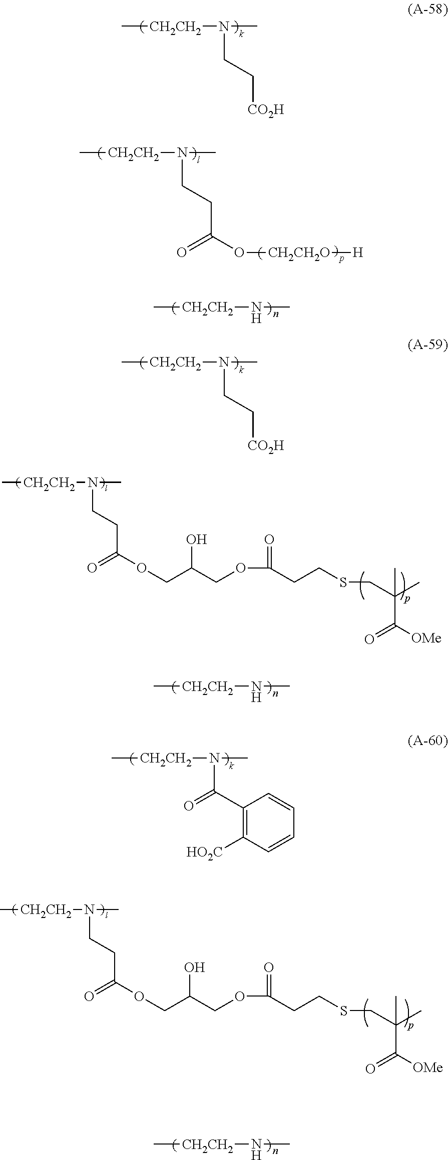

Specific dispersing resin (B1) can be synthesized by, for example, (1) a method in which a resin having a primary or secondary amino group, precursor x for substructure X and precursor y for the oligomer or polymer chain Y are allowed to react; or (2) a method of polymerizing a monomer including a structure corresponding to substructure X and a macromonomer having a structure corresponding to the oligomer or polymer chain Y.

Preferably, specific dispersing resin (B1) is produced by synthesizing a resin having a primary or secondary amino group in the main chain, and subsequently allowing the resin to react with precursor x and precursor y thereby introducing the same to the nitrogen atom in the main chain by polymer reaction.

Examples of the resin having a primary or secondary amino group include oligomers and polymers that include a primary or secondary amino group that can constitute the main chain having a nitrogen atom, such as poly(lower alkyleneimine), polyallylamine, polydiallylamine, metaxylenediamine-epichlorohydrin polycondensates and polyvinylamines. Among these, poly(lower alkyleneimine) and an oligomer or a polymer formed from polyallylamine are preferred.

Precursor x for substructure X is a compound capable of reacting with a resin having a primary or secondary amino group, as described above, thereby introducing substructure X to the main chain.

Examples of precursor x include cyclic carboxylic anhydrides (preferably C₄-C₃₀ cyclic carboxylic anhydrides, such as succinic anhydride, glutaric anhydride, itaconic anhydride, maleic anhydride, allylsuccinic anhydride, butylsuccinic anhydride, n-octyl succinic anhydride, n-decyl succinic anhydride, n-dodecyl succinic anhydride, n-tetradecyl succinic anhydride, n-docosenyl succinic anhydride, (2-hexen-1-yl)succinic anhydride, (2-methylpropen-1-yl)succinic anhydride, (2-dodecen-1-yl)succinic anhydride, n-octenyl succinic anhydride, (2,7-octanedien-1-yl)succinic anhydride, acetylmalic anhydride, diacetyltartaric anhydride, HET anhydride, cyclohexane-1,2-dicarboxylic anhydride, 3- or 4-methylcyclohexane-1,2-dicarboxylic anhydride, tetrafluorosuccinic anhydride, 3- or 4-cyclohexen-1,2-dicarboxylic anhydride, 4-methyl-4-cyclohexen-1,2-dicarboxylic anhydride, phthalic anhydride, tetrachlorophthalic anhydride, naphthalic anhydride, bicyclo[2.2.2]oct-7-ene-2,3,5,6-tetracarboxylic dianhydride, pyromellitic dianhydride, meso-butane-1,2,3,4-tetracarboxylic dianhydride and 1,2,3,4-cyclopentanecarboxylic dianhydride); halogen atom-containing carboxylic acids (such as chloroacetic acid, bromoacetic acid, iodoacetic acid and 4-chloro-n-butyric acid); sultones (such as propane sultone and 1,4-butane sultone); diketenes; cyclic sulfocarboxylic anhydrides (such as 2-sulfobenzoic anhydride); compounds containing —COCH₂COCl (such as ethyl malonyl chloride); and cyanoacetic acid chlorides. From the standpoint of productivity, cyclic carboxylic anhydrides, sultones and diketenes are preferred.

Precursor y for the oligomer or polymer chain Y is a compound capable of reacting with the resin having a primary or secondary amino group as described above, thereby introducing the oligomer or polymer chain Y.

Precursor y is preferably an oligomer or a polymer consisting of from 40 atoms to 10,000 atoms and has a group capable of forming a covalent bond or an ionic bond with the nitrogen atom of specific dispersing resin (B1). Precursor y is more preferably an oligomer or a polymer consisting of from 40 atoms to 10,000 atoms having a free carboxyl group at one of terminals thereof

Examples of precursor y include a polyester having a free carboxylic acid at one of terminals thereof, represented by Formula (IV), a polyamide having a free carboxylic acid at one of terminals thereof, and a poly(meth)acrylate resin having a free carboxylic acid at one of terminals thereof. Among these, a polyester having a free carboxylic group at one of terminals thereof, represented by Formula (IV), is preferred.

Precursor y can be synthesized by a known method. For example, a polyester having a free carboxylic acid group at one of terminals thereof, represented by Formula (IV), can be produced by the methods as mentioned above, i.e., (IV-1) polycondensation of a carboxylic acid and a lactone; (IV-2) polycondensation of a hydroxyl group-containing carboxylic acid; or (IV-3) polycondensation of a dihydric alcohol and a divalent carboxylic acid (or a cyclic acid anhydride). A polyamide having a free carboxylic acid at one of terminals thereof can be produced by, for example, self-condensation of an amino group-containing carboxylic acid (such as glycine, alanine, β-alanine or 2-aminobutyrate). A poly(meth)acrylate having a free carboxylic acid at one of terminals thereof can be produced by radical polymerization of a (meth)acrylic acid monomer in the presence of a carboxyl group-containing chain transfer agent (such as ε-mercaptopropionic acid).

Specific dispersing resin (B1) can be produced by (a) a method in which a resin having a primary or secondary amino group, precursor x and precursor y are allowed to react at the same time; (b) a method in which a resin having a primary or secondary amino group and precursor x are allowed to react, and the resultant is subsequently allowed to react with precursor y; or (c) a method in which a resin having a primary or secondary amino group and precursor y are allowed to react and the resultant is subsequently allowed to react with precursor x. Among these, (c) a method in which a resin having a primary or secondary amino group and precursor y are allowed to react and the resultant is subsequently allowed to react with precursor x is preferred.

The reaction temperature may be selected as appropriate depending on the reaction conditions. However, for example, the temperature is preferably from 20° C. to 200° C., most preferably from 40° C. to 150° C. The reaction time is preferably from 1 hour to 48 hours, more preferably from 1 hour to 24 hours from the standpoint of productivity.

The reaction may be carried out in the presence of a solvent. Examples of the solvent include water, sulfoxide compounds (such as dimethyl sulfoxide), ketone compounds (such as acetone, methyl ethyl ketone and cyclohexanone), ester compounds (such as ethyl acetate, butyl acetate, ethyl propionate and propylene glycol 1-monomethyl ether 2-acetate), ether compounds (such as diethyl ether, dibutyl ether and tetrahydrofuran), aliphatic hydrocarbon compounds (such as pentane and hexane), aromatic hydrocarbon compounds (such as toluene, xylene and mesitylene), nitrile compounds (such as acetonitrile and propionitrile), amide compounds (such as N,N-dimethylformamide, N,N-dimethylacetamide and N-methylpyrrolidone), carboxylic compounds (such as acetic acid and propionic acid), alcohol compounds (such as methanol, ethanol, isopropanol, n-butanol, 3-methylbutanol and 1-methoxy-2-propanol) and halogen solvents (such as chloroform and 1,2-dichloroethane).

In a case in which a solvent is used, the amount thereof is preferably from 0.1 times to 100 times, more preferably from 0.5 times to 10 times, with respect to the mass of the substrate.

Specific dispersing resin (B1) may be purified by a reprecipitation method. By removing components of low molecular weight by a reprecipitation method, the ability of dispersing of specific dispersing resin (B1) used as a dispersant van be improved. When carrying out reprecipitation, it is preferred to use a hydrocarbon solvent such as hexane or an alcohol solvent such as methanol.

Specific dispersing resin (B1), synthesized by a method as described above, preferably has a weight average molecular weight as determined by a GPC method of preferably from 3,000 to 100,000, more preferably from 5,000 to 55,000. When the molecular weight is within the above-described range, there is an advantage in that excellent developability and storage stability can be achieved. Further, the presence of a nitrogen atom in the nitrogen atom-containing repeating unit in specific dispersing resin (B1) can be confirmed by an acidimetric method or the like. The presence of a functional group with a pKa of 14 or less and whether or not the functional group is bound to the nitrogen atom in the repeating unit can be confirmed by a method such as base titration, nuclear magnetic resonance spectroscopy or infrared spectroscopy. Moreover, whether or not the oligomer or polymer chain Y is present in a side chain can be verified by nuclear magnetic resonance spectroscopy, GPC method or the like.

The following are specific examples of specific dispersing resin (B1) and the molecular weight thereof

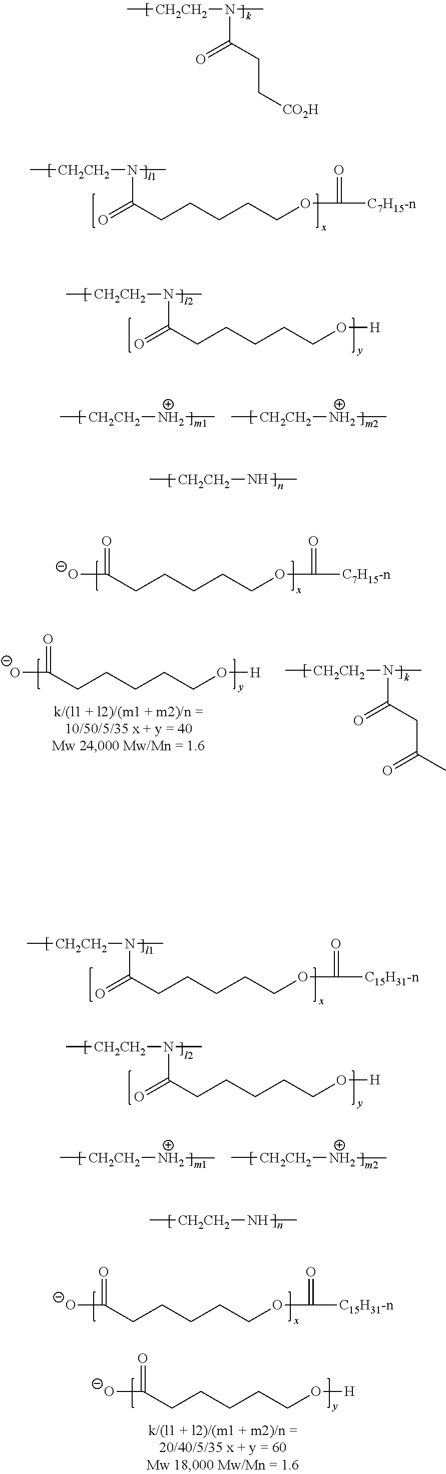

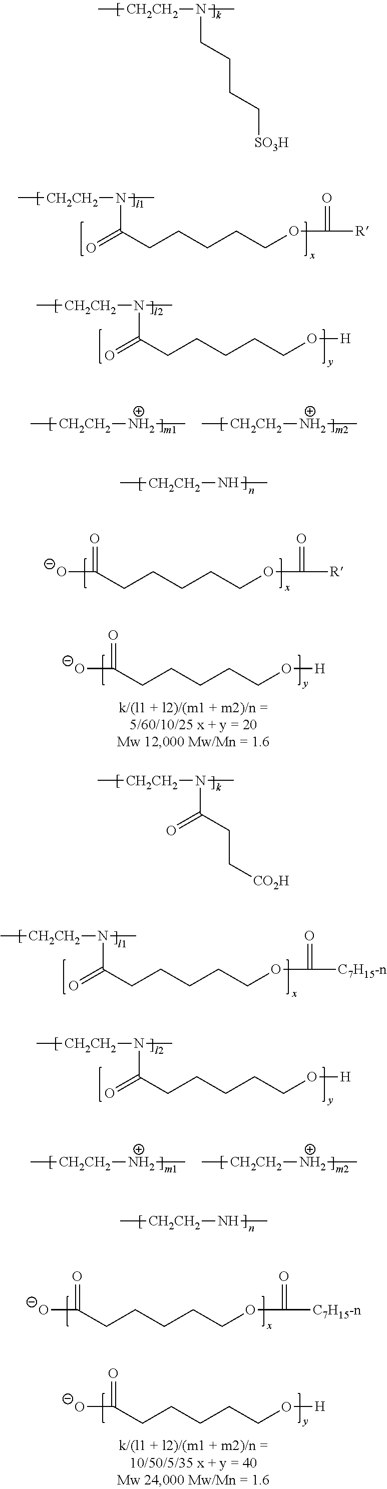

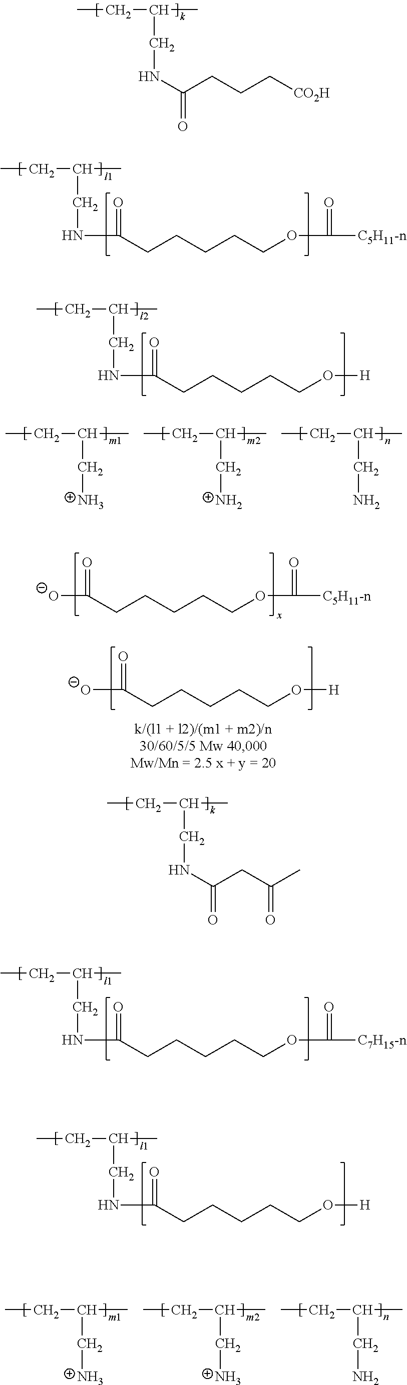

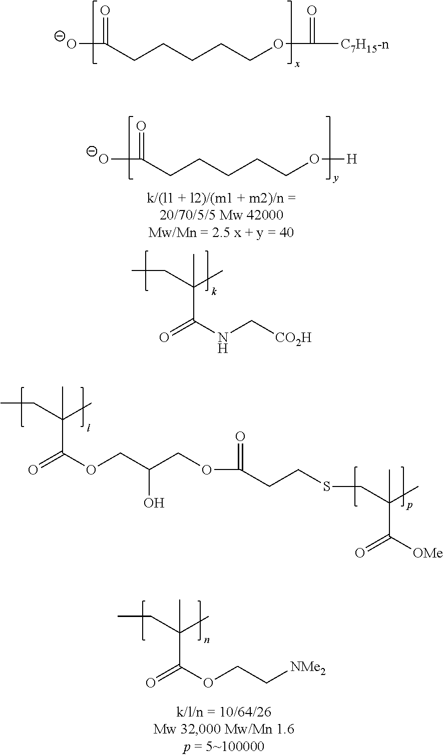

In the radiation-sensitive composition, specific dispersing resin (B) may be used singly or as a combination of two or more kinds thereof

From the standpoints of the dispersion properties and dispersion stability, the content of the specific dispersing resin (B) is in the range of preferably 5 to 50% by mass, more preferably 5 to 40% by mass, still more preferably 5 to 30% by mass, with respect to the total solids of the radiation-sensitive composition according to the present invention.

Other Dispersing Resins

The radiation-sensitive composition may include a dispersing resin other than specific dispersing resin (B) (also referred to as “other dispersing resins”) for the purposes of, for example, adjusting the dispersibility.

Examples of the other dispersing resins that may be used in the present invention include macromolecular dispersants (such as polyamide amines and salts thereof, polycarboxylic acids and salts thereof, high molecular weight unsaturated acid esters, modified polyurethanes, modified polyesters, modified poly(meth)acrylates, (meth)acrylic copolymers and naphthalene sulfonic acid-formalin condensates); polyoxyethylene alkyl phosphates; polyoxyethylene alkylamines; alkanolamines; and pigment derivatives.

The other dispersing resins can be classified into linear macromolecules, terminal-modified macromolecules, graft-type macromolecules and block-type macromolecules, based on their structures.

The other dispersing resins act to prevent reaggregation by adsorbing to surfaces of metal oxide particles such as titanium dioxide particles. From this point of view, preferred examples of the other dispersing resins include the resin having an anchoring site to the surface of metal oxide particles, such as terminal-modified macromolecules, graft-type macromolecules and block-type macromolecules.

In a case of dispersing resins of other types, it is possible to improve adsorbability to the surface of metal oxide particles by modifying the surface of the metal oxide particles.

Specific examples of the other dispersing resins include DISPERBYK-101 (polyamide amine phosphate), 107 (carboxylic acid ester), 110 (an acid group-containing copolymer), 130 (polyamide), 161, 162, 163, 164, 165, 166 and 170 (macromolecular copolymers) and BYK-P104 and P105 (high-molecular-weight unsaturated polycarboxylic acids), all of which are manufactured by BYK-Chemie; EFKA4047, 4050, 4010, 4165 (polyurethane), EFKA4330, 4340 (block copolymers), 4400, 4402 (modified polyacrylates), 5010 (polyester amide), 5765 (high-molecular-weight unsaturated polycarboxylate), 6220 (fatty acid polyester), 6745 (phthalocyanine derivative) and 6750 (azo pigment derivative), all of which are manufactured by EFKA Additives BV; AJISPER PB821 and PB822, manufactured by Ajinomoto Fine-Techno Co., Ltd.; FLOWLEN TG-710 (urethane oligomer) and POLYFLOW No. 50E and No. 300 (acrylic copolymers), all of which are manufactured by Kyoeisha Chemical Co., Ltd.; DISPARLON KS-860, 873 SN, 874, 2150 (aliphatic polyvalent carboxylic acids), 7004 (polyether ester), DA-703-50, DA-705 and DA-725, all of which are manufactured by Kusumoto Chemicals, Ltd.; DEMOL RN, N (naphthalene sulfonic acid-formalin polycondensates), MS, C, SN-B (aromatic sulfonic acid-formalin polycondensates), HOMOGENOL L-18 (macromolecular polycarboxylic acid), EMULGEN 920, 930, 935, 985 (polyoxyethylene nonylphenyl ether) and ACETAMIN 86 (stearyl amine acetate), all of which are manufactured by Kao Corporation; SOLSPERSE 5000 (phthalocyanine derivative), 22000 (azo pigment derivative), 13240 (polyester amine), 3000, 17000, 27000 (macromolecules having a functional site at a terminal), 24000, 28000, 32000 and 38500 (graft-type macromolecules), all of which are manufactured by the Lubrizol Corporation; and NIKKOL T106 (polyoxyethylene sorbitan monooleate) and MYS-IEX (polyoxyethylene monostearate), manufactured by Nikko Chemicals Co., Ltd.

These resins may be used singly, or as a combination of two or more kinds.

In a case in which the radiation-sensitive composition according to the present invention includes a dispersing resin other than specific dispersing resin (B1), the content thereof is preferably from 1% by mass to 20% by mass, more preferably from 1% by mass to 10% by mass, with respect to the total solid components of the radiation-sensitive composition.

(C) Polymerizable Compound

The radiation-sensitive composition includes a polymerizable compound.

The polymerizable compound is a compound that causes polymerization by an active species. Examples of the active species include a radical, an acid and a base.

In a case in which the active species is a radical, a compound having a terminal ethylenically unsaturated bond as a polymerizable group is typically used as the polymerizable compound.

In a case in which the active species is an acid such as sulfonic acid, phosphoric acid, sulfinic acid, carboxylic acid, sulfuric acid or a sulfuric monoester, for example, a compound having a cyclic ether group such as an epoxy group, an oxetanyl group or a tetrahydrofuranyl group, or a vinylbenzene group, may be used as the polymerizable compound.

In a case in which the active species is a base such as an amino compound, a compound having a cyclic ether group such as an epoxy group, an oxetanyl group or a tetrahydrofuranyl group, or a vinylbenzene group, may be used as the polymerizable compound.

The polymerizable compound is preferably selected from compounds having at least one terminal ethylenically unsaturated bond, more preferably from compounds two or more terminal ethylenically unsaturated bonds. Such compounds are well known in the field of the art, and may be used in the invention without particular restriction. The polymerizable compound may have any chemical structure such as a monomer, a prepolymer, i.e., a dimer, a trimer or an oligomer, a mixture thereof, or a multimer thereof. The polymerizable compound may be used singly or as a combination of two or more kinds.

Specific examples of the monomer and the prepolymer thereof include unsaturated carboxylic acids (such as acrylic acid, methacrylic acid, itaconic acid, crotonic acid, isocrotonic acid, and maleic acid), esters and amides thereof, and multimers thereof. Preferable examples thereof include esters of an unsaturated carboxylic acid and an aliphatic polyalcohol compound, amides of an unsaturated carboxylic acid and an aliphatic polyamine compound, and a multimer thereof. Additionally, reaction products obtained from an unsaturated carboxylic acid ester or amide having a nucleophilic substituent group, such as a hydroxyl group, an amino group or a mercapto group, and a monofunctional or polyfunctional isocyanate or an epoxy compound; and dehydration condensation reaction products with a monofunctional or polyfunctional carboxylic acid are suitably used. Further, addition reaction products of an unsaturated carboxylic acid ester or amide having an electrophilic substituent group, such as an isocyanate group or an epoxy group, and a monofunctional or polyfunctional alcohol, amine or thiol; and substitution reaction products of an unsaturated carboxylic acid ester or amide having a leaving substituent, such as a halogen group or a tosyloxy group, and a monofunctional or polyfunctional alcohol, amine or thiol, are also suitable. It is also possible to use compounds obtained by replacing the unsaturated carboxylic acid as described above with an unsaturated phosphonic acid, a vinyl benzene derivative such as styrene, vinyl ether, or allyl ether.

Specific compounds of the above examples described in paragraphs [0095] to [0108] of JP-A No. 2009-288705 are also suitably used in the invention.

Further, a compound having a boiling point of 100° C. or higher at atmospheric pressure and having at least one addition-polymerizable ethylenically unsaturated group is also preferable as the polymerizable compound. Examples of the compound include monofunctional acrylates or methacrylates such as polyethylene glycol mono(meth)acrylate, polypropylene glycol mono(meth)acrylate, and phenoxyethyl (meth)acrylate; polyethylene glycol di(meth)acrylate, trimethylol ethane tri(meth)acrylate, neopentyl glycol di(meth)acrylate, pentaerythritol tri(meth)acrylate, pentaerythritol tetra(meth)acrylate, dipentaerythritol penta(meth)acrylate, dipentaerythritol hexa(meth)acrylate, hexane diol (meth)acrylate, trimethylol propane tri(acryloyloxypropyl) ether, tri(acryloyloxyethyl)isocyanurate, compounds obtained by adding ethylene oxide or propylene oxide to a polyfunctional alcohol such as glycerin or trimethylol ethane, and then making it into a (meth)acrylate, urethane (meth)acrylates as described in Japanese Examined Patent Application Publication (JP-B) No. 48-41708, JP-B No. 50-6034, or JP-A No. 51-37193, polyester acrylates as described in JP-A No. 48-64183, JP-B No. 49-43191, or JP-B No. 52-30490, polyfunctional acrylates or methacrylates such as epoxy acrylates, which are reaction products of an epoxy resin and (meth)acrylic acid, and a mixture of these compounds.

Polyfunctional (meth)acrylates obtained by reacting a polyfunctional carboxylic acid with a compound having a cyclic ether group and an ethylenically unsaturated group, such as glycidyl (meth)acrylate, are also suitable polymerizable compounds.

Further, compounds having a fluorene ring and two or more ethylenically unsaturated groups, i.e., cardo resin, disclosed in JP-A No. 2010-160418, JP-A No. 2010-129825, and Japanese Patent No. 4364216, etc., are also suitable polymerizable compounds.

Further, compounds described in paragraphs [0254] to [0257] of JP-A No. 2008-292970 are also preferable compounds having a boiling point of 100° C. or higher at atmospheric pressure and at least one addition-polymerizable ethylenically unsaturated group.

Suitable examples of the polymerizable compound in the invention include a polymerizable compound having two or more terminal ethylenically unsaturated bonds.

Radical polymerizable monomers represented by following Formula (MO-1) to Formula (MO-5) are also suitable examples of the polymerizable compound having two or more terminal ethylenically unsaturated bonds. In the Formula, when T is an oxyalkylene group, a terminal at the carbon atom side is bound to R.

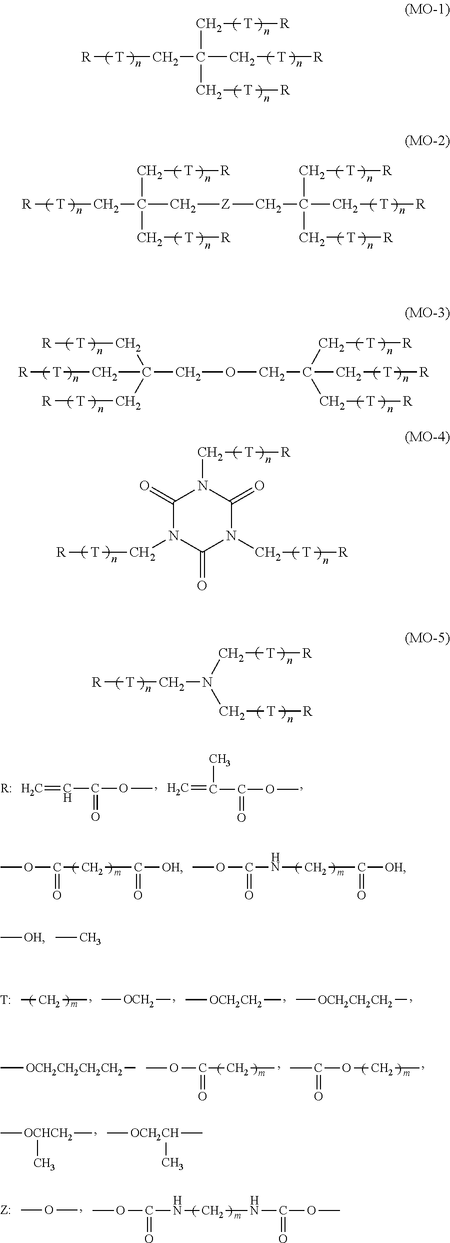

In Formula (MO-1) to Formula (MO-5), n is from 0 to 14, and m is from 1 to 8. Each of R and T, existing by the number of two or more in the same molecule, may be the same or different from each other.

In each of the polymerizable compounds represented by Formula (MO-1) to Formula (MO-5), at least one of the two or more of R represents a group represented by —OC(═O)CH═CH₂ or —OC(═O)C(CH₃)═CH₂.

Compounds described in paragraph [0248] to paragraph [0251] of JP-A No. 2007-269779, which are specific examples of the polymerizable compounds represented by Formula (MO-1) to Formula (MO-5), can also be suitably used in the invention.

Further, (meth)acrylate compounds represented by Formula (1) and Formula (2) and specific examples thereof described in JP-A No. 10-62986, which are obtained by adding ethylene oxide or propylene oxide to a polyfunctional alcohol and making it into a (meth)acrylate, as described above, can also be used as the polymerizable compound.

Among them, preferable examples of the polymerizable compound include dipentaerythritol triacrylate (also commercially available as KAYARAD D-330, trade name, manufactured by Nippon Kayaku Co., Ltd.), dipentaerythritol tetraacrylate (also commercially available as KAYARAD D-320, trade name, manufactured by Nippon Kayaku Co., Ltd.), dipentaerythritol penta(meth)acrylate (also commercially available as KAYARAD D-310, trade name, manufactured by Nippon Kayaku Co., Ltd.), dipentaerythritol hexa(meth)acrylate (also commercially available as KAYARAD DPHA, trade name, manufactured by Nippon Kayaku Co., Ltd.), and a compound selected from the above compounds having a structure in which the (meth)acryloyl group is bonded via an ethylene glycol or propylene glycol residue group. Oligomers of these compounds are also applicable.

The polymerizable compound may have an acid group such as a carboxyl group, a sulfonic group, or a phosphoric group, and preferred examples include ethylenically unsaturated compounds having an acid group. The ethylenically unsaturated compound having an acid group can be obtained by (meth)acrylating part of the hydroxy groups of the polyfunctional alcohol, and adding an acid anhydride to the remaining hydroxy groups to produce carboxy groups.

When the ethylenic compound has an unreacted carboxyl group, as with the case in which the compound is in a mixture, it can be used as it is, but if necessary, an acid group may be introduced by reacting the hydroxyl group of the ethylenic compound with a non-aromatic carboxylic acid anhydride. Specific examples of the non-aromatic carboxylic acid anhydride include tetrahydrophthalic anhydride, alkylated tetrahydrophthalic anhydride, hexahydrophthalic anhydride, alkylated hexahydrophthalic anhydride, succinic anhydride, and maleic anhydride.

In the invention, the monomer having an acid group is preferably a polyfunctional monomer which is an ester obtained from an aliphatic polyhydroxy compound and an unsaturated carboxylic acid. The monomer having an acid group is preferably a polyfunctional monomer to which an acid group is introduced by reacting an unreacted hydroxyl group of the aliphatic polyhydroxy compound with a non-aromatic carboxylic acid anhydride. Particularly preferably, it is an ester in which the aliphatic polyhydroxy compound is pentaerythritol and/or dipentaerythritol. Commercially available product includes M-510 and M-520, trade name, which are an acryl oligomer modified with polybasic acid, manufactured by TOAGOSEI CO., LTD.

These monomers may be used alone, but two or more kinds thereof may be used in combination since it is difficult to produce a compound having a uniform structure due to the production conditions. Further, a polyfunctional monomer not having an acid group may be used in combination with a polyfunctional monomer having an acid group, if necessary.

The acid value of the polyfunctional monomer having an acid group is preferably in the range of from 0.1 to 40 mg-KOH/g, and more preferably in the range of from 5 to 30 mg-KOH/g. When the acid value of the polyfunctional monomer having an acid group is too low, development and dissolution properties may be impaired. When the acid value of the polyfunctional monomer having an acid group is too high, it may be difficult to produce or handle the polyfunctional monomer, its photopolymerizability may be insufficient, and curability such as surface smoothness of pixels may be inferior. Thus, when two or more kinds of polyfunctional monomers having different acid values are used in combination, or when a polyfunctional monomer not having an acid group is used in combination, it is preferable to adjust the acid value of the total polyfunctional monomers to be within the range described above.

In the present invention, the polymerizable compound is also preferably at least one selected from compounds represented by Formula (i) or Formula (ii).

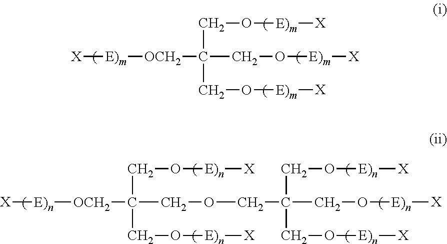

In Formula (i) and Formula (ii), each of E independently represents —((CH₂)_{y}CH₂O)— or —((CH₂)_{y}CH(CH₃)O)—, each of y independently represents an integer from 0 to 10, and each of X independently represents an acryloyl group, a methacryloyl group, a hydrogen atom, or a carboxyl group.

In Formula (i), the sum of the acryloyl group and the methacryloyl group is 3 or 4, each of m independently represents an integer from 0 to 10, and the sum of m is an integer from 0 to 40. When the sum of m is 0, any one of X is a carboxyl group.

In Formula (ii), the sum of the acryloyl group and the methacryloyl group is 5 or 6, each of n independently represents an integer from 0 to 10, and the sum of n is an integer from 0 to 60. When the sum of n is 0, any one of X is a carboxyl group.

In Formula (i), m is preferably an integer from 0 to 6, and more preferably an integer from 0 to 4. The sum of m is preferably an integer from 2 to 40, more preferably an integer from 2 to 16, and still more preferably an integer from 4 to 8.

In Formula (ii), n is preferably an integer from 0 to 6, and more preferably an integer from 0 to 4. The sum of n is preferably an integer from 3 to 60, more preferably an integer from 3 to 24, and still more preferably an integer from 6 to 12.

Further, the oxygen-side terminal of —((CH₂)_{y}CH₂O)— or —((CH₂)_{y}CH(CH₃)O)— in Formula (i) or Formula (ii) is preferably bound to X.

The compound represented by Formula (i) or Formula (ii) may be used alone, or as a combination of two or more kinds thereof. In particular, a compound represented by Formula (ii) in which all of the six of X are an acryloyl group is preferable.

The total content of the compound represented by Formula (i) or Formula (ii) in the polymerizable compound is preferably 20% by mass or more, and more preferably 50% by mass or more.

Compounds represented by Formula (i) or Formula (ii) can be produced by a known method including a process of bonding an open-ring structure to pentaerythritol or dipentaerythritol via ring-opening addition reaction of ethylene oxide or propylene oxide, and a process of introducing a (meth)acryloyl group to a terminal hydroxyl group of the open-ring structure by reacting with (meth)acryloyl chloride, for example. Such processes are well known in the art, and a person skilled in the art can easily synthesize the compounds represented by Formula (i) or Formula (ii).

Among the compounds represented by Formula (i) or Formula (ii), pentaerythritol derivatives and/or dipentaerythritol derivatives are more preferable.

Specific examples of pentaerythritol derivatives and/or dipentaerythritol derivatives include the compounds represented by the following Formula (a) to Formula (f) (also referred to as “exemplary compounds (a) to (f)”). Among them, exemplary compounds (a), (b), (e) and (f) are preferable.

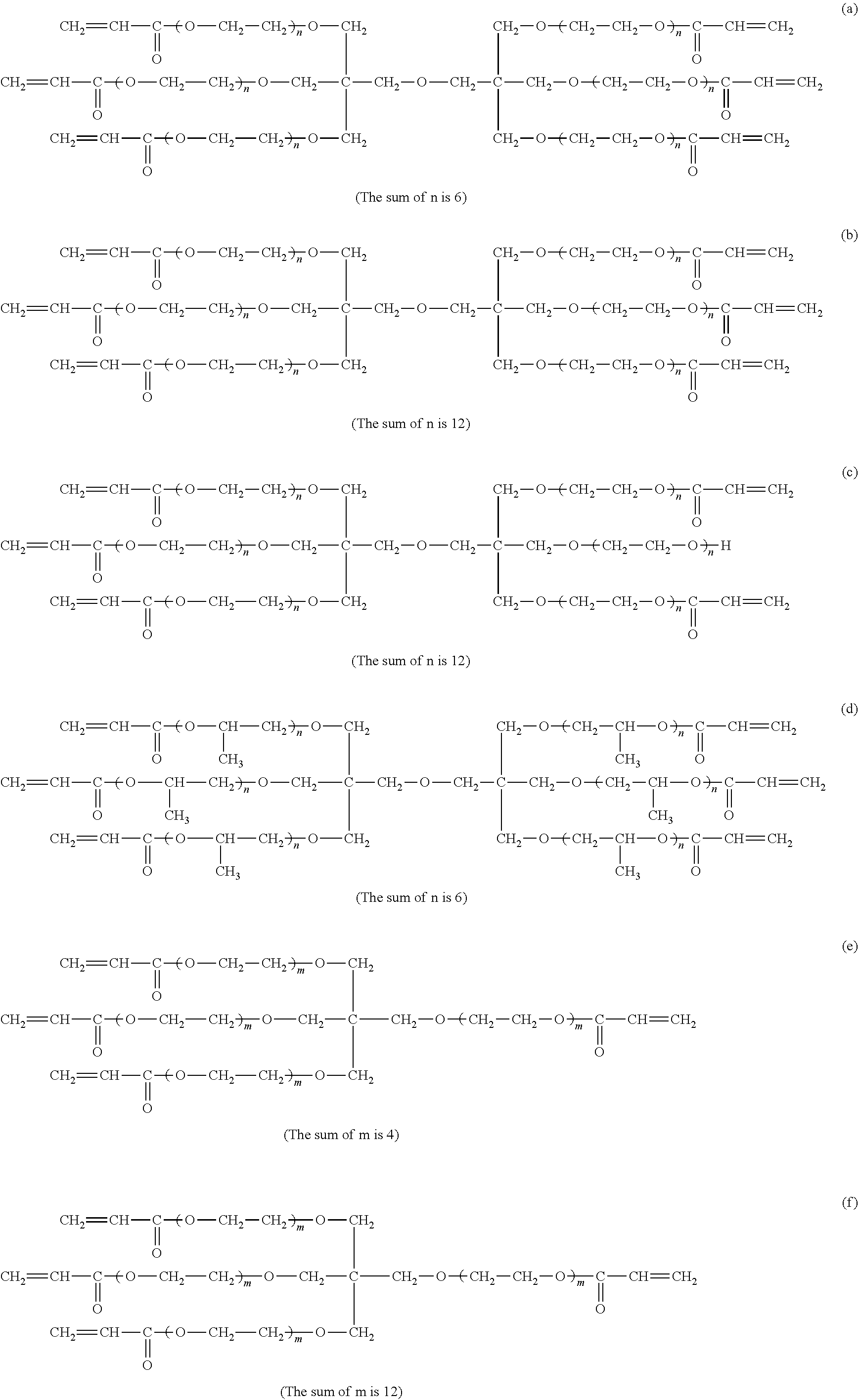

Examples of the commercially available compounds represented by Formula (i) or Formula (ii) include SR-494, trade name, manufactured by Sartomer Company Inc., which is a tetra-functional acrylate having four ethylene oxy chains, DPCA-60, trade name, manufactured by Nippon Kayaku Co., Ltd., which is a hexa-functional acrylate having six pentylene oxy chains, and TPA-330, trade name, manufactured by Nippon Kayaku Co., Ltd., which is a tri-functional acrylate having three isobutylene oxy chains.

Further, as the polymerizable compound, urethane acrylates as disclosed in JP-B No. 48-41708, JP-A No. 51-37193, JP-A No. 2-32293, or JP-A No. 2-16765, and urethane compounds having an ethylene oxide skeleton as disclosed in JP-B No. 58-49860, JP-B No. 56-17654, JP-B No. 62-39417 or JP-B No. 62-39418 are also suitable. Further, a curable composition capable of being very rapidly sensitized can be obtained by using an addition-polymerizable compound having an amino structure or a sulfide structure in a molecule, disclosed in JP-A No. 63-277653, JP-A No. 63-260909, or JP-A No. 1-105238, as a polymerizable compound.

Examples of the commercially available product of the polymerizable compound include urethane oligomers UAS-10, UAB-140 (trade name, manufactured by Sanyo-Kokusaku Pulp Co., Ltd.), UA-7200 (trade name, manufactured by SHIN-NAKAMURA CHEMICAL CO., LTD., DPHA-40H (trade name, manufactured by Nippon Kayaku Co., Ltd.), UA-306H, UA-306T, UA-3061, AH-600, T-600, AI-600 (trade names, manufactured by KYOEISHA CO., LTD.)

Details of the methods of use of these polymerizable compounds, such as the structure of the compounds, single use or combined use, the amount to be added, or the like, may be determined in accordance with the intended performance design of the compounds. From the viewpoint of sensitivity, a structure having a high content of unsaturated groups per molecule is preferable, and in many cases, bifunctionality or higher functionality is desirable. Further, in order to increase the strength of a cured film, trifunctionality or higher functionality is desirable. Also, it is effective to use a method of controlling the sensitivity and the strength at the same time by using compounds having different functionalities and/or different polymerizable groups (for example, acrylic acid esters, methacrylic acid esters, styrene compounds and vinyl ether compounds) in combination. Further, it is desirable to use a tri- or higher functional polymerizable compound, having ethylene oxide chains with different chain lengths, in combination is preferable from the viewpoint that the developability of the radiation-sensitive composition can be controlled and a favorable pattern can be obtained.

The selection and the method of use of the polymerizable compounds are also important factors for the compatibility with other components (for example, a polymerization initiator, a dispersed material and an alkali soluble resin and the like) included in the radiation-sensitive composition and for the dispersibility. For example, the compatibility may be increased by the use of a compound with low purity, or by the use of a combination of two or more kinds of other components. Moreover, in some cases, a specific structure may be selected for the purpose of improving the adhesion to a hard surface such as a substrate.

The following are specific examples of the polymerizable compound. However, the invention is not limited thereto.

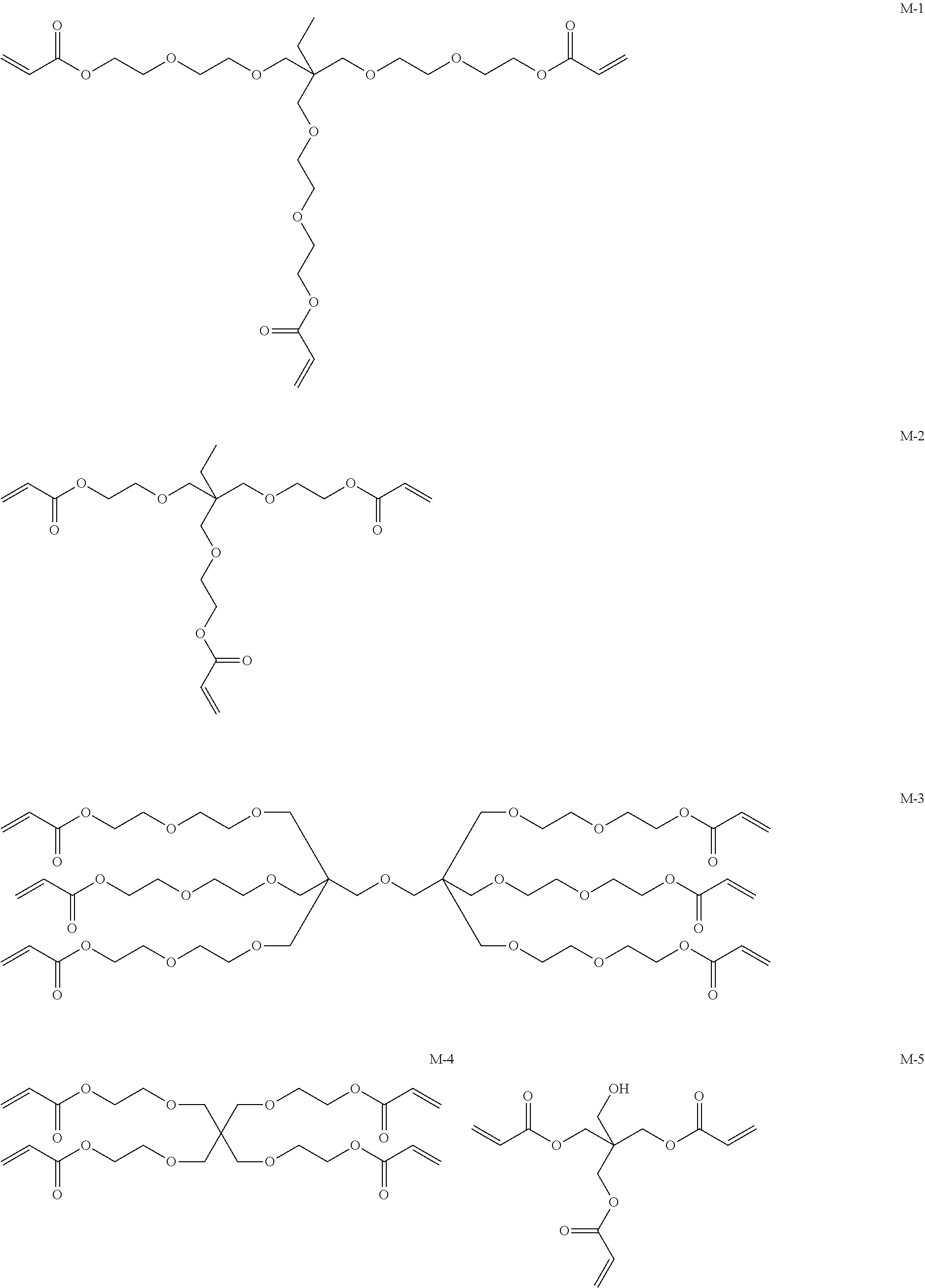

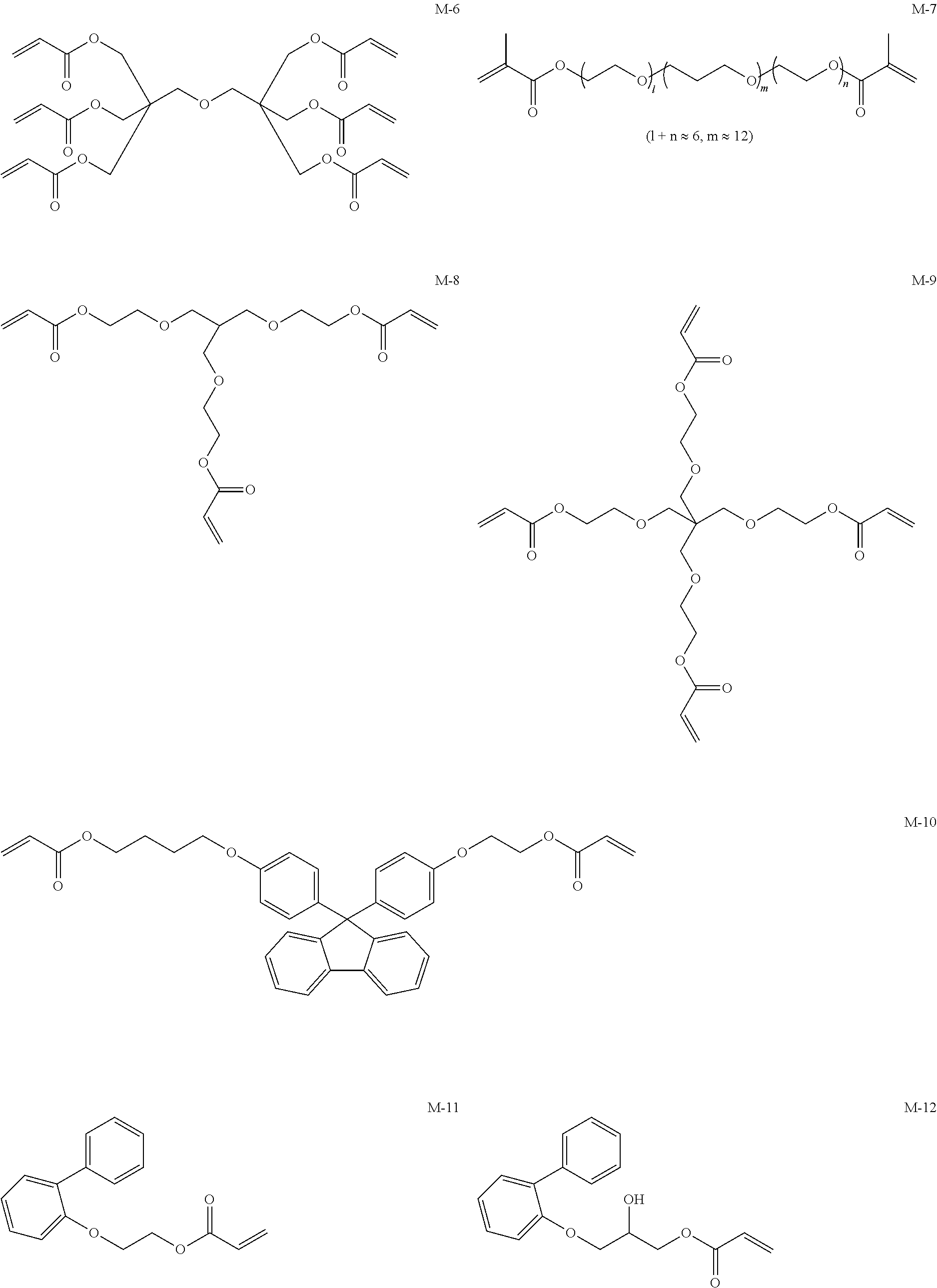

The polymerizable compound may be used singly or in a combination of two or more kinds.

The content of the polymerizable compound in the radiation-sensitive composition of the invention, with respect to the total solid content of the radiation-sensitive composition, is preferably from 0.1% by mass to 90% by mass, more preferably from 1.0% by mass to 80% by mass, and still more preferably from 2.0% by mass to 70% by mass.

(D) Polymerization Initiator

The radiation-sensitive composition includes a photopolymerization initiator.

By including a photopolymerization initiator, photosensitivity can be imparted to the radiation-sensitive composition. In addition, by including a polymerizable compound as mentioned above and an alkali-soluble resin, which may be optionally used, a pattern can be formed by forming a coating from the radiation-sensitive composition, and then exposing and developing the coating. In that way, pixels for a white (transparent) filter in a color filter for solid-state imaging sensor can be obtained.

The photopolymerization initiator is not specifically limited, as long as it has an ability of initiating polymerization of the polymerizable compound as described above, and it can be suitably selected from known photopolymerization initiators. For example, the photopolymerization initiator is preferably sensitive to light in the range of from the UV region to the visible region. Further, the polymerization initiator may be an activator that generates activated radicals by causing an interaction with a photo-excited sensitizer, or may be an initiator that initiates cation polymerization depending on the type of the monomer.

The polymerization initiator preferably includes at least one compound having a molar absorption coefficient of about 50 in the range of from about 300 nm to about 800 nm, more preferably in the range of from 330 nm to 500 nm.

Examples of the photopolymerization initiator include a halogenated hydrocarbon derivative (for example, a hydrocarbon having a triazine skeleton or a hydrocarbon having an oxadiazole skeleton), an acyl phosphine compound such as an acyl phosphine oxide, hexaaryl biimidazole, an oxime compound such as an oxime derivative, an organic peroxide compound, a thio compound, a ketone compound, an aromatic onium salt, ketoxime ether, an aminoacetophenone compound, and hydroxyacetophenone. Among them, an oxime compound is preferable.

Examples of the halogenated hydrocarbon compound having a triazine skeleton include compounds disclosed in Bull. Chem. Soc. Japan, 42, 2924 (1969) by Wakabayashi et al., compounds disclosed in U.K. Patent No. 1388492, compounds disclosed in JP-A No. 53-133428, compounds disclosed in German Patent No. 3337024, compounds disclosed in J. Org. Chem., 29, 1527 (1964) by F. C. Schaefer et al., compounds disclosed in JP-A No. 62-58241, compounds disclosed in JP-A No. 5-281728, compounds disclosed in JP-A No. 5-34920, and compounds disclosed in U.S. Pat. No. 4,212,976. Commercially available compounds include TAZ-107 (trade name, Midori Kagaku Co., Ltd.)

Examples of the compounds disclosed in U.S. Pat. No. 4,212,976 include compounds having an oxadiazole skeleton (for example, 2-trichloromethyl-5-phenyl-1,3,4-oxadiazole, 2-trichloromethyl-5-(4-chlorophenyl)-1,3,4-oxadiazole, 2-trichloromethyl-5-(1-naphthyl)-1,3,4-oxadiazole, 2-trichloromethyl-5-(2-naphthyl)-1,3,4-oxadiazole, 2-tribromomethyl-5-phenyl-1,3,4-oxadiazole, 2-tribromomethyl-5-(2-naphthyl)-1,3,4-oxadiazole; 2-trichloromethyl-5-styryl-1,3,4-oxadiazole, 2-trichloromethyl-5-(4-chlorostyryl)-1,3,4-oxadiazole, 2-trichloromethyl-5-(4-methoxystyryl)-1,3,4-oxadiazole, 2-trichloromethyl-5-(1-naphthyl)-1,3,4-oxadiazole, 2-trichloromethyl-5-(4-n-butoxystyryl)-1,3,4-oxadiazole, and 2-tribromomethyl-5-styryl-1,3,4-oxadiazole).

Examples of the photopolymerization initiator other than those described above include an acridine derivative (for example, 9-phenylacridine, 1,7-bis(9,9′-acridinyl)heptane, etc.), N-phenylglycine, etc., polyhalogen compounds (for example, carbon tetrabromide, phenyltribromomethyl sulfone, phenyltrichloromethyl ketone), coumarins (for example, 3-(2-benzofuranoyl)-7-diethylaminocoumarin, 3-(2-benzofuroyl)-7-(1-pyrrolidinyl)coumarin, 3-benzoyl-7-diethylaminocoumarin, 3-(2-methoxybenzoyl)-7-diethylaminocoumarin, 3-(4-dimethylaminobenzoye-7-diethylaminocoumarin, 3,3′-carbonylbis(5,7-di-n-propoxycoumarin), 3,3′-carbonylbis(7-diethylaminocoumarin), 3-benzoyl-7-methoxycoumarin, 3-(2-furoyl)-7-diethylaminocoumarin, 3-(4-diethylaminocinnamoyl)-7-diethylaminocoumarin, 7-methoxy-3-(3-pyridylcarbonyl)coumarin, 3-benzoyl-5,7-dipropoxycoumarin, 7-benzotriazol-2-ylcoumarin, and coumarin compounds disclosed in JP-A No. 5-19475, JP-A No. 7-271028, JP-A No. 2002-363206, JP-A No. 2002-363207, JP-A No. 2002-363208, and JP-A No. 2002-363209, etc.), acyl phosphine oxides (for example, bis(2,4,6-trimethylbenzoyl)-phenyl phosphine oxide, bis(2,6-dimethoxybenzoyl)-2,4,4-trimethyl-pentylphenyl phosphine oxide, such as LUCIRIN TPO, trade name, manufactured by BASF Japan), metallocenes (for example, bis(η5-2,4-cyclopentadien-1-yl)-bis(2,6-difluoro-3-(1H-pyrrol-1-yl)-phenyl)titanium, η5-cyclopentadienyl-η6-cumenyl-iron (1+)-hexafluorophosphate (1−), etc.), and compounds disclosed in JP-A No. 53-133428, JP-B No. 57-1819, JP-B No. 57-6096, and U.S. Pat. No. 3,615,455.

Examples of the ketone compound include benzophenone, 2-methylbenzophenone, 3-methylbenzophenone, 4-methylbenzophenone, 4-methoxybenzophenone, 2-chlorobenzophenone, 4-chlorobenzophenone, 4-bromobenzophenone, 2-carboxybenzophenone, 2-ethoxycarbonylbenzophenone, benzophenonetetracarboxylic acid or a tetramethyl ester thereof, 4,4′-bis(dialkylamino)benzophenones (for example, 4,4′-bis(dimethylamino)benzophenone, 4,4′-bis dicyclohexylamino)benzophenone, 4,4′-bis(diethylamino)benzophenone, 4,4′-bis(dihydroxyethylamino)benzophenone, 4-methoxy-4′-dimethylaminobenzophenone, 4,4′-dimethoxybenzophenone, 4-dimethylaminobenzophenone, 4-dimethylaminoacetophenone, benzil, anthraquinone, 2-t-butylanthraquinone, 2-methylanthraquinone, phenanthraquinone, xanthone, thioxanthone, 2-chloro thioxanthone, 2,4-diethyl thioxanthone, fluorenone, 2-benzyl-dimethylamino-1-(4-morpholinophenyl)-1-butanone, 2-methyl-1-[4-(methylthio)phenyl]-2-morpholino-1-propanone, 2-hydroxy-2-methyl-[4-(1-methylvinyl)phenyl]propanol oligomer, benzoin, benzoin ethers (for example, benzoin methyl ether, benzoin ethyl ether, benzoin propyl ether, benzoin isopropyl ether, benzoin phenyl ether, benzil dimethyl ketal), acridone, chloroacridone, N-methylacridone, N-butylacridone, and N-butylchloroacridone.

A hydroxyacetophenone compound, an aminoacetophenone compound, and an acyl phosphine compound are also suitably used as the polymerization initiator. More specifically, the aminoacetophenone-based initiators described in JP-A No. 10-291969 and the acyl phosphine oxide-based initiators described in Japanese Patent No. 4225898 may be used.

Examples of the hydroxyacetophenone-based initiators include IRGACURE-184, DAROCUR-1173, IRGACURE-500, IRGACURE-2959 and IRGACURE-127 (trade names, all manufactured by BASF Japan). Examples of the aminoacetophenone-based initiators include IRGACURE-907, IRGACURE-369 and IRGACURE-379 (trade names, all manufactured by BASF Japan). The aminoacetophenone-based initiators include the compounds described in JP-A No. 2009-191179, which have an absorption wavelength being matched to long wavelength light such as 365 nm or 405 nm. Further, as an acylphosphine-based initiator, commercially available IRGACURE-819 or DAROCUR-TPO (trade names, all manufactured by BASF Japan) can be used.

More preferred examples of the polymerization initiator include an oxime compound. Specific examples of the oxime compound include the compounds disclosed in JP-A No. 2001-233842, the compounds disclosed in JP-A No. 2000-80068, and the compounds disclosed in JP-A No. 2006-342166.

Examples of the oxime compound such as an oxime derivative that is suitably used as a polymerization initiator include 3-benzoyloxyiminobutan-2-one, 3-acetoxyiminobutan-2-one, 3-propionyloxyiminobutan-2-one, 2-acetoxyiminopentan-3-one, 2-acetoxyimino-1-phenylpropan-1-one, 2-benzoyloxyimino-1-phenylpropan-1-one, 3-(4-toluenesulfonyloxy)iminobutan-2-one, and 2-ethoxycarbonyloxyimino-1-phenylpropan-1-one.

Examples of the oxime compound include the compounds disclosed in J. C. S. Perkin II (1979) pp. 1653-1660, J. C. S. Perkin II (1979) pp. 156-162, Journal of Photopolymer Science and Technology (1995) pp. 202-232, JP-A Nos. 2000-66385 and 2000-80068, Japanese Patent Application National Publication (Laid-Open) No. 2004-534797, and JP-A No. 2006-342166.

As a commercially available product, IRGACURE OXE-01 (trade name, manufactured by BASF Japan) and IRGACURE OXE-02 (trade name, manufactured by BASF Japan) are also suitably used.

Further, other than the oxime compounds described above, the compounds disclosed in Japanese Patent Application National Publication (Laid-Open) No. 2009-519904, in which an oxime compound is bound to the N-position of carbazole, the compounds disclosed in U.S. Pat. No. 7,626,957, in which a hetero substituent group is introduced to a benzophenone moiety, the compounds disclosed in JP-A No. 2010-15025 and U.S. Patent Application Laid-Open No. 2009-292039, in which a nitro group is introduced into a pigment moiety, the ketoxime compounds disclosed in International Publication No. WO2009/131189, the compounds disclosed in U.S. Pat. No. 7,556,910, in which a triazine skeleton and an oxime skeleton are included in the same molecule, and the compounds disclosed in JP-A No. 2009-221114, which have an absorption maximum at 405 nm and exhibit favorable sensitivity with respect to a g-line light source, can also be used.

Preferably, the cyclic oxime compounds disclosed in JP-A No. 2007-231000 and JP-A No. 2007-322744 are also suitably used. Among the cyclic oxime compounds, the cyclic oxime compounds fused with a carbazole pigment disclosed in JP-A No. 2010-32985 and JP-A No. 2010-185072 are preferred, since these compounds exhibit a high light absorbency and are suitable from the viewpoint of increasing sensitivity.

Further, compounds disclosed in JP-A No. 2009-242469, in which an unsaturated bond is included in a specific position of an oxime compound, are also suitably used, since these compounds can increase sensitivity by regenerating activated radicals from polymerization inactive radicals.

Most preferable examples of the oxime compounds include those having a specific substituent disclosed in JP-A No. 2007-269779 and those having a thioaryl group disclosed in JP-A No. 2009-191061.

Specifically, a compound represented by following Formula (1) is preferred as an oxime compound having a thioaryl group. The oxime compound may be an (E)-oxime compound, a (Z)-oxime compound, or a mixture thereof, in terms of the N—O bond.

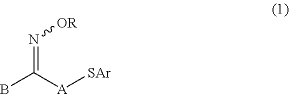

In Formula (1), each of R and B independently represents a monovalent substituent, A represents a divalent organic group, and Ar represents an aryl group.

In Formula (1), the monovalent substituent represented by R is preferably a monovalent non-metal atomic group.

Examples of the monovalent non-metal atomic group include an alkyl group, an aryl group, an acyl group, an alkoxycarbonyl group, an aryloxycarbonyl group, a heterocyclic group, an alkylthiocarbonyl group, and an arylthiocarbonyl group. These groups may have one or more substituents. Further, the substituent may be substituted with another substituent.

Examples of the substituent include a halogen atom, an aryloxy group, an alkoxycarbonyl group, an aryloxycarbonyl group, an acyloxy group, an acyl group, an alkyl group, and an aryl group.

As the alkyl group that may have a substituent, an alkyl group having 1 to 30 carbon atoms is preferable, and examples thereof include a methyl group, an ethyl group, a propyl group, a butyl group, a hexyl group, an octyl group, a decyl group, a dodecyl group, an octadecyl group, an isopropyl group, an isobutyl group, a sec-butyl group, a t-butyl group, a 1-ethylpentyl group, a cyclopentyl group, a cyclohexyl group, a trifluoromethyl group, a 2-ethylhexyl group, a phenacyl group, a 1-naphthoylmethyl group, a 2-naphthoylmethyl group, a 4-methylsulfanylphenacyl group, a 4-phenylsulfanylphenacyl group, a 4-dimethylaminophenacyl group, a 4-cyanophenacyl group, a 4-methylphenacyl group, a 2-methylphenacyl group, a 3-fluorophenacyl group, a 3-trifluoromethylphenacyl group, and a 3-nitrophenacyl group.

As the aryl group that may have a substituent, an aryl group having 6 to 30 carbon atoms is preferable, and examples thereof include a phenyl group, a biphenyl group, a 1-naphthyl group, a 2-naphthyl group, a 9-anthryl group, a 9-phenanthryl group, a 1-pyrenyl group, a 5-naphthacenyl group, a 1-indenyl group, a 2-azulenyl group, a 9-fluorenyl group, a terphenyl group, a quarter phenyl group, an o-, m-, or p-tolyl group, a xylyl group, an o-, m-, and p-cumenyl group, a mesityl group, a pentalenyl group, a binaphthalenyl group, ternaphthalenyl group, a quarter naphthalenyl group, a heptalenyl group, a biphenylenyl group, an indacenyl group, a fluoranthenyl group, an acenaphthylenyl group, an aceanthrylenyl group, a phenalenyl group, a fluorenyl group, an anthryl group, a bianthracenyl group, a teranthracenyl group, a quarter anthracenyl group, an anthraquinolyl group, a phenanthryl group, a triphenylenyl group, a pyrenyl group, a chrysenyl group, a naphthacenyl group, a pleiadenyl group, a picenyl group, a perylenyl group, a pentaphenyl group, a pentacenyl group, a tetraphenylenyl group, a hexaphenyl group, a hexacenyl group, a rubicenyl group, a coronenyl group, a trinaphthylenyl group, a heptaphenyl group, a heptacenyl group, a pyranthrenyl group, and an ovalenyl group.

As the acyl group that may have a substituent, an acyl group having 2 to 20 carbon atoms is preferable, and examples thereof include an acetyl group, a propanoyl group, a butanoyl group, a trifluoroacetyl group, a pentanoyl group, a benzoyl group, a 1-naphthoyl group, a 2-naphthoyl group, a 4-methylsulfanylbenzoyl group, a 4-phenylsulfanylbenzoyl group, a 4-dimethylaminobenzoyl group, a 4-diethylaminobenzoyl group, a 2-chlorobenzoyl group, a 2-methylbenzoyl group, a 2-methoxybenzoyl group, a 2-butoxybenzoyl group, a 3-chlorobenzoyl group, a 3-trifluoromethylbenzoyl group, a 3-cyanobenzoyl group, a 3-nitrobenzoyl group, a 4-fluorobenzoyl group, a 4-cyanobenzoyl group, and a 4-methoxybenzoyl group.

As the alkoxycarbonyl group that may have a substituent, an alkoxycarbonyl group having 2 to 20 carbon atoms is preferable, and specific examples thereof include a methoxycarbonyl group, an ethoxycarbonyl group, a propoxycarbonyl group, a butoxycarbonyl group, a hexyloxycarbonyl group, an octyloxycarbonyl group, a decyloxycarbonyl group, an octadecyloxycarbonyl group, and a trifluoromethyloxycarbonyl group.

Specific examples of the aryloxycarbonyl group that may have a substituent include a phenoxycarbonyl group, a 1-naphthyloxycarbonyl group, a 2-naphthyloxycarbonyl group, a 4-methylsulfanylphenyloxycarbonyl group, a 4-phenylsulfanylphenyloxycarbonyl group, a 4-dimethylaminophenyloxycarbonyl group, a 4-diethylaminophenyloxycarbonyl group, a 2-chlorophenyloxycarbonyl group, a 2-methylphenyloxycarbonyl group, a 2-methoxyphenyloxycarbonyl group, a 2-butoxyphenyloxycarbonyl group, a 3-chlorophenyloxycarbonyl group, a 3-trifluoromethylphenyloxycarbonyl group, a 3-cyanophenyloxycarbonyl group, a 3-nitrophenyloxycarbonyl group, a 4-fluorophenyloxycarbonyl group, a 4-cyanophenyloxycarbonyl group, and a 4-methoxyphenyloxycarbonyl group.

As the heterocyclic group that may have a substituent, an aromatic or aliphatic heterocycle including a nitrogen atom, an oxygen atom, a sulfur atom, or a phosphorus atom is preferable, and specific examples thereof include a thienyl group, a benzo[b]thienyl group, a naphth[2,3-b]thienyl group, a thianthrenyl group, a furyl group, a pyranyl group, an isobenzofuranyl group, a chromenyl group, a xanthenyl group, a phenoxathiinyl group, a 2H-pyrrolyl group, a pyrrolyl group, an imidazolyl group, a pyrazolyl group, a pyridyl group, a pyrazinyl group, a pyrimidinyl group, a pyridazinyl group, an indolizinyl group, an isoindolyl group, a 3H-indolyl group, an indolyl group, a 1H-indazolyl group, a purinyl group, a 4H-quinolizinyl group, an isoquinolyl group, a quinolyl group, a phthalazinyl group, a naphthyridinyl group, a quinoxalinyl group, a quinazolinyl group, a cinnolinyl group, a pteridinyl group, a 4aH-carbazolyl group, a carbazolyl group, a β-carbolinyl group, a phenanthridinyl group, an acridinyl group, a perimidinyl group, a phenanthrolinyl group, a phenazinyl group, a phenarsazinyl group, an isothiazolyl group, a phenothiazinyl group, an isoxazolyl group, a furazanyl group, a phenoxazinyl group, an isochromanyl group, a chromanyl group, a pyrrolidinyl group, a pyrrolinyl group, an imidazolidinyl group, an imidazolinyl group, a pyrazolidinyl group, a pyrazolinyl group, a piperidyl group, a piperazinyl group, an indolinyl group, an isoindolinyl group, a quinuclidinyl group, a morpholinyl group, and a thioxanthonyl group.

Specific examples of the alkylthiocarbonyl group that may have a substituent include a methylthiocarbonyl group, a propylthiocarbonyl group, a butylthiocarbonyl group, a hexylthiocarbonyl group, an octylthiocarbonyl group, a decylthiocarbonyl group, an octadecylthiocarbonyl group, and a trifluoromethyl thiocarbonyl group.

Specific examples of the arylthiocarbonyl group that may have a substituent include a 1-naphthylthiocarbonyl group, a 2-naphthylthiocarbonyl group, a 4-methylsulfanylphenylthiocarbonyl group, a 4-phenylsulfanylphenylthiocarbonyl group, a 4-dimethylaminophenylthiocarbonyl group, a 4-diethylaminophenylthiocarbonyl group, a 2-chlorophenylthiocarbonyl group, a 2-methylphenylthiocarbonyl group, a 2-methoxyphenylthiocarbonyl group, a 2-butoxyphenylthiocarbonyl group, a 3-chlorophenylthiocarbonyl group, a 3-trifluoromethylphenylthiocarbonyl group, a 3-cyanophenylthiocarbonyl group, a 3-nitrophenylthiocarbonyl group, a 4-fluorophenylthiocarbonyl group, a 4-cyanophenylthiocarbonyl group, and a 4-methoxyphenylthiocarbonyl group.

The monovalent substituent represented by B indicates an aryl group, a heterocyclic group, an arylcarbonyl group, or a heterocyclic carbonyl group. These groups may have one or more substituents. Examples of the substituent include the substituents as described above. Further, the substituent may be substituted by another substituent.

The monovalent substituent represented by B is particularly preferably a substituent having a structure represented as described below.

In the following structures, Y, X and n have the same definitions as Y, X and n in Formula (2) that will described later, and the preferable examples are also the same.

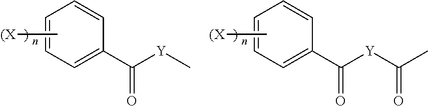

In Formula (1), examples of the divalent organic group represented by A includes an alkylene group (preferably an alkylene group having 1 to 12 carbon atoms), a cycloalkylene group (preferably a cycloalkylene group having 6 to 12 carbon atoms) and an alkynylene group (preferably an alkynylene group having 2 to 12 carbon atoms). These groups may by substituted by one or more substituents. Examples of the substituent include the substituents as described above. Further, the substituent may be substituted by another substituent.

In particular, in view of increasing sensitivity and suppressing coloration due to heat and time, the divalent organic group represented by A is preferably an unsubstituted alkylene group, an alkylene group substituted by an alkyl group (for example, a methyl group, an ethyl group, a tert-butyl group, or a dodecyl group), an alkylene group substituted by an alkenyl group (for example, a vinyl group or an allyl group), or an alkylene group substituted by an aryl group (for example, a phenyl group, a p-tolyl group, a xylyl group, a cumenyl group, a naphthyl group, an anthryl group, a phenanthryl group or a styryl group).

The aryl group represented by Ar is preferably an aryl group having 6 to 30 carbon atoms. The aryl group may be substituted by another substituent. Examples of the substituent include the substituents that are described above as the substituent introduced to the substituted aryl group that are listed above as specific examples of an aryl group that may have a substituent.

In particular, in view of increasing sensitivity and suppressing coloration due to heat and time, a substituted or unsubstituted phenyl group is preferable.

In Formula (1), from the viewpoint of sensitivity, the structure represented by “SAr”, formed from Ar and S that is adjacent to Ar, is preferably selected from the following structures. In the following structures, Me represents a methyl group and Et represents an ethyl group.

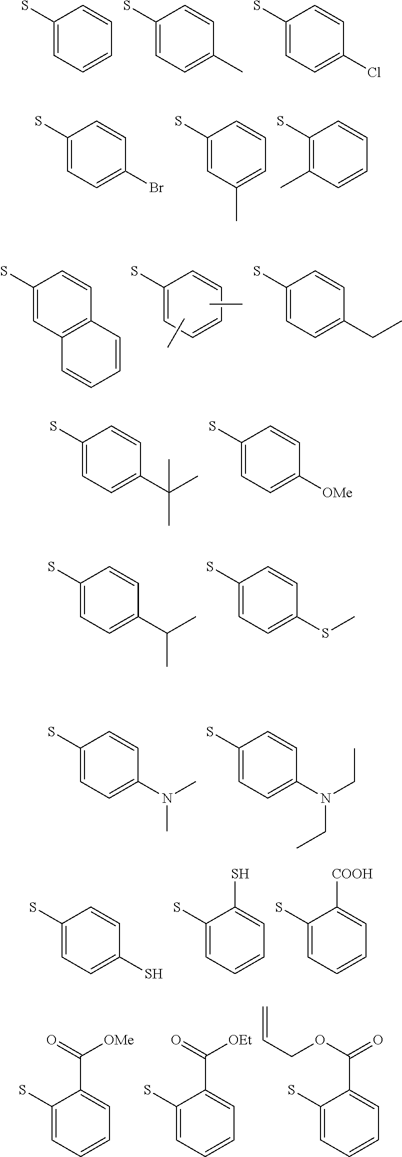

The oxime compound is preferably a compound represented by following Formula (2).

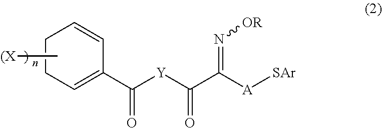

In Formula (2), each of R and X independently represents a monovalent substituent, each of A and Y independently represents a divalent organic group, Ar represents an aryl group, and n is an integer from 0 to 5.

In Formula (2), R, A and Ar have the same definitions as R, A and Ar in Formula (1), and preferable examples thereof are also the same.

In Formula (2), examples of the monovalent substituent represented by X include an alkyl group, an aryl group, an alkoxy group, an aryloxy group, an acyloxy group, an acyl group, an alkoxycarbonyl group, an amino group, a heterocyclic group, and a halogen atom. These groups may be substituted by one or more substituents. Examples of the substituent include the substituents as described above. Further, the substituent may be substituted by another substituent.

Among them, from the viewpoint of solubility in a solvent and improvement in absorption efficiency at a long wavelength range, X is preferably an alkyl group.

Further, n in Formula (2) represents an integer from 0 to 5, and an integer from 0 to 2 is preferable.

In Formula (2), the divalent organic group represented by Y include the following structures. In the structures, * represents a site to be bound to the carbon atom adjacent to Y in Formula (2).

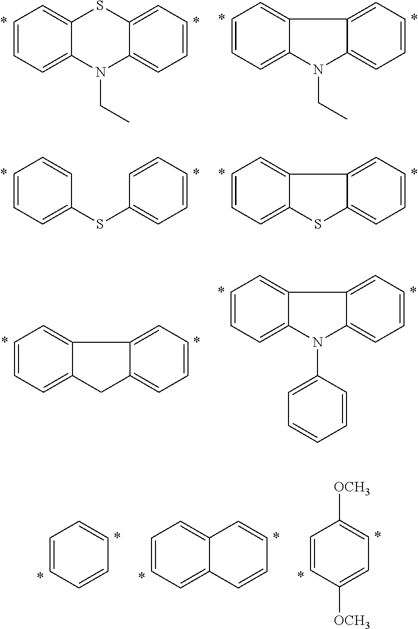

Among them, from the viewpoint of increasing sensitivity, the following structures are preferred.

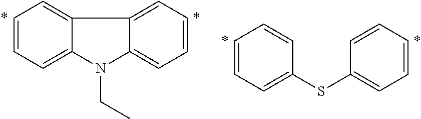

Further, the oxime compound is preferably a compound represented by the following Formula (3).

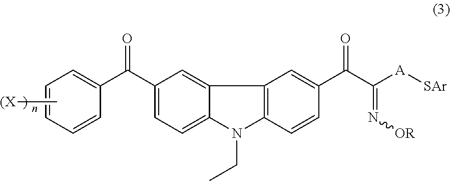

In Formula (3), each of R and X independently represents a monovalent substituent, A represents a divalent organic group, Ar represents an aryl group, and n is an integer from 0 to 5.

In Formula (3), R, X, A, Ar and n have the same definitions as R, X, A, Ar and n in Formula (2), respectively, and preferable examples thereof are also the same.

The following structures (B-1) to (B-11) are specific example of the oxime compound suitably used in the invention. However, the invention is not limited to these examples.

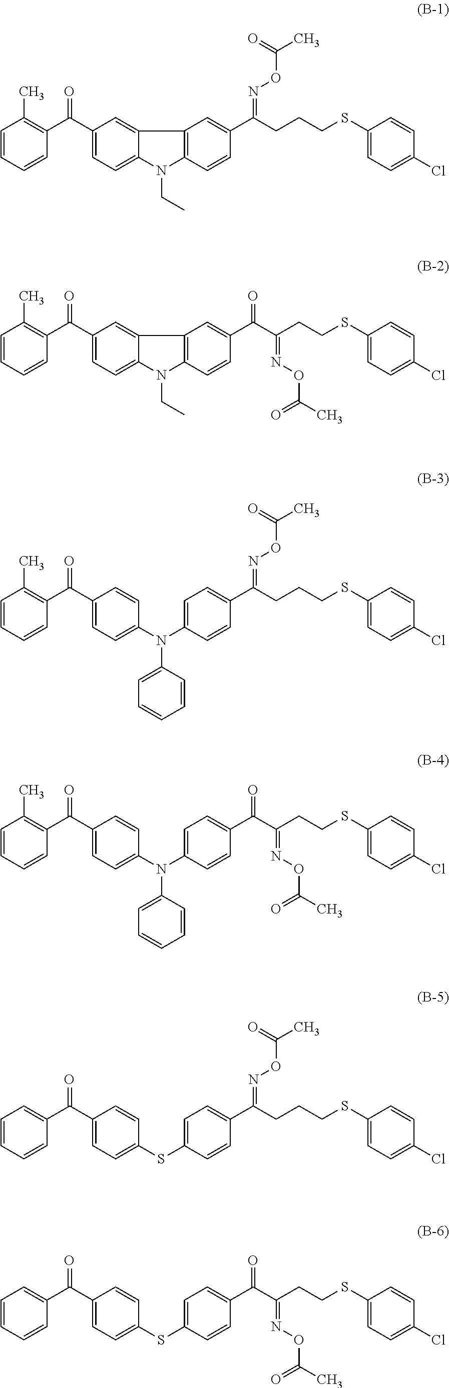 [SMILES: CCn1c2ccc(C(=O)c3ccccc3C)cc2c2cc(/C(CCCSc3ccc(Cl)cc3)=N/OC(C)=O)ccc21 ; CCn1c2ccc(C(=O)/C(CCSc3ccc(Cl)cc3)=N/OC(C)=O)cc2c2cc(C(=O)c3ccccc3C)ccc21 ; CC(=O)O/N=C(\CCCSc1ccc(Cl)cc1)c1ccc(N(c2ccccc2)c2ccc(C(=O)c3ccccc3C)cc2)cc1 ; CC(=O)O/N=C(\CCSc1ccc(Cl)cc1)C(=O)c1ccc(N(c2ccccc2)c2ccc(C(=O)c3ccccc3C)cc2)cc1 ; CC(=O)O/N=C(\CCCSc1ccc(Cl)cc1)c1ccc(Sc2ccc(C(=O)c3ccccc3)cc2)cc1 ; CC(=O)O/N=C(\CCSc1ccc(Cl)cc1)C(=O)c1ccc(Sc2ccc(C(=O)c3ccccc3)cc2)cc1]

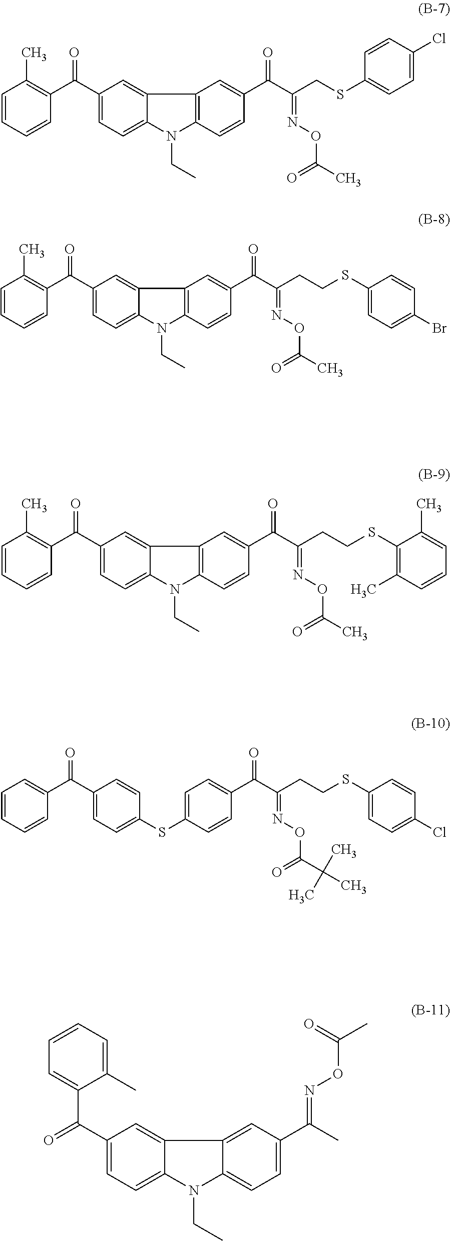 [SMILES: CCn1c2ccc(C(=O)/C(CSc3ccc(Cl)cc3)=N/OC(C)=O)cc2c2cc(C(=O)c3ccccc3C)ccc21 ; CCn1c2ccc(C(=O)/C(CCSc3ccc(Br)cc3)=N/OC(C)=O)cc2c2cc(C(=O)c3ccccc3C)ccc21 ; CCn1c2ccc(C(=O)/C(CCSc3c(C)cccc3C)=N/OC(C)=O)cc2c2cc(C(=O)c3ccccc3C)ccc21 ; CC(C)(C)C(=O)O/N=C(\CCSc1ccc(Cl)cc1)C(=O)c1ccc(Sc2ccc(C(=O)c3ccccc3)cc2)cc1 ; CCn1c2ccc(C(=O)c3ccccc3C)cc2c2cc(/C(C)=N/OC(C)=O)ccc21]

The oxime compound has a maximum absorption wavelength in the wavelength range of from 350 nm to 500 nm, preferably in the wavelength range of 360 nm to 480 nm. The oxime compound having a high absorbance at from 365 nm and 455 nm is particularly preferable.

The molar absorption coefficient of the oxime compound is preferably from 1,000 to 300,000 at 365 nm or 405 nm in view of sensitivity, more preferably from 2,000 to 300,000, most preferably from 5,000 to 200,000.

The molar absorption coefficient of a compound can be measured by a known method. Specifically, for example, the molar absorption coefficient is preferably measured with a UV and visible light spectrophotometer (CARRYS, trade name, manufactured by Varian) with ethyl acetate as a solvent at a concentration of 0.01 g/L.

The photopolymerization initiator used in the invention may be used alone, or as a combination of two or more kinds.

The amount of the photopolymerization initiator with respect to the total solid content of the radiation-sensitive composition is preferably from 0.1% by mass to 10% by mass, more preferably from 1% by mass to 10% by mass, and still more preferably from 2% by mass to 10% by mass.

Sensitizer

The radiation-sensitive composition may include a sensitizer for the purpose of improving efficiency in radical generation and extending the wavelength to which the radiation-sensitive composition is sensitive. The sensitizer that can be used in the invention is preferably a sensitizer that works with the polymerization initiator via an electron transfer system or an energy transfer system.

Examples of the sensitizer include compounds described in paragraphs [0101] to [0154] of JP-A No. 2008-32803.

From the viewpoint of photoabsorption efficiency to a deep portion and initiation decomposition efficiency, the content of the sensitizer in terms of the solid content in the radiation-sensitive composition is preferably from 0.1% by mass to 20% by mass, more preferably from 0.5% by mass to 15% by mass.

The sensitizer may be used alone or as a combination of two or more kinds.

(F) Organic Solvent

The radiation-sensitive composition includes an organic solvent.

The organic solvent is not particularly restricted as long as it ensures dissolvability of each component and coatability of the radiation-sensitive composition.

Examples of the organic solvent include the following: as esters, ethyl acetate, n-butyl acetate, isobutyl acetate, amyl formate, isoamyl acetate, isobutyl acetate, butyl propionate, isopropyl butyrate, ethyl butyrate, butyl butyrate, methyl lactate, ethyl lactate, alkyl oxyacetate (methyl oxyacetate, ethyl oxyacetate, butyl oxyacetate (for example, methyl methoxyacetate, ethyl methoxyacetate, butyl methoxyacetate, methyl ethoxyacetate, and ethyl ethoxyacetate)), 3-oxypropionic acid alkyl esters (for example, methyl 3-oxypropionate and ethyl 3-oxypropionate (for example, methyl 3-methoxypropionate, ethyl 3-methoxypropionate, methyl 3-ethoxypropionate, and ethyl 3-ethoxypropionate)), 2-oxypropionic acid alkyl esters (examples: methyl 2-oxypropionate, ethyl 2-oxypropionate, and propyl 2-oxypropionate (for example, methyl 2-methoxypropionate, ethyl 2-methoxypropionic acid, propyl 2-methoxypropionate, methyl 2-ethoxypropionate, and ethyl 2-ethoxypropionate)), methyl 2-oxy-2-methylpropionate and ethyl 2-oxy-2-methylpropionate (for example, methyl 2-methoxy-2-methylpropionate and ethyl 2-ethoxy-2-methylpropionate), methyl pyruvate, ethyl pyruvate, propyl pyruvate, methyl acetoacetate, ethyl acetoacetate, methyl 2-oxobutanonate and ethyl 2-oxobutanonate; as ethers, diethylene glycol dimethyl ether, tetrahydrofuran, ethylene glycol monomethyl ether, ethylene glycol monoethyl ether, methylcellosolve acetate, ethylcellosolve acetate, diethylene glycol monomethyl ether, diethylene glycol monoethyl ether, diethylene glycol monobutyl ether, propylene glycol monomethyl ether, propylene glycol monomethyl ether acetate, propylene glycol monoethyl ether acetate, and propylene glycol monopropyl ether acetate; as ketones, methyl ethyl ketone, cyclohexanone, 2-heptanone, and 3-heptanone; and as aromatic hydrocarbons, toluene and xylene.

The organic solvent may be used as a mixture of combination of two or more kinds thereof. When two or more organic solvents are used in combination, a mixture solution of at least two selected from methyl 3-ethoxypropionate, ethyl 3-ethoxypropionate, ethylcellosolve acetate, ethyl lactate, diethylene glycol dimethyl ether, butyl acetate, methyl 3-methoxypropionate, 2-heptanone, cyclohexanone, ethyl carbitol acetate, butyl carbitol acetate, propylene glycol methyl ether, and propylene glycol methyl ether acetate is particularly preferable.

When a mixture of organic solvent includes cyclohexanone, the content of cyclohexanone in the mixture in the radiation-sensitive composition is preferably from 5% by mass to 90% by mass, more preferably from 10% by mass to 85% by mass, and still more preferably from 15% by mass to 80% by mass.

The content of the organic solvent in the radiation-sensitive composition is preferably adjusted such that the total solid content of the composition is from 5% by mass to 80% by mass, more preferably 5% by mass to 60% by mass, and still more preferably from 10% by mass to 50% by mass.

(G) Binder Polymer

The radiation-sensitive composition may include a binder polymer.

The binder polymer may be selected from alkali soluble resins, which is a linear organic macromolecular polymer having at least one group that promotes alkali solubility in the molecule (preferably, a molecule whose main chain is an acryl-based copolymer or a styrene-based copolymer). From the viewpoint of heat resistance, a polyhydroxystyrene resin, a polysiloxane resin, an acryl resin, an acrylamide resin, and an acryl/acrylamide copolymer resin are preferable. From the viewpoint of controlling developability, an acryl resin, an acrylamide and an acryl/acrylamide copolymer resin are preferable.

Examples of the group that promotes alkali solubility include an acidic group, an alcoholic hydroxy group, pyrrolidone group and an alkyleneoxide group. An acidic group is preferred.

The acidic group is not particularly restricted, and examples include a carboxyl group, an active methylene group, a phosphoric group, a sulfonic group, a phenolic hydroxyl group and a carboxylic anhydride group. The acidic group is preferably soluble in an organic solvent and developable with a weak alkali aqueous solution, and a carboxyl group is particularly preferred. The acidic group may be used alone or as a combination of two or more kinds.

The production of an alkali soluble resin may be carried out by a known radical polymerization method. The polymerization conditions for producing an alkali soluble resin by radical polymerization, including the temperature, the pressure, the type and the amount of a radical initiator, the type of a solvent, can be easily determined by a person skilled in the art, or can be experimentally determined.

The linear organic macromolecular polymer, which is used as an alkali soluble resin, is preferably a polymer having carboxylic acid in a side chain. Examples thereof include a methacrylic acid copolymer, an acrylic acid copolymer, an itaconic acid copolymer, a crotonic acid copolymer, a maleic acid copolymer, a partially esterified maleic acid copolymer, an alkali soluble phenol resin such as a novolac resin, an acidic cellulose derivative having carboxylic acid in a side chain, and a polymer obtained from a polymer having a hydroxy group added with an acid anhydride. In particular, (meth)acrylic acid and a copolymer of (meth)acrylic acid and a monomer copolymerizable with (meth)acrylic acid are suitable as the alkali soluble resin. Examples of the monomer copolymerizable with (meth)acrylic acid include alkyl (meth)acrylate, aryl (meth)acrylate, and a vinyl compound. Examples of the alkyl (meth)acrylate and the aryl (meth)acrylate include methyl (meth)acrylate, ethyl (meth)acrylate, propyl (meth)acrylate, butyl (meth)acrylate, isobutyl (meth)acrylate, pentyl (meth)acrylate, hexyl (meth)acrylate, octyl (meth)acrylate, phenyl (meth)acrylate, benzyl (meth)acrylate, tolyl (meth)acrylate, naphthyl (meth)acrylate, and cyclohexyl (meth)acrylate. Examples of the vinyl compound include styrene, α-methylstyrene, vinyltoluene, glycidyl methacrylate, acrylonitrile, vinyl acetate, N-vinylpyrrolidone, tetrahydrofurfuryl methacrylate, a polystyrene macromonomer, a polymethyl methacrylate macromonomer, and N-substituted maleimide monomers described in JP-A No. 10-300922 such as N-phenylmaleimide and N-cyclohexylmaleimide. The monomer copolymerizable with (meth)acrylic acid may be used alone or as a combination of two or more types.

An alkali soluble resin that includes, as a monomer component, a compound represented by following Formula (ED) (also referred to as an “ether dimer”) is also suitably used.

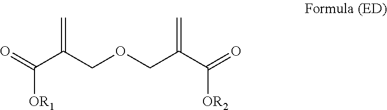

In Formula (ED), each of R¹ and R² independently represents a hydrogen atom or a hydrocarbon group. The hydrocarbon group preferably has 1 to 25 carbon atoms. The hydrocarbon group may have a substituent.

In that case, a cured film that exhibits favorable heat resistance and transparency can be formed from the radiation-sensitive composition.

In Formula (ED), the hydrocarbon group having 1 to 25 carbon atoms which may have a substituent group, represented by R¹ and R², is not specifically limited. Examples thereof include a linear or branched alkyl group such as a methyl group, an ethyl group, an n-propyl group, an isopropyl group, an n-butyl group, an isobutyl group, a t-butyl group, a t-amyl group, a stearyl group, a lauryl group, and a 2-ethylhexyl group; an aryl group such as a phenyl group; a cycloaliphatic group such as a cyclohexyl group, a t-butylcyclohexyl group, a dicyclopentadienyl group, a tricyclodecanyl group, an isobornyl group, an adamantyl group, and a 2-methyl-2-adamantyl group; an alkyl group substituted by an alkoxy group such as a 1-methoxyethyl group and 1-ethoxyethyl group; and an alkyl group substituted by an aryl group such as a benzyl group. Among these, a substituent group having a primary or secondary carbon atom such as methyl, ethyl, cyclohexyl or benzyl, which is difficult to dissociate by acid or heat, is preferable from the viewpoint of heat resistance.

Specific examples of the ether dimer include dimethyl-2,2′-[oxybis(methylene)]bis-2-propenoate, diethyl-2,2′-[oxybis(methylene)]bis-2-propenoate, di(n-propyl)-2,2′-[oxybis(methylene)]bis-2-propenoate, di(isopropyl)-2,2′-[oxybis(methylene)]bis-2-propenoate, di(n-butyl)-2,2′-[oxybis(methylene)]bis-2-propenoate, di(isobutyl)-2,2′-[oxybis(methylene)]bis-2-propenoate, di(t-butyl)-2,2′-[oxybis(methylene)]bis-2-propenoate, di(t-amyl)-2,2′-[oxybis(methylene)]bis-2-propenoate, di(stearyl)-2,2′-[oxybis(methylene)]bis-2-propenoate, di(lauryl)-2,2′-[oxybis(methylene)]bis-2-propenoate, di(2-ethylhexyl)-2,2′-[oxybis(methylene)]bis-2-propenoate, di(1-methoxyethyl)-2,2′-[oxybis(methylene)]bis-2-propenoate, di(1-ethoxyethyl)-2,2′-[oxybis(methylene)]bis-2-propenoate, dibenzyl-2,2′-[oxybis(methylene)]bis-2-propenoate, diphenyl-2,2′-[oxybis(methylene)]bis-2-propenoate, dicyclohexyl-2,2′-[oxybis(methylene)]bis-2-propenoate, di(t-butylcyclohexyl)-2,2′-[oxybis(methylene)]bis-2-propenoate, di(dicyclopentadienyl)-2,2′-[oxybis(methylene)]bis-2-propenoate, di(tricyclodecanyl)-2,2′-[oxybis(methylene)]bis-2-propenoate, di(isobornyl)-2,2′-[oxybis(methylene)]bis-2-propenoate, diadamantyl-2,2′-[oxybis(methylene)]bis-2-propenoate, and di(2-methyl-2-adamantyl)-2,2′-[oxybis(methylene)]bis-2-propenoate.

Among these, dimethyl-2,2′-[oxybis(methylene)]bis-2-propenoate, diethyl-2,2′-[oxybis(methylene)]bis-2-propenoate, dicyclohexyl-2,2′-[oxybis(methylene)]bis-2-propenoate, and dibenzyl-2,2′-[oxybis(methylene)]bis-2-propenoate are particularly preferable.

The ether dimer may be used alone or as a combination of two or more types. The structural body derived from a compound represented by Formula (ED) may be copolymerized with other monomers.

In order to improve crosslinking efficiency of the radiation-sensitive composition, an alkali soluble resin having a polymerizable group may be used.

As an alkali soluble resin having a polymerizable group, an alkali soluble resin having an allyl group, a (meth)acryloyl group, or an allyloxyalkyl group in a side chain is useful. Examples of the polymer having a polymerizable group include DIANAL NR series (trade name, manufactured by Mitsubishi Rayon Co., Ltd.), PHOTOMER 6173 (trade name, COOH-containing polyurethane acrylic oligomer, manufactured by Diamond Shamrock Co. Ltd.), VISCOAT R-264 and KS RESIST 106 (trade names, manufactured by Osaka Organic Chemical Industry Ltd.), CYCLOMER P series and PLACCEL CF200 series (trade names, manufactured by Daicel Chemical Industries, Ltd.) and EBECRYL 3800 (trade name, manufactured by Daicel-UCB Co., Ltd.). Examples of the alkali soluble resin having a polymerizable group include a urethane-modified acrylic resin including a polymerizable double bond, which is obtained by reacting a compound in which an isocyanate group has been reacted with an OH group in advance, in such a manner that one isocyanate group is left unreacted, and having a (meth)acryloyl group, with an acrylic resin including a carboxyl group; an acrylic resin including an unsaturated group, which is obtained by reacting an acrylic resin including a carboxyl group with a compound having an epoxy group and a polymerizable double bond in the molecule; an acid pendant-type epoxy acrylate resin; an acrylic resin including a polymerizable double bond, which is obtained by reacting an acrylic resin including an OH group with a dibasic acid anhydride having a polymerizable double bond; a resin obtained by reacting an acrylic resin including an OH group with a compound having an isocyanate group and a polymerizable group, and a resin obtained by performing a basic treatment of a resin having an ester group in a side chain, wherein the ester group has a halogen group or a leaving group such a sulfonate group at the α position or the β position, as described in JP-A Nos. 2002-229207 and 2003-335814.

As an example of the alkali soluble resin, a benzyl (meth)acrylate/(meth)acrylic acid copolymer or a multi-component copolymer formed of benzyl (meth)acrylate/(meth)acrylic acid/other monomer are preferable. Other examples of the alkali soluble resin include a copolymer including 2-hydroxyethyl methacrylate, a copolymer of 2-hydroxypropyl (meth)acrylate/polystyrene macromonomer/benzyl methacrylate/methacrylic acid, a copolymer of 2-hydroxy-3-phenoxypropylacrylate/polymethyl methacrylate macromonomer/benzyl methacrylate/methacrylic acid, a copolymer of 2-hydroxyethyl methacrylate/polystyrene macromonomer/methyl methacrylate/methacrylic acid, and a copolymer of 2-hydroxyethyl methacrylate/polystyrene macromonomer/benzyl methacrylate/methacrylic acid copolymer, which are described in JP-A No. 7-140654.

The acid value of the alkali soluble resin is preferably from 30 mgKOH/g to 200 mgKOH/g, more preferably from 50 mgKOH/g to 150 mgKOH/g, and still more preferably from 70 mgKOH/g to 120 mgKOH/g.

The weight average molecular weight (Mw) of the alkali soluble resin is preferably from 2,000 to 50,000, more preferably from 5,000 to 30,000, and still more preferably from 7,000 to 20,000.

The content of the alkali soluble resin in the radiation-sensitive composition is preferably from 1% by mass to 60% by mass, more preferably from 2% by mass to 50% by mass, further preferably from 3% by mass to 40% by mass, with respect to the total solid content of the composition.

Specific examples of the alkali soluble resin used as a binder polymer include following resins (E-1) to (E-8). However, the invention is not limited to these resins. The numerical values attached to each unit refer to the molar fraction of the unit.

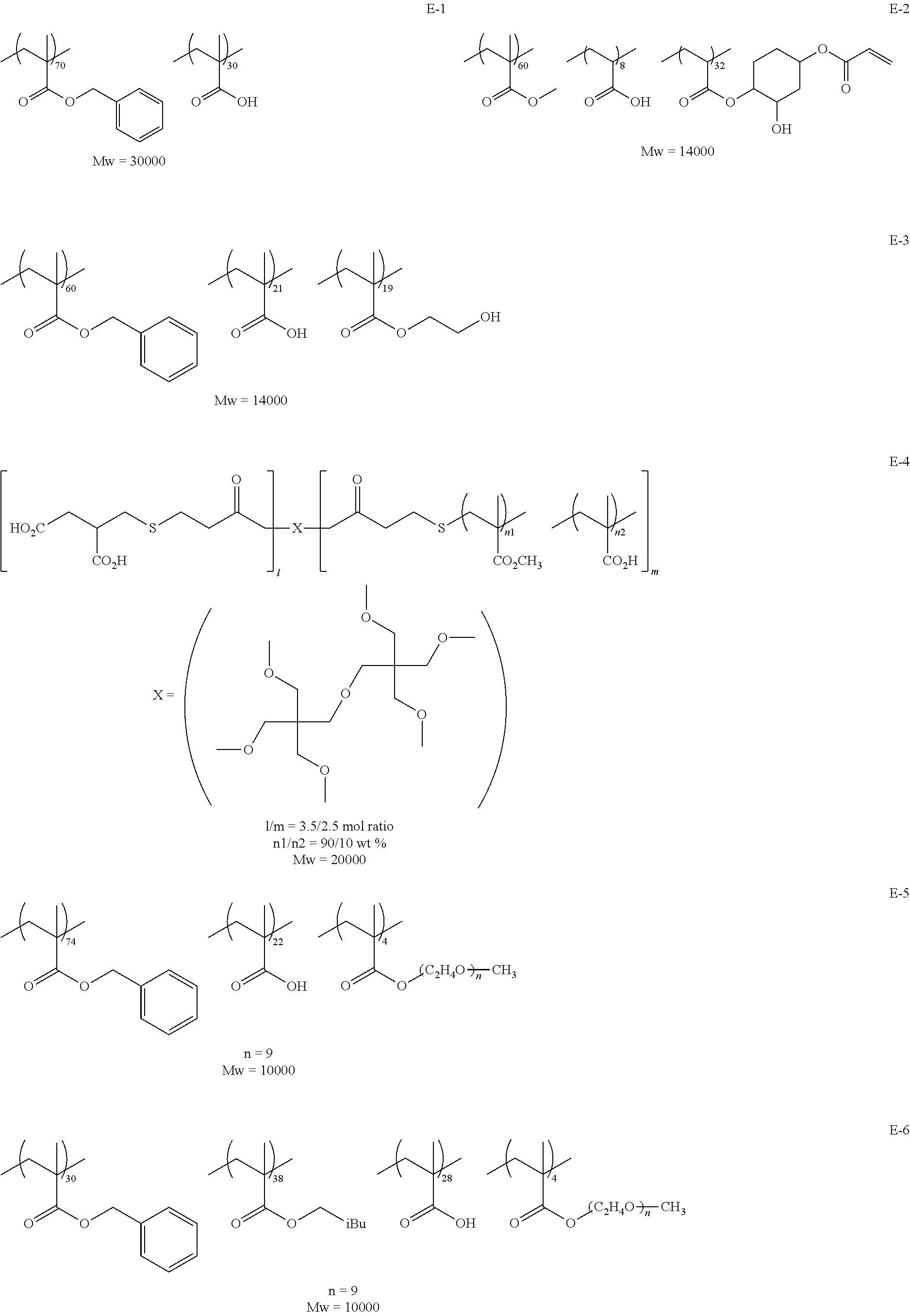

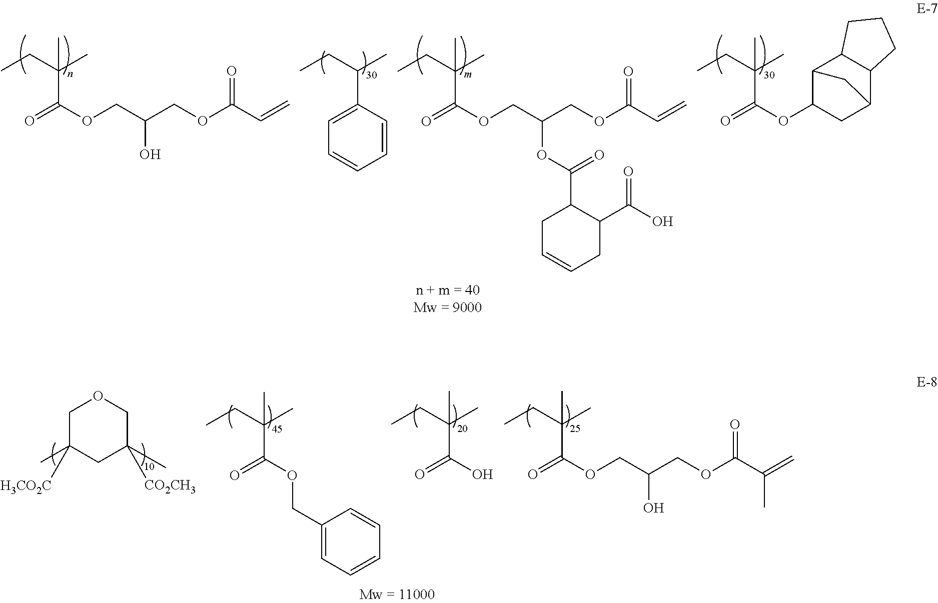

Additives

The radiation-sensitive composition may include other additives such as a surfactant, an adhesion promoter, a polymerization inhibitor, a UV absorber, an antioxidant or an aggregation inhibitor, to such an amount that the properties of a film obtained from the composition (such as heat resistance, mechanical strength, coatability and adhesion) are not impaired.

<Surfactant>

The radiation-sensitive composition may include a surfactant in view of improving coatability. Examples of the surfactant include a fluorinated surfactant, a nonionic surfactant, a cationic surfactant, an anionic surfactant and a silicone surfactant.

In particular, when the radiation-sensitive composition includes a fluorinated surfactant, liquid properties (in particular, fluidity) of the composition can be further improved when the composition is prepared as a coating liquid. Therefore, uniformity in coating thickness can be improved and the amount of the coating liquid to use can be reduced.

More specifically, when a film is formed from a coating liquid prepared from the radiation-sensitive composition including a fluorinated surfactant, the interfacial tension between the coating liquid and a surface of a substrate to be coated is lowered, whereby wettability with respect to the substrate and coatability of the composition are improved. Therefore, a coating layer having a uniform thickness can be formed with a small amount of the coating liquid, even if the thickness of the coating layer is only a few micrometers.

The fluorine content of the fluorinated surfactant is preferably from 3% by mass to 40% by mass, more preferably from 5% by mass to 30% by mass, and still more preferably from 7% by mass to 25% by mass. When the fluorine content is within the range, sufficient effects of obtaining a uniform thickness of a coating layer and reducing the amount of the coating liquid can be achieved. In addition, sufficient solubility in the radiation-sensitive composition can be obtained.

Examples of the fluorinated surfactant include MEGAFAC F171, MEGAFAC F172, MEGAFAC F173, MEGAFAC F176, MEGAFAC F177, MEGAFAC F141, MEGAFAC F142, MEGAFAC F143, MEGAFAC F144, MEGAFAC R30, MEGAFACK F437, MEGAFAC F475, MEGAFAC F479, MEGAFAC F482, MEGAFAC F554, MEGAFAC F780, MEGAFAC F781 (trade names, all manufactured by DIC Corporation), FLUORAD FC430, FLUORAD FC431, FLUORAD FC171 (trade names, all manufactured by Sumitomo 3M Limited), and SURFLON S-382, SURFLON SC-101, SURFLON SC-103, SURFLON SC-104, SURFLON SC-105, SURFLON SC-1068, SURFLON SC-381, SURFLON SC-383, SURFLON 5393, SURFLON KH-40 (trade names, all manufactured by Asahi Glass Co., Ltd.)

Specific examples of the nonionic surfactant include glycerol, trimethylol propane, trimethylol ethane, and ethoxylates and propoxylates thereof (for example, glycerol propoxylate and glycerin ethoxylate), polyoxyethylene lauryl ether, polyoxyethylene stearyl ether, polyoxyethylene oleyl ether, polyoxyethylene octylphenyl ether, polyoxyethylene nonylphenyl ether, polyethylene glycol dilauate, polyethylene glycol distearate, and sorbitan fatty acid esters (trade names: PLURONIC L10, L31, L61, L62, 10R5, 17R2, 25R2, TETRONIC 304, 701, 704, 901, 904, 150R1, all manufactured by BASF Japan) and SOLSPERSE 20000 (trade name, manufactured by The Lubrizol Corporation).

Specific examples of the cationic surfactant include phthalocyanine derivative EFKA-745 (trade name, manufactured by BASF Japan), organosiloxane polymer KP341 (manufactured by Shin-Etsu Chemical Co., Ltd.), (meth)acrylic acid (co)polymers POLYFLOW 75, No. 90, and No. 95 (trade names, manufactured by Kyoeisha Chemical Co., Ltd.) and W001 (trade name, available from Yusho Co Ltd.).

Specific examples of the anionic surfactant include W004, W005, and W017 (trade names, available from Yusho Co Ltd.).

Examples of the silicone surfactant include TORAY SILICONE DC3PA, TORAY SILICONE SH7PA, TORAY SILICONE DC11PA, TORAY SILICONE SH21PA, TORAY SILICONE SH28PA, TORAY SILICONE SH29PA, TORAY SILICONE SH30PA, TORAY SILICONE SH8400 (trade names, all manufactured by Dow Corning Toray Co., Ltd.), TSF-4440, TSF-4300, TSF-4445, TSF-4460, TSF-4452 (trade names, all manufactured by Momentive Performance Materials Inc.), KP341, KF6001, KF6002 (trade names, all manufactured by Shin-Etsu Silicone), and BYK307, BYK323, BYK330 (trade names, all manufactured by BYK-Chemie GmbH). The surfactant may be used singly, or as a combination of two or more kinds thereof

The radiation-sensitive composition may not include a surfactant. However, if it includes a surfactant, the content of the surfactant is preferably from 0.001% by mass to 2.0% by mass, more preferably from 0.005% by mass to 1.0% by mass, with respect to the total mass of the radiation-sensitive composition.

<Adhesion Promoter>

The radiation-sensitive composition may include an adhesion promoter to such an extent that the effect of the invention is not impaired. Examples of the adhesion promoter include 3-glycidyloxypropyltrimethoxysilane, 1-methacryloyloxypropylmethyldimethoxysilane, 2-aminoglycidyloxypropyltriethoxysilane, 3-glycidyloxypropylmethyldimethoxysilane and 3-aminoipropyltrimethoxysilane. Other examples include compounds described in [0048] of JP-A No. 2008-243945.

The radiation-sensitive composition may not include an adhesion promoter. However, if it includes an adhesion promoter, the amount of the adhesion promoter is preferably 10% by mass or less, more preferably from 0.005% by mass to 5% by mass, with respect to the total solid content of the composition, although it is not particularly restricted.

Polymerization Inhibitor

The radiation-sensitive composition may include a small amount of a polymerization inhibitor in order to prevent unnecessary heat polymerization of the polymerizable compound during the manufacture or the storage of the radiation-sensitive composition.

Examples of the polymerization inhibitor that can be used in the invention include hydroquinone, p-methoxyphenol, di-t-butyl-p-cresol, pyrogallol, t-butyl catechol, benzoquinone, 4,4′-thiobis(3-methyl-6-t-butylphenol), 2,2′-methylenebis(4-methyl-6-t-butylphenol) and a N-nitrosophenylhydroxylamine cerium salt.

The amount of the polymerization inhibitor is preferably from about 0.01% by mass to about 5% by mass with respect to the total solid content in the radiation-sensitive composition.

<UV Absorber>

The radiation-sensitive composition preferably include a UV absorber. In that case, a pattern having a more favorable (fine) can be formed.

Examples of the UV absorber include salicylate compounds, benzophenone compounds, benzotriazole compounds, substituted acrylonitrile compounds and triazine compounds.

Examples of the salicylate UV absorbers include phenyl salicylate, p-octyl salicylate, and p-t-butylphenyl salicylate. Examples of the benzophenone UV absorbers include 2,2′-dihydroxy-4-methoxybenzophenone, 2,2′-dihydroxy-4,4′-dimethoxybenzophenone, 2,2′, 4,4′-tetrahydroxybenzophenone, 2-hydroxy-4-methoxybenzophenone, 2,4-dihydroxybenzophenone, and 2-hydroxy-4-octoxybenzophenone. Examples of the benzotriazole UV absorbers include 2-(2′-hydroxy-3′,5′-di-tert-butylphenyl)-5-chlorobenzotriazole, 2-(2′-hydroxy-3′-tert-butyl-5′-methylphenyl)-5-chlorobenzotriazole, 2-(2′-hydroxy-3′-tert-amyl-5′-isobutylphenyl)-5-chlorobenzotriazole, 2-(2′-hydroxy-3′-isobutyl-5′-methylphenyl)-5-chlorobenzotriazole, 2-(2′-hydroxy-3′-isobutyl-5′-propylphenyl)-5-chlorobenzotriazole, 2-(2′-hydroxy-3′,5′-di-tert-butyl)benzotriazole, 2-(2′-hydroxy-5′-methylphenyl)benzotriazole and 2-[2′-hydroxy-5′-(1,1,3,3-tetramethyephenyl]benzotriazole.

Examples of the substituted acrylonitrile UV absorbers include ethyl 2-cyano-3,3-diphenylacrylate and 2-ethylhexyl 2-cyano-3,3-diphenylacrylate. Examples of the triazine UV absorbers include mono(hydroxyphenyl)triazine compounds such as 2-[4-[(2-hydroxy-3-dodecyloxypropyl)oxy]-2-hydroxyphenyl]-4,6-bis(2,4-dimethylphenyl)-1,3,5-triazine, 2-[4-[(2-hydroxy-3-tridecyloxypropyl)oxy]-2-hydroxyphenyl]-4,6-bis(2,4-dimethylphenyl)-1,3,5-triazine and 2-(2,4-dihydroxyphenyl)-4,6-bis(2,4-dimethylphenyl)-1,3,5-triazine; bis(hydroxyphenyl)triazine compounds such as 2,4-bis(2-hydroxy-4-propyloxyphenyl)-6-(2,4-dimethylphenyl)-1,3,5-triazine, 2,4-bis(2-hydroxy-3-methyl-4-propyloxyphenyl)-6-(4-methylphenyl)-1,3,5-triazine and 2,4-bis(2-hydroxy-3-methyl-4-hexyloxyphenyl)-6-(2,4-dimethylphenyl)-1,3,5-triazine; and tris(hydroxyphenyl)triazine compounds such as 2,4-bis(2-hydroxy-4-butoxyphenyl)-6-(2,4-dibutoxyphenyl)-1,3,5-triazine, 2,4,6-tris(2-hydroxy-4-octyooxyphenyl)-1,3,5-triazine and 2,4,6-tris[2-hydroxy-4-β-butoxy-2-hydroxypropyloxy)phenyl]-1,3,5-triazine.

The following are specific examples of the UV absorbers. However, the invention is not limited to these examples.

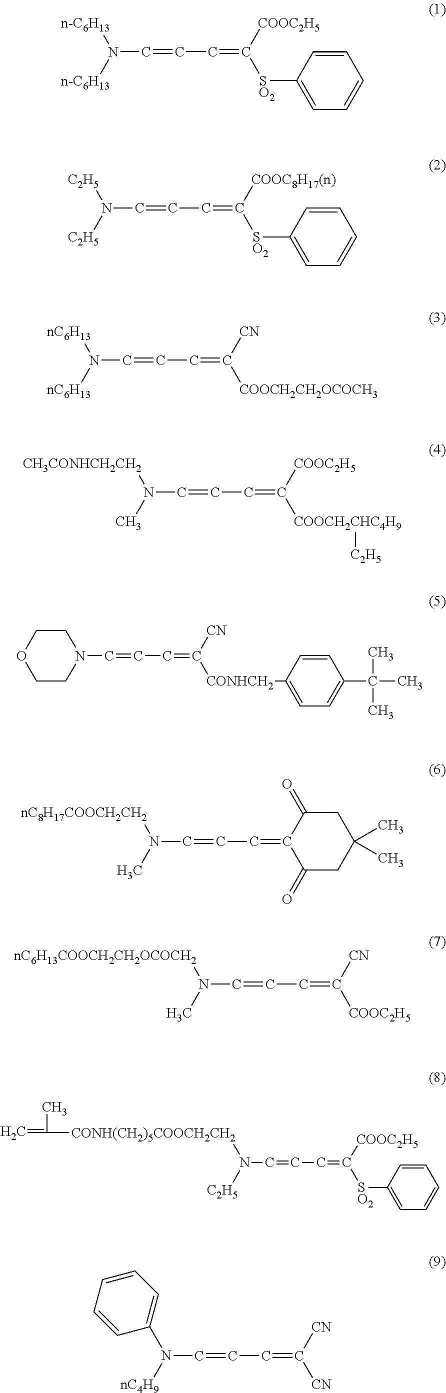

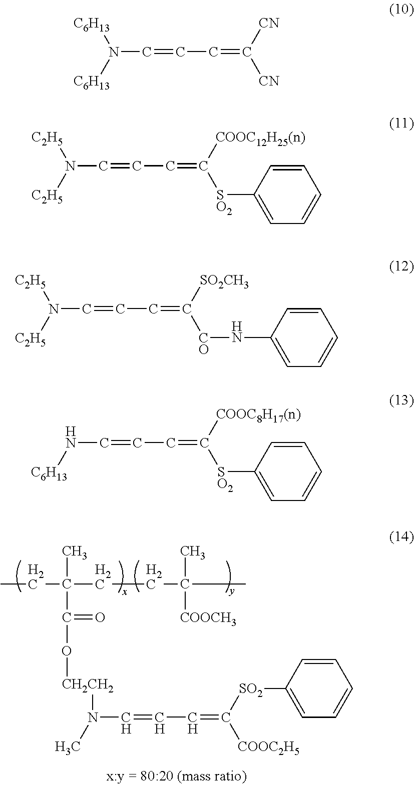

In the invention, the UV absorber may be used alone or in a combination of two or more kinds.

The radiation-sensitive composition may not include a UV absorber. However, if it includes a UV absorber, the content of the UV absorber is preferably from 0.001% by mass to 15% by mass, more preferably from 0.01% by mass to 15% by mass, with respect to the total solid content of the radiation-sensitive composition.

The radiation-sensitive composition preferably satisfies that a cured film obtained from the radiation-sensitive composition has a refraction index of from 1.55 to 1.90 with respect to light having a wavelength of 500 nm.

The radiation-sensitive composition is preferably a transparent composition. More specifically, it is preferred that a cured film having a thickness of 0.6 μm obtained from the radiation-sensitive composition exhibits a light transmission in a thickness direction of 85% or more in the whole wavelength range of from 400 nm to 700 nm.

When the cured film exhibits a light transmission in a thickness direction of 85% or more in the whole wavelength range of from 400 nm to 700 nm, pixels for a white filter included in a color filter can sufficiently function as pixels for a white color filter (i.e., imaging can be carried out with an image sensor at high sensitivity).

The light transmission in the whole wavelength range of from 400 nm to 700 nm is more preferably 90% or more, further preferably 95% or more, yet further preferably 100%.

The radiation-sensitive composition includes substantially no colorant (i.e., the content of a colorant is preferably 0% by mass with respect to the total solid content of the composition). The titanium dioxide particles, inorganic particles that may be used in combination and UV absorbers are not included in the colorant as mentioned herein.

The radiation-sensitive composition is used for solid-state image sensors, preferably for forming pixels of a color filter of solid-state image sensors. More specifically, the radiation-sensitive composition is preferably used for forming white filter pixels of a color filter for solid-state imaging sensors.

The content of metal as impurities in the radiation-sensitive composition is preferably sufficiently small. The concentration of metal in the composition can be measured at high sensitivity by an ICP-MS method or the like. In that case, the content of the meal other than transition metals is preferably 300 ppm or less, more preferably 100 ppm or less.

The method of producing the radiation-sensitive composition is not particularly restricted. For example, the radiation-sensitive composition may be produced by adding the components to an organic solvent and agitating the same.

The radiation-sensitive composition is preferably filtrated with a filter in order to remove foreign matters and reducing defects. The filer is not restricted and may be selected from those commonly used for the purpose of filtration.

Examples of the material for the filter include fluorine resins such as PTFE (polytetrafluoroethylene); polyamide resins such as nylon-6 and nylon-6,6; polyolefin resins such as polyethylene and polypropylene (PP), including high-density polyolefins and ultra high molecular weight polyolefins. Among these, polypropylene (including high density polypropylene) is preferred.

The pore size of the filter is not particularly restricted. For example, the pore size may be approximately from 0.01 μm to 20.0 μm, preferably approximately from 0.01 μm to 5.0 μm, further preferably approximately from 0.01 μm to 2.0 μm.

By adjusting the pore size of the filter to the above range, fine particles can be removed more effectively, and turbidness can be further reduced.

The pore size of the filter may be nominal size from the filter manufacturers. Commercially available filters may be selected from those provided from Pall Corporation, Advantec Group, Nihon Entegris K.K. (previously Mykrolis Corporation) and Kitz Micro Filter Corporation.

The filtration may be performed with a combination of two or more kinds of filters. For example, filtration may include a first filtration with a first filter and a second filtration with a second filter that has a different pore size from that of the first filter. In that case, each filtration may be performed once or more.

The second filter may be made of a material similar to that of the first filter.

Pattern Formation Method, Color Filter and Method of Producing Color Filter

In the following, the pattern formation method, the color filter and the method of producing the color filter will be described.

The pattern formation method according to the invention includes forming a coating layer (radiation-sensitive composition layer) by applying the radiation-sensitive composition onto a substrate (hereinafter, also referred to as a “radiation-sensitive composition layer-forming step”), exposing the coating layer to light (hereinafter, also referred to as an “exposure step”), and developing the coating layer to form a pattern (hereinafter, also referred to as a “development step”) and thereby obtaining a patterned cured film.

The pattern formation method may be suitably applied to formation of pixels for a color filter for solid-state image sensors.

The substrate on which a pattern is formed by the pattern formation method is not particularly restricted as long as a pattern can be formed thereon, and may be an object other than a plate object such as a substrate.

The steps included in the pattern formation method will be described later through the method of producing a color filter according to the present invention.

The method of producing a color filter according to the present invention adopts the pattern formation method according to the present invention, and includes forming a patterned cured film on a substrate by the pattern formation method.

The method of producing a color filter of solid-state imaging sensors (hereinafter, also referred to as a “color filter for solid-state imaging sensors”) according to the present invention includes applying the radiation-sensitive composition to a substrate to form a coating layer (radiation-sensitive composition layer); exposing the coating layer to light; and developing the exposed coating layer to form a pattern, thereby obtaining a cured film as white filter pixels in a color filter of solid-state imaging sensors.

That is, the method of producing a color filter according to the present invention (hereinafter, also referred to as “the production method according to the present invention”) includes applying the radiation-sensitive composition onto a substrate to form a coating layer (radiation-sensitive composition layer); exposing the coating layer to light (the exposure step); and developing the exposed coating layer to form a pattern (the development step), thereby obtaining a patterned cured film.

The color filter according to the present invention is obtained by the method as described above.

The color filter at least includes a transparent (white) pattern (white filter pixels) that is formed from the radiation-sensitive composition.

Specific embodiments of the color filter include a multicolor filter in which a transparent pattern (white filter pixels) and patterns of different colors are combined (for example, a color filter of four or more colors that includes at least a transparent pattern, a red pattern, a blue pattern and a green pattern).

<Radiation-Sensitive Composition Layer Formation Step>

In the radiation-sensitive composition layer formation step, it is preferred to form a radiation-sensitive composition layer by applying the radiation-sensitive composition onto a substrate.

Examples of the substrate that can be used in this step include a substrate for solid-state imaging sensors, which has an imaging element (light-receiving element) such as CCD (Charge Coupled Device) or CMOS (Complementary Metal-Oxide Semiconductor) provided on a support (such as a silicon support).

The transparent pattern obtained by the present invention may be formed on the side on which the imaging element is formed (upper surface) of the substrate for a solid-state imaging device, or on the side on which the imaging element is not formed (back surface).

A light-shading film may be provided between the imaging elements or on the back surface of the substrate.

Further, an undercoat layer may be provided on the substrate in order to improve the adhesion with respect to the upper layer, prevent diffusion of substances, or level the substrate surface.

Application of the radiation-sensitive composition to the substrate may be carried out by a method such as slit coating, ink-jetting, spin coating, cast coating, roll coating or screen printing.

The thickness of the radiation-sensitive composition layer is preferably from 0.1 μm to 10 μm, more preferably from 0.2 μm to 5 μm, still more preferably from 0.2 μm to 3 μm.

The radiation-sensitive composition layer that has been formed on the substrate may be dried (pre-baked) with a hot plate, an oven or the like, at a temperature of from 50° C. to 140° C. for from 10 seconds to 300 seconds.

<Exposure Step>

In the exposure step, the radiation-sensitive composition layer that has been formed in the radiation-sensitive composition layer formation step is subjected to pattern exposure via a mask having a desired pattern with an exposure apparatus such as a stepper.

The radiation (light) that can be used for the exposure includes visible light, ultraviolet ray, far ultraviolet ray, electron beam, X-ray or the like. Ultraviolet ray such as g-line or i-line is preferably employed, and i-line is particularly preferred. The dose of irradiation (exposure dose) is preferably from 30 mJ/cm² to 1,500 mJ/cm², more preferably from 50 mJ/cm² to 1,000 mJ/cm², further preferably from 80 mJ/cm² to 500 mJ/cm².

<Development Step>

Subsequent to the exposure, an alkali development treatment is performed. In this step, unexposed portions of the radiation-sensitive composition layer elute into an aqueous alkaline solution, while cured portions remain on the substrate.

The developer is preferably an organic alkali developer that does not affect the underlying imaging device, circuit or the like. The development temperature is usually from 20° C. to 30° C. The development time has been conventionally between 20 seconds to 90 seconds. However, in order to remove residues more effectively, there are cases in recent years in which development is performed for from 120 seconds to 180 seconds. In order to remove residues more effectively, there are cases in which the development is repeated while supplying a fresh developer ever 60 seconds.

Examples of alkali agent used for the developer include organic alkaline compounds such as aqueous ammonia, ethylamine, diethylamine, dimethylethanolamine, tetramethylammonium hydroxide, tetraethylammonium hydroxide, choline, pyrrole, piperidine and 1,8-diazabicyclo-[5,4,0]-7-undecene. A developer prepared by diluting the alkali agent with pure water to a concentration of from 0.001% by mass to 10% by mass, preferably from 0.01% by mass to 1% by mass, is suitably used.

An inorganic alkali may be used for the developer. Preferred examples of the inorganic alkali include sodium hydroxide, potassium hydroxide, sodium carbonate, sodium bicarbonate, sodium silicate and sodium metasilicate.

In a case in which a developer composed of an aqueous alkaline solution is used, rinsing is typically carried out after the development with pure water.

After the development and the subsequent drying, it is preferred to perform a heat treatment (post-baking). In a case in which a multicolor pattern is formed, the aforementioned steps are repeated for the number of colors to form a cured film of each color. A color filter is thus obtained.

The post-baking is a heat treatment that is performed after the development for the purpose of attaining complete curing. The heat treatment is carried out at a temperature of usually from 100° C. to 240° C., preferably from 200° C. to 240° C.

The post-baking treatment can be performed continuously or batchwise with a heating means such as a hot plate, a convection oven (hot-air circulation-type dryer) or a high-frequency heater under the above-described conditions.

The method of producing a color filter may include other known steps that may be included in a method of producing a color filter for solid-state imaging sensors. For example, after the steps of forming the radiation-sensitive composition layer, exposure and development, a step of curing the obtained transparent pattern by heat and/or light may be included as necessary.

In the process of using the radiation-sensitive composition according to the present invention, problems such as clogging of the nozzle of a discharge outlet or a piping of a coating apparatus or contamination caused by adhesion, precipitation or drying of the radiation-sensitive composition or inorganic particles in the coating apparatus may occur. In order to efficiently wash off the contamination caused by the radiation-sensitive composition, it is preferred to use the solvent as described above that may be used in the radiation-sensitive composition as a cleaning solution. It is also suitable to use the cleaning solutions described in JP-A No. 7-128867, JP-A No. 7-146562, JP-A No. 8-278637, JP-A No. 2000-273370, JP-A No. 2006-85140, JP-A No. 2006-291191, JP-A No. 2007-2101, JP-A No. 2007-2102, JP-A No. 2007-281523 and the like.

Among the cleaning solutions as described in the above, alkylene glycol monoalkyl ether carboxylate and alkylene glycol monoalkyl ether are preferred.

The solvent may be used alone, or two or more thereof may be used in combination. In a case in which two or more solvents are used in combination, it is preferred to mix a solvent having a hydroxy group and a solvent having no hydroxy group. The mass ratio of the solvent having a hydroxy group and the solvent having no hydroxy group may be from 1/99 to 99/1, preferably from 10/90 to 90/10, more preferably from 20/80 to 80/20. A mixed solvent of propylene glycol monomethyl ether acetate (PGMEA) and propylene glycol monomethyl ether (PGME), at a mixing ratio of 60/40, is particularly preferred. In order to improve the permeability with respect to contaminants, the cleaning solution may include the surfactant as described above that may be included in the radiation-sensitive composition.

With an image sensor in which the color filter according to the present invention is installed, imaging can be performed at high sensitivity and high quality.

The color filter for solid-state imaging sensors can be suitably used in solid-state imaging sensors such as CCD and CMOS. The color filter is particularly suitable for high-resolution CCD, CMOS and the like that has more than 1,000,000 pixels. The color filter can be used as, for example, a color filter disposed between a light-receiving section of each pixel that constitutes the CCD or CMOS and a light-collecting microlens.

The thickness of the color pattern (color pixel) in the color filter for solid-state imaging sensors is preferably not greater than 2.0 μm, more preferably not greater than 1.0 μm. The term “color” used herein for the color pattern (color pixels) encompasses transparent (white).

Further, the size (pattern width) of the color pattern (color pixels) is preferably not greater than 2.5 μm, more preferably not greater than 2.0 μm, particularly preferably not greater than 1.7 μm.

Solid-State Imaging Sensor

The solid-state imaging sensor according to the invention is equipped with the color filter according to the present invention.

The constitution of the solid-state imaging sensor is not particularly restricted as long as it includes the color filter according to the present invention and functions as a solid-state imaging sensor.

An example of the constitution of the solid-state imaging sensor includes plural photodiodes and transfer electrodes made of polysilicon etc. that constitute a light-receiving area of the solid-state imaging sensor (such as a CCD image sensor or CMOS image sensor) on a substrate; a light-shading film made of tungsten etc. provided on the above-described photodiodes and the transfer electrodes, the light-shading film having openings at positions corresponding to the light-receiving portions of the photodiodes; a device protection film made of silicon nitride etc. provided on the light-shading film in such a manner to cover the entire surface of the light-shading film and the light-receiving portions of the photodiodes; and the color filter according to the present invention provided on the device protection film.

The solid-state imaging sensor may also have, for example, a constitution in which a light-collecting means (such as a microlens) is provided between the device protection layer and the color filter (closer to the substrate), or a constitution in which a light-collecting means is provided on the color filter.

### EXAMPLES

In the following, the invention will be described in more details with reference to the examples. However, the invention is not limited to these examples. Unless otherwise specified, “parts” and “%” are based on mass.

### Example 1

### (1) Preparation of Titanium Dioxide Dispersion 1-1

A mixture having the following composition A was subjected to a dispersion treatment with a circulation-type dispersing machine (bead mill), ULTRA APEX MILL (trade name, manufactured by Kotobuki Industries Co., Ltd.).

<Composition A>

| | | |
|---|---|---|
| Titanium dioxide (TTO-51 (C), trade name, | 12.5 | parts |
| manufactured by Ishihara Sangyo Kaisha, Ltd.) | | |
| Specific dispersing resin (A) (20% solution of propylene | 86. | parts |
| glycol monomethyl ether acetate (PGMEA), following | | |
| structure) | | |
| PGMEA | 350.6 | parts |

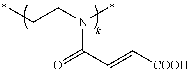

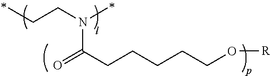

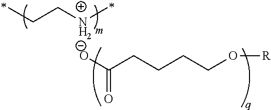

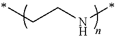

R = COC₇H₁₅
Specific dispersing resin (A)

In Specific dispersing resin (A), k:l:m:n is 25:40:5:30 (polymerization molar ratio), p is 60, q is 60 and the weight average molecular weight is 10,000.

The dispersing machine was operated under the following conditions.

Bead diameter: 0.05 mm

Bead filling rate: 75% by volume

Circumferential velocity: 8 m/sec

Pump supply rate: 10 kg/hour

Cooling water: tap water

Volume of circular path of bead mill: 0.15 L

Amount of mixture to be dispersed: 0.44 kg

The projected areas of 300 titanium dioxide particles included in the obtained titanium dioxide dispersion 1-1 were measured with a transmission electron microscope. The arithmetic average of the equivalent circle diameters of the measured projected areas was 40 nm.

### (2) Preparation of Radiation-Sensitive Composition

A radiation-sensitive composition having the following composition was prepared.

<Composition of radiation-sensitive composition>

| | | |
|---|---|---|
| Titanium dioxide dispersion (prepared above, | 22.1 | parts |
| dispersion composition) | | |
| Polymerizable compound (A) (following structure) | 4.7 | parts |
| Photopolymerization initiator (oxime compound having | 0.9 | parts |
| the following structure, IRGACURE OXE-02, trade name, | | |
| manufactured by BASF Japan) | | |
| Binder polymer (A) (having the following structure, | 13.6 | parts |
| 20% PGMEA solution) | | |
| Ultraviolet absorber (A) (following structure) | 1.4 | parts |
| Surfactant (fluorine-surfactant, 1% PGMEA solution, | 2.5 | parts |
| MEGAFAC F-781, trade name, manufactured by | | |
| DIC Corporation) | | |
| PGMEA | 54.8 | parts |

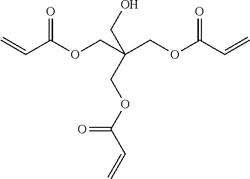 [SMILES: C=CC(=O)OCC(CO)(COC(=O)C=C)COC(=O)C=C]

Polymerizable compound (A) 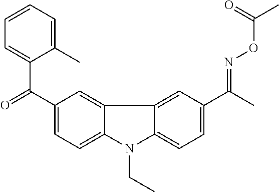 [SMILES: CCn1c2ccc(C(=O)c3ccccc3C)cc2c2cc(/C(C)=N/OC(C)=O)ccc21]
IRGACURE OXE-02 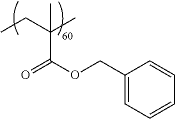 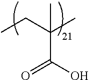 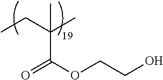
Binder polymer (A) (acid value: 79 mg/KOH, Mw = 14,000) 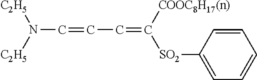
Ultraviolet absorber (A)

### Examples 2 to 24 and Comparative Examples 1 to 32

Titanium dioxide dispersions 1-2 to 1-24, which were used in Examples 2 to 24, and titanium dioxide dispersions 1C to 32C, which were used in Comparative Examples 1 to 32, were prepared in a manner substantially similar to the preparation of titanium dioxide dispersion 1-1 in Example 1, except that the dispersing resins shown in the following Table 1 were used instead of dispersing resin (A).

Radiation-sensitive composition 1 to 24 for Examples 1 to 24 and radiation-sensitive compositions 1C to 32C for Comparative Examples 1 to 32 were prepared in a manner substantially similar to Example 1, except that the titanium dioxide dispersions obtained above were used and that the polymerizable compound and the binder polymer were changed as shown in Tables 1 and 2.

### Example 25

Titanium dioxide dispersion 2 was prepared in a manner substantially similar to Example 1, except that the mixture of composition A, prepared in the preparation of titanium dioxide dispersion 1-1 for Example 1, was changed to a mixture of the following composition B.

<Composition B>

| | |
|---|---|
| Titanium dioxide (TTO-51 (C), trade name, manufactured | 212.5 parts |
| by Ishihara Sangyo Kaisha, Ltd.) | |
| Specific dispersing resin (A) (20% PGMEA solution) | 286.9 parts |
| PGMEA | 350.6 parts |
| Cyclohexanone | 248.7 parts |

Radiation-sensitive composition 25 was prepared in a manner substantially similar to Example 1, except that titanium dioxide dispersion 1-1, which was used in the preparation of radiation-sensitive composition 1 of Example 1, was changed to titanium dioxide dispersion 2 obtained above, and that PGMEA was changed to cyclohexanone.

The content of cyclohexanone in the organic solvent included in the radiation-sensitive composition of Example 25 was approximately 70%.

### Example 26

Radiation-sensitive composition 26 was prepared in a manner substantially similar to Example 1, except that titanium dioxide dispersion 1-1, which was used in the preparation of radiation-sensitive composition 1 of Example 1, was changed to titanium dioxide dispersion 2 prepared in Example 25, and that PGMEA was changed to a mixture of PGMEA/cyclohexanone (75%/25%).

The content of cyclohexanone in the organic solvent included in the radiation-sensitive composition of Example 26 was approximately 20%.

Details of specific dispersion resin (B), specific dispersing resin (C), comparative dispersing resin (A), comparative dispersing resin (B), polymerizable compound (B), polymerizable compound (C) and binder polymer (B) are shown below.

DPHA, used as a polymerizable compound, refers to dipentaerythritol hexaacrylate (KAYARAD DPHA, trade name, manufactured by Nippon Kayaku Co., Ltd.)

DISPERBYK 101 (trade name), used as a dispersant in Comparative Examples 13 to 18, refers to a phosphoric acid salt of polyamideamine, manufactured by BYK Japan K.K.

SOLSPERSE-5000 (trade name), used as a dispersant in Comparative Example 19 to 24, refers to a phthalocyanine derivative manufactured by the Lubrizol Corporation.

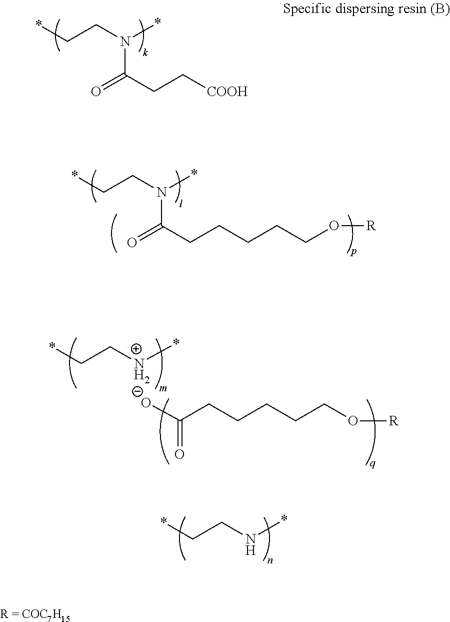

In specific dispersing resin (B), k:l:m:n is 25:40:53:0 (polymerization molar ratio), p is 60, q is 60 and the weight-average molecular weight is 11,000.

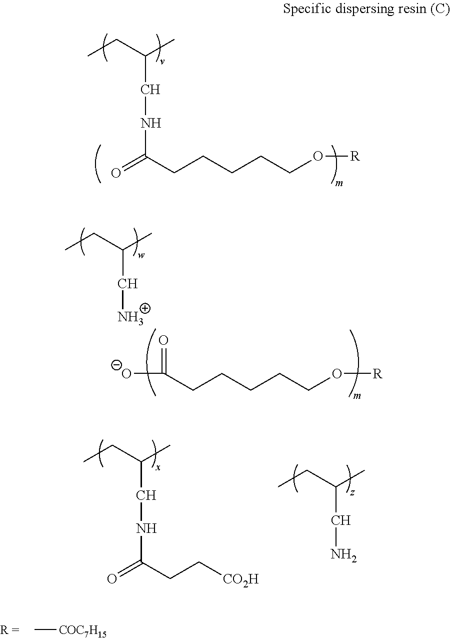

In specific dispersing resin (C), v:w:x:z is 40:5:25:30 (polymerization molar ratio), m is 60, and the weight-average molecular weight is 12,000.

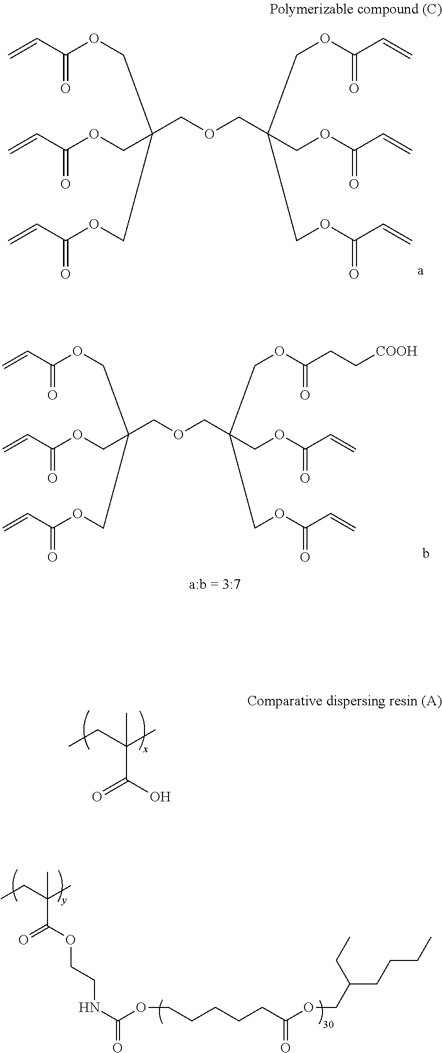

In comparative dispersing resin (A), x:y is 20:80 and the weight-average molecular weight is 20,500.

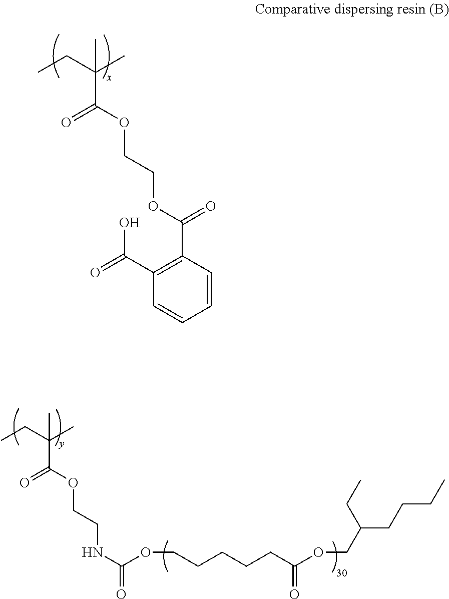

In comparative dispersing resin (B), x:y is 20:80 and the weight-average molecular weight is 26,000.

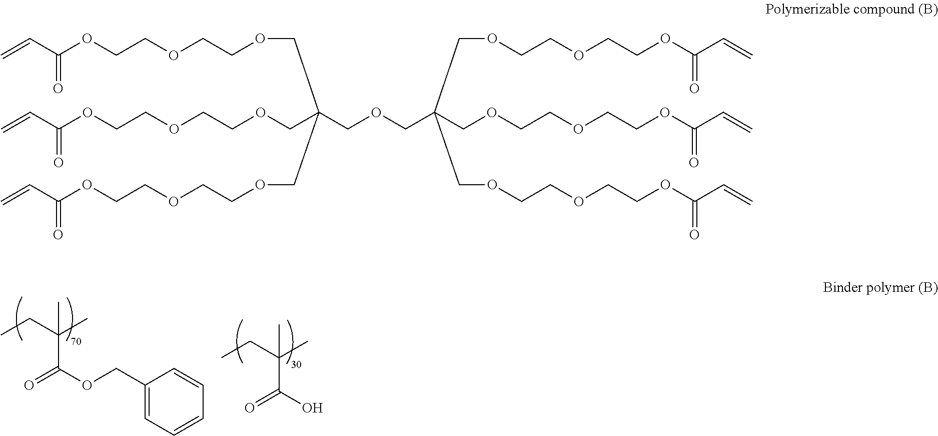

TABLE 1

| | Titanium | Radiation- | | | |
|---|---|---|---|---|---|
| | dioxide | sensitive | | | |
| | dispersion | composition | Composition | | |
| | No. | No. | Dispersant | Polymerizable compound | Binder polymer |
| Example 1 | 1-1 | 1 | Specific dispersing resin (A) | Polymerizable compound (A) | Binder polymer (A) |
| Example 2 | 1-2 | 2 | Specific dispersing resin (A) | Polymerizable compound (A) | Binder polymer (B) |
| Example 3 | 1-3 | 3 | Specific dispersing resin (A) | Polymerizable compound (B) | Binder polymer (A) |
| Example 4 | 1-4 | 4 | Specific dispersing resin (A) | Polymerizable compound (B) | Binder polymer (B) |
| Example 5 | 1-5 | 5 | Specific dispersing resin (A) | Polymerizable compound (C) | Binder polymer (A) |
| Example 6 | 1-6 | 6 | Specific dispersing resin (A) | Polymerizable compound (C) | Binder polymer (B) |
| Example 7 | 1-7 | 7 | Specific dispersing resin (A) | DPHA | Binder polymer (A) |
| Example 8 | 1-8 | 8 | Specific dispersing resin (A) | DPHA | Binder polymer (B) |
| Example 9 | 1-9 | 9 | Specific dispersing resin (B) | Polymerizable compound (A) | Binder polymer (A) |
| Example 10 | 1-10 | 10 | Specific dispersing resin (B) | Polymerizable compound (A) | Binder polymer (B) |
| Example 11 | 1-11 | 11 | Specific dispersing resin (B) | Polymerizable compound (B) | Binder polymer (A) |
| Example 12 | 1-12 | 12 | Specific dispersing resin (B) | Polymerizable compound (B) | Binder polymer (B) |
| Example 13 | 1-13 | 13 | Specific dispersing resin (B) | Polymerizable compound (C) | Binder polymer (A) |
| Example 14 | 1-14 | 14 | Specific dispersing resin (B) | Polymerizable compound (C) | Binder polymer (B) |
| Example 15 | 1-15 | 15 | Specific dispersing resin (B) | DPHA | Binder polymer (A) |
| Example 16 | 1-16 | 16 | Specific dispersing resin (B) | DPHA | Binder polymer (B) |
| Example 17 | 1-17 | 17 | Specific dispersing resin (C) | Polymerizable compound (A) | Binder polymer (A) |
| Example 18 | 1-18 | 18 | Specific dispersing resin (C) | Polymerizable compound (A) | Binder polymer (B) |
| Example 19 | 1-19 | 19 | Specific dispersing resin (C) | Polymerizable compound (B) | Binder polymer (A) |
| Example 20 | 1-20 | 20 | Specific dispersing resin (C) | Polymerizable compound (B) | Binder polymer (B) |
| Example 21 | 1-21 | 21 | Specific dispersing resin (C) | Polymerizable compound (C) | Binder polymer (A) |
| Example 22 | 1-22 | 22 | Specific dispersing resin (C) | Polymerizable compound (C) | Binder polymer (B) |
| Example 23 | 1-23 | 23 | Specific dispersing resin (C) | DPHA | Binder polymer (A) |
| Example 24 | 1-24 | 24 | Specific dispersing resin (C) | DPHA | Binder polymer (B) |
| Example 25 | 2 | 25 | Specific dispersing resin (A) | Polymerizable compound (A) | Binder polymer (A) |
| Example 26 | 2 | 26 | Specific dispersing resin (A) | Polymerizable compound (A) | Binder polymer (A) |

| | Evaluation | | | | | | | |
|---|---|---|---|---|---|---|---|---|
| | | | | Storage stability | | Color migration | | |
| | | | | Rate of | | | | |
| | Spectral | Refraction | Pattern | increase in | | due to heat diffusion | | |
| | transmission | index | formation | impurities | Precipitation | Red | Green | Blue |
| Example 1 | 5 | 5 | 0.9 | 5 | 2 | 5 | 5 | 5 |
| Example 2 | 5 | 5 | 0.9 | 5 | 2 | 5 | 5 | 5 |
| Example 3 | 5 | 5 | 0.9 | 5 | 2 | 5 | 5 | 5 |
| Example 4 | 5 | 5 | 0.9 | 5 | 2 | 5 | 5 | 5 |
| Example 5 | 5 | 5 | 0.9 | 4 | 2 | 4 | 4 | 4 |
| Example 6 | 5 | 5 | 0.9 | 4 | 2 | 4 | 4 | 4 |
| Example 7 | 5 | 5 | 0.9 | 5 | 2 | 5 | 5 | 5 |
| Example 8 | 5 | 5 | 0.9 | 5 | 2 | 5 | 5 | 5 |
| Example 9 | 5 | 5 | 0.9 | 5 | 2 | 5 | 5 | 5 |
| Example 10 | 5 | 5 | 0.9 | 5 | 2 | 5 | 5 | 5 |
| Example 11 | 5 | 5 | 0.9 | 5 | 2 | 5 | 5 | 5 |
| Example 12 | 5 | 5 | 0.9 | 5 | 2 | 5 | 5 | 5 |
| Example 13 | 5 | 5 | 0.9 | 4 | 2 | 4 | 4 | 4 |
| Example 14 | 5 | 5 | 0.9 | 4 | 2 | 4 | 4 | 4 |
| Example 15 | 5 | 5 | 0.9 | 5 | 2 | 5 | 5 | 5 |
| Example 16 | 5 | 5 | 0.9 | 5 | 2 | 5 | 5 | 5 |
| Example 17 | 5 | 5 | 0.9 | 5 | 2 | 5 | 5 | 5 |
| Example 18 | 5 | 5 | 0.9 | 5 | 2 | 5 | 5 | 5 |
| Example 19 | 5 | 5 | 0.9 | 5 | 2 | 5 | 5 | 5 |
| Example 20 | 5 | 5 | 0.9 | 5 | 2 | 5 | 5 | 5 |
| Example 21 | 5 | 5 | 0.9 | 4 | 2 | 4 | 4 | 4 |
| Example 22 | 5 | 5 | 0.9 | 4 | 2 | 4 | 4 | 4 |
| Example 23 | 5 | 5 | 0.9 | 5 | 2 | 5 | 5 | 5 |
| Example 24 | 5 | 5 | 0.9 | 5 | 2 | 5 | 5 | 5 |
| Example 25 | 5 | 5 | 0.9 | 5 | 3 | 5 | 5 | 5 |
| Example 26 | 5 | 5 | 0.9 | 5 | 3 | 5 | 5 | 5 |

TABLE 2

| | Titanium | Radiation- | | | |
|---|---|---|---|---|---|
| | dioxide | sensitive | | | |
| | dispersion | composition | Composition | | |
| | No. | No. | Dispersant | Polymerizable compound | Binder polymer |
| Comparative Example 1 | C1 | 1C | Specific dispersing resin (A) | Polymerizable compound (A) | Binder polymer (A) |
| Comparative Example 2 | C2 | 2C | Specific dispersing resin (A) | Polymerizable compound (A) | Binder polymer (B) |
| Comparative Example 3 | C3 | 3C | Specific dispersing resin (A) | Polymerizable compound (B) | Binder polymer (A) |
| Comparative Example 4 | C4 | 4C | Specific dispersing resin (A) | Polymerizable compound (B) | Binder polymer (B) |
| Comparative Example 5 | C5 | 5C | Specific dispersing resin (A) | Polymerizable compound (C) | Binder polymer (A) |
| Comparative Example 6 | C6 | 6C | Specific dispersing resin (A) | Polymerizable compound (C) | Binder polymer (B) |
| Comparative Example 7 | C7 | 7C | Specific dispersing resin (A) | DPHA | Binder polymer (A) |
| Comparative Example 8 | C8 | 8C | Specific dispersing resin (A) | DPHA | Binder polymer (B) |
| Comparative Example 9 | C9 | 9C | Specific dispersing resin (B) | Polymerizable compound (A) | Binder polymer (A) |
| Comparative Example 10 | C10 | 10C | Specific dispersing resin (B) | Polymerizable compound (A) | Binder polymer (B) |
| Comparative Example 11 | C11 | 11C | Specific dispersing resin (B) | Polymerizable compound (B) | Binder polymer (A) |
| Comparative Example 12 | C12 | 12C | Specific dispersing resin (B) | Polymerizable compound (B) | Binder polymer (B) |
| Comparative Example 13 | C13 | 13C | Specific dispersing resin (B) | Polymerizable compound (C) | Binder polymer (A) |
| Comparative Example 14 | C14 | 14C | Specific dispersing resin (B) | Polymerizable compound (C) | Binder polymer (B) |
| Comparative Example 15 | C15 | 15C | Specific dispersing resin (B) | DPHA | Binder polymer (A) |
| Comparative Example 16 | C16 | 16C | Specific dispersing resin (B) | DPHA | Binder polymer (B) |
| Comparative Example 17 | C17 | 17C | DISPERBYK 101 | Polymerizable compound (A) | Binder polymer (A) |
| Comparative Example 18 | C18 | 18C | DISPERBYK 101 | Polymerizable compound (A) | Binder polymer (B) |
| Comparative Example 19 | C19 | 19C | DISPERBYK 101 | Polymerizable compound (B) | Binder polymer (A) |
| Comparative Example 20 | C20 | 20C | DISPERBYK 101 | Polymerizable compound (B) | Binder polymer (B) |
| Comparative Example 21 | C21 | 21C | DISPERBYK 101 | Polymerizable compound (C) | Binder polymer (A) |
| Comparative Example 22 | C22 | 22C | DISPERBYK 101 | Polymerizable compound (C) | Binder polymer (B) |
| Comparative Example 23 | C23 | 23C | DISPERBYK 101 | DPHA | Binder polymer (A) |
| Comparative Example 24 | C24 | 24C | DISPERBYK 101 | DPHA | Binder polymer (B) |
| Comparative Example 25 | C25 | 25C | SOLSPERSE-5000 | Polymerizable compound (A) | Binder polymer (A) |
| Comparative Example 26 | C26 | 26C | SOLSPERSE-5000 | Polymerizable compound (A) | Binder polymer (B) |
| Comparative Example 27 | C27 | 27C | SOLSPERSE-5000 | Polymerizable compound (B) | Binder polymer (A) |
| Comparative Example 28 | C28 | 28C | SOLSPERSE-5000 | Polymerizable compound (B) | Binder polymer (B) |
| Comparative Example 29 | C29 | 29C | SOLSPERSE-5000 | Polymerizable compound (C) | Binder polymer (A) |
| Comparative Example 30 | C30 | 30C | SOLSPERSE-5000 | Polymerizable compound (C) | Binder polymer (B) |
| Comparative Example 31 | C31 | 31C | SOLSPERSE-5000 | DPHA | Binder polymer (A) |
| Comparative Example 32 | C32 | 32C | SOLSPERSE-5000 | DPHA | Binder polymer (B) |

| | Evaluation | | | | | | | |
|---|---|---|---|---|---|---|---|---|
| | | | | Storage stability | | Color migration | | |
| | Spectral | Refraction | Pattern | Rate of increase | | due to heat diffusion | | |
| | transmission | index | formation | in impurities | Precipitation | Red | Green | Blue |
| Comparative Example 1 | 4 | 4 | 0.9 | 2 | 2 | 2 | 2 | 2 |
| Comparative Example 2 | 4 | 4 | 0.9 | 2 | 2 | 2 | 2 | 2 |
| Comparative Example 3 | 4 | 4 | 0.9 | 2 | 2 | 2 | 2 | 2 |
| Comparative Example 4 | 4 | 4 | 0.9 | 2 | 2 | 2 | 2 | 2 |
| Comparative Example 5 | 4 | 4 | 0.9 | 2 | 2 | 2 | 2 | 2 |
| Comparative Example 6 | 4 | 4 | 0.9 | 2 | 2 | 2 | 2 | 2 |
| Comparative Example 7 | 4 | 4 | 0.9 | 2 | 2 | 2 | 2 | 2 |
| Comparative Example 8 | 4 | 4 | 0.9 | 2 | 2 | 2 | 2 | 2 |
| Comparative Example 9 | 4 | 4 | 0.9 | 3 | 2 | 3 | 3 | 3 |
| Comparative Example 10 | 4 | 4 | 0.9 | 3 | 2 | 3 | 3 | 3 |
| Comparative Example 11 | 4 | 4 | 0.9 | 3 | 2 | 3 | 3 | 3 |
| Comparative Example 12 | 4 | 4 | 0.9 | 3 | 2 | 3 | 3 | 3 |
| Comparative Example 13 | 4 | 4 | 0.9 | 3 | 2 | 3 | 3 | 3 |
| Comparative Example 14 | 4 | 4 | 0.9 | 3 | 2 | 3 | 3 | 3 |
| Comparative Example 15 | 4 | 4 | 0.9 | 3 | 2 | 3 | 3 | 3 |
| Comparative Example 16 | 4 | 4 | 0.9 | 3 | 2 | 3 | 3 | 3 |
| Comparative Example 17 | 3 | 2 | x | 1 | 1 | 1 | 1 | 1 |
| Comparative Example 18 | 3 | 2 | x | 1 | 1 | 1 | 1 | 1 |
| Comparative Example 19 | 3 | 2 | x | 1 | 1 | 1 | 1 | 1 |
| Comparative Example 20 | 3 | 2 | x | 1 | 1 | 1 | 1 | 1 |
| Comparative Example 21 | 3 | 2 | x | 1 | 1 | 1 | 1 | 1 |
| Comparative Example 22 | 3 | 2 | x | 1 | 1 | 1 | 1 | 1 |
| Comparative Example 23 | 3 | 2 | x | 1 | 1 | 1 | 1 | 1 |
| Comparative Example 24 | 3 | 2 | x | 1 | 1 | 1 | 1 | 1 |
| Comparative Example 25 | 3 | 2 | x | 1 | 1 | 1 | 1 | 1 |
| Comparative Example 26 | 3 | 2 | x | 1 | 1 | 1 | 1 | 1 |
| Comparative Example 27 | 3 | 2 | x | 1 | 1 | 1 | 1 | 1 |
| Comparative Example 28 | 3 | 2 | x | 1 | 1 | 1 | 1 | 1 |
| Comparative Example 29 | 3 | 2 | x | 1 | 1 | 1 | 1 | 1 |
| Comparative Example 30 | 3 | 2 | x | 1 | 1 | 1 | 1 | 1 |
| Comparative Example 31 | 3 | 2 | x | 1 | 1 | 1 | 1 | 1 |
| Comparative Example 32 | 3 | 2 | x | 1 | 1 | 1 | 1 | 1 |

Evaluation

The following evaluations were carried out with the radiation-sensitive compositions obtained in the Examples and the Comparative Examples.

<Spectral Transmission>

The radiation-sensitive composition was applied onto a glass wafer by spin coating to have a thickness of 0.6 μm after coating, and the coating was heated on a hot plate at 100° C. for 2 minutes. The coating was further heated on a hot plate at 200° C. for 8 minutes, thereby forming a radiation-sensitive composition layer.

The spectral transmission of the glass wafer on which the radiation-sensitive composition layer was formed was measured with a spectrometer (MCPD-2000, trade name, manufactured by Otsuka Electronics Co., Ltd.), and evaluated in accordance with the following evaluation criteria. The results are shown in Tables 1 and 2.

Evaluation Criteria

5: 500-nm spectral transmission is not less than 99%

4: 500-nm spectral transmission is from 95% to less than 99%

3: 500-nm spectral transmission is from 90% to less than 95%

2: 500-nm spectral transmission is from 85% to less than 90%

1: 500-nm spectral transmission is less than 85%

<Refraction Index>

The radiation-sensitive composition was applied onto a glass wafer by spin coating to have a thickness of 0.6 μm after coating, and the coating was heated on a hot plate at 100° C. for 2 minutes. The coating was further heated on a hot plate at 200° C. for 8 minutes, thereby forming a radiation-sensitive composition layer.

The refraction index of the glass wafer on which the radiation-sensitive composition layer was formed was measured with an ellipsometer (VUV-VASE, trade name, manufactured by J. A. Woollam Co., Inc.) in accordance with the following evaluation criteria. The results are shown in Tables 1 and 2.

Evaluation Criteria

5: 500-nm refraction index is not less than 1.70

4: 500-nm refraction index is from 1.67 to less than 1.70

3: 500-nm refraction index is from 1.64 to less than 1.67

2: 500-nm refraction index is from 1.60 to less than 1.64

1: 500-nm refraction index is less than 1.60

<Pattern Formation>

The radiation-sensitive composition was applied on a silicon wafer having a primer layer by spin coating to have a thickness of 0.6 μm after coating. The coating was heated on a hot plate at 100° C. for 2 minutes, thereby forming a radiation-sensitive composition layer.

Subsequently, the radiation-sensitive composition layer was exposed to light via a mask to form a dot array pattern or a Bayer pattern of five different sizes from 0.9 μm×0.9 μm to 3.0 μm×3.0 μm, respectively, with an i-line stepper (FPA-3000i5+, trade name, manufactured by Canon Inc.

After the exposure, the radiation-sensitive composition layer was subjected to paddle development at 23° C. for 60 seconds with a 0.3% aqueous solution of tetramethyl ammonium hydroxide (TMAH). The radiation-sensitive composition layer was then rinsed with spin shower and washed with pure water, thereby obtaining a transparent pattern.

The shape of the transparent pattern was examined with a critical dimension scanning electron microscope (S-7800H, trade name, manufactured by Hitachi, Ltd.) at a magnification of 30,000.

The size of the pattern that could be resolved (μm) is shown in Tables 1 and 2.

In Tables 1 and 2, “x” indicates that a pattern having a size of from 0.9 μm×0.9 μm to 3.0×3.0 μm was not formed.

<Storage Stability 1 (Rate of Increase in Impurities)>

The radiation-sensitive composition was applied on a silicon wafer having a primer layer by spin coating to have a thickness of 0.6 μm after coating. The coating was heated on a hot plate at 100° C. for 2 minutes, thereby forming a radiation-sensitive composition layer.

The number of impurities having a size of 1.0 μm or more found in the radiation-sensitive composition layer formed on the silicon substrate was counted with a defect inspector (ComPLUS, trade name, manufactured by Applied Materials, Inc.) The impurities evaluated in the evaluation are derived from aggregation of titanium dioxide particles.

The evaluation was carried out immediately after the preparation of the radiation-sensitive composition, and after storing the radiation-sensitive composition at approximately 4° C. for three months, and the rate of increase in impurities was evaluated in accordance with the following evaluation criteria.

The rate of increase in impurities was calculated as (number of impurities after 3-month storage/number of impurities immediately after preparation). Grade 3 or higher in accordance with the following criteria is desirable for practical use. The results are shown in Tables 1 and 2.

Evaluation Criteria

5: rate of increase in impurities is less than 1.1

4: rate of increase in impurities is from 1.1 to less than 1.3

3: rate of increase in impurities is from 1.3 to less than 1.5

2: rate of increase in impurities is from 1.5 to less than 3.0

1: rate of increase in impurities is not less than 3.0

<Storage Stability 2 (Precipitation)>

After storing the radiation-sensitive composition at approximately 4° C. for six months, occurrence of precipitation was evaluated by visual observation in accordance with the following evaluation criteria. The precipitation evaluated in the evaluation is formed from the components in the radiation-sensitive composition as a result of being stored at low temperature. Grade 2 or higher in accordance with the following criteria is desirable for practical use. The results are shown in Tables 1 and 2.

Evaluation Criteria

3: precipitation is not observed

2: a slight degree of precipitation is observed

1: precipitation is observed

<Color Migration Due to Heat Diffusion>

The radiation-sensitive composition was applied onto a glass wafer having a primer layer (method of producing the glass wafer is described later) with a spin coater to have a thickness of 0.6 μm after coating. The coating was heated on a hot plate at 100° C. for 120 seconds (pre-baking).

Subsequently, the radiation-sensitive composition layer was exposed to light via a mask having a Bayer pattern of 3.0 μm×3.0 μm at a wavelength of 365 nm while adjusting the exposure amount such that the pattern size was 3.0 μm×3.0 μm, with an i-line stepper (FPA-3000i5+, trade name, manufactured by Canon Inc.)

After the exposure, the glass wafer on which the radiation-sensitive composition layer was formed was subjected to paddle development at 23° C. for 60 seconds with a 0.3% TMAH aqueous solution. The radiation-sensitive composition layer was then rinsed with spin shower and washed with pure water, thereby obtaining a transparent pattern.

The transparent pattern was further heated on a hot plate at 200° C. for 480 seconds (post-baking), and a monocolor filter having transparent pixels on which a Bayer pattern was formed was obtained.

Subsequently, a red radiation-sensitive composition was applied onto the monocolor filter having transparent pixels obtained above with a spin coater to have a thickness of 0.6 μm after coating, and the resultant was heated on a hot plate at 100° C. for 120 seconds (pre-baking).

Then, the red radiation-sensitive composition layer was exposed to light via a mask having an island pattern of 3.0 μm×3.0 μm at a wavelength of 365 nm with an i-line stepper (FPA-3000i5+, trade name, manufactured by Canon Inc.), and red pixels were produced adjacent to the transparent pixels.

The glass wafer on which the red pixels (colored layer) was formed was subjected to development, rinsing, drying and post-baking, in a manner substantially similar to the formation of the transparent pixels, thereby obtaining a bicolored color filter having transparent pixels and red pixels.

The spectral transmission at a transparent pixel portion of the bicolored color was measured with a micro spectrophotometer (LV MICRO-V, trade name, manufactured by Lambda Vision Inc.) The result was defined as an initial spectral transmission.

Then, the bicolored color filter was heated on a hot plate at 200° C. for 60 minutes, and the spectral transmission of the bicolored color was measured with a micro spectrophotometer (LV MICRO-V, trade name, manufactured by Lambda Vision Inc.) The result was defined as a spectral transmission after treatment.

Color migration due to heat diffusion to the transparent pixels from the adjacent red pixels was evaluated in terms of a difference in absorption intensity at from 400 nm to 700 nm between the initial spectral transmission and the spectral transmission after treatment. The smaller the difference is, the less the heat diffusion tends to occur. The evaluation criteria are as follows. Grade 3 or higher is desirable for practical use. The results are shown in Tables 1 and 2.

5: difference in absorption intensity is less than 0.01.

4: difference in absorption intensity is from 0.01 to less than 0.02.

3: difference in absorption intensity is from 0.02 to less than 0.04.

2: difference in absorption intensity is from 0.04 to less than 0.08.

1: difference in absorption intensity is not less than 0.08.

Further, color migration due to heat diffusion was evaluated in a manner substantially similar to the above, except that the red radiation-sensitive composition used for pixels of the second color was changed to a green radiation-sensitive composition or a blue radiation-sensitive composition. The results are shown in Tables 1 and 2.

As shown in Tables 1 and 2, the radiation-sensitive compositions of the Examples exhibit favorable results as compared with the radiation-sensitive composition of the Comparative Examples, in terms of spectral transmission, refraction index, storage stability (rate of increase in impurities or precipitation) and color migration due to heat diffusion. The radiation-sensitive compositions 25 and 26 of Examples 25 and 26 do not form precipitation even after six months of storage at low temperature, which indicates that storage stability is especially favorable.

The following are details of the glass wafer having a primer layer, the silicon wafer having a primer layer, the red radiation-sensitive composition, the green radiation-sensitive composition and the blue radiation-sensitive composition that were used in the evaluation.

<Glass Wafer Having Primer Layer>

The glass wafer having a primer layer used in the evaluation was prepared in accordance with the following process.

(1) Preparation of composition for primer layer

| | |
|---|---|
| Propylene glycol monomethyl ether acetate (PGMEA) | 19.20 parts |
| Ethyl lactate | 36.67 parts |
| Binder (benzyl methacrylate/methacrylic acid/2- | 30.51 parts |
| hydroxyethyl methacrylate) copolymer (molar ratio = | |
| 60:20:20), 41% EL solution | |
| DPHA (dipentaerythritol hexaacrylate, KAYARAD DPHA, | 12.20 parts |
| trade name, manufactured by Nippon Kayaku Co., Ltd.) | |
| Polymerization inhibitor (p-methoxyphenol) | 0.006 parts |
| Surfactant (MEGAFAC F-781, trade name, manufactured | 0.83 parts |
| by DIC Corporation, 1.0% PGMEA solution) | |
| Photopolymerization initiator (TAZ-107, trade name, | 0.59 parts |
| manufactured by Midori Kagaku Co., Ltd.) | |

(2) Preparation of Glass Wafer Having Primer Layer

The composition for a primer layer obtained above was uniformly applied onto a 8-inch glass wafer by spin coating, and the coating was heated on a hot plate at 120° C. for 120 seconds. The number of rotation for spin coating was adjusted such that the thickness of the coating after the heating was approximately 0.5 μm. The glass wafer having a primer layer was thus obtained.

<Silicon Wafer Having Primer Layer>

The silicon wafer having a primer layer used in the evaluation was prepared in accordance with the following process.

The composition for a primer layer obtained above was uniformly applied onto a 8-inch silicon wafer by spin coating, and the coating was heated on a hot plate at 120° C. for 120 seconds. The number of rotation for spin coating was adjusted such that the thickness of the coating after the heating was approximately 0.5 μm.

The coating was further heated in an oven at 220° C. for 1 hour to cure the coating layer, thereby forming a primer layer. The silicon wafer having a primer layer was thus obtained.

<Colored Radiation-Sensitive Composition>

The red radiation-sensitive composition, the green radiation-sensitive composition and the blue radiation-sensitive composition, used for the evaluation of color migration due to heat diffusion, were prepared in accordance with the following process.

(1) Preparation of Pigment Dispersion

Red pigment dispersion: dispersion including PR254 and PY139

A mixture of Pigment Red 254 (9.6 parts), Pigment Yellow 139 (4.3 parts), a pigment dispersant (BYK-161, trade name, manufactured by BYK Japan K.K.) (6.8 parts) and PGMEA (79.3 parts) was mixed and dispersed with a bead mill (with zirconia beads having 0.3 mm in diameter) for 3 hours, thereby obtaining a pigment dispersion. The pigment dispersion was further dispersed with a high-pressure dispersing machine equipped with a pressure-reducing system (NANO-3000-10, trade name, manufactured by Beryu Col., Ltd.) at a pressure of 2000 kg/cm³ and a flow rate of 500 g/min. The dispersion treatment was carried out 10 times, whereby the red radiation-sensitive composition was obtained.

Green Pigment Dispersion: Dispersion Including PG36 and PY150

A mixture of Pigment Green 36 (6.4 parts), Pigment Yellow 150 (5.3 parts), a pigment dispersant (BYK-161, trade name, manufactured by BYK Japan K.K.) (5.2 parts) and PGMEA (83.1 parts) was mixed and dispersed with a bead mill (with zirconia beads having 0.3 mm in diameter) for 3 hours, thereby obtaining a pigment dispersion. The pigment dispersion was further dispersed with a high-pressure dispersing machine equipped with a pressure-reducing system (NANO-3000-10, trade name, manufactured by Beryu Col., Ltd.) at a pressure of 2000 kg/cm³ and a flow rate of 500 g/min. The dispersion treatment was carried out 10 times, whereby the green radiation-sensitive composition was obtained.

Blue Pigment Dispersion: Dispersion Including PB15:6 and PV23

A mixture of Pigment Blue 15:6 (9.7 parts), Pigment Violet 23 (2.4 parts), a pigment dispersant (BYK-161, trade name, manufactured by BYK Japan K.K.) (5.5 parts) and PGMEA (82.4 parts) was mixed and dispersed with a bead mill (with zirconia beads having 0.3 mm in diameter) for 3 hours, thereby obtaining a pigment dispersion. The pigment dispersion was further dispersed with a high-pressure dispersing machine equipped with a pressure-reducing system (NANO-3000-10, trade name, manufactured by Beryu Col., Ltd.) at a pressure of 2000 kg/cm³ and a flow rate of 500 g/min. The dispersion treatment was carried out 10 times, whereby the blue radiation-sensitive composition was obtained.

(2) Preparation of Colored Radiation-Sensitive Composition

(Preparation of Red Radiation-Sensitive Composition)

The red radiation-sensitive composition was prepared by mixing the following components.

<Composition>

| | | |
|---|---|---|
| Red pigment dispersion | 50.9 | parts |
| Binder polymer (C) (following structure, 40% | 8.6 | parts |
| PGMEA solution) | | |
| Polymerizable compound (B) | 0.6 | parts |
| Photopolymerization initiator (following structure, | 0.3 | parts |
| IRGACURE OXE-01, trade name, manufactured by BASF) | | |
| Surfactant (MEGAFAC F-781, trade name, | 4.2 | parts |
| manufactured by DIC Corporation, 1.0% PGMEA solution) | | |
| PGMEA | 43.2 | parts |

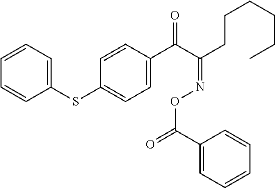 [SMILES: CCCCCC/C(=N/OC(=O)c1ccccc1)C(=O)c1ccc(Sc2ccccc2)cc1]

IRGACURE OXE-01 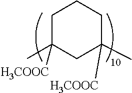 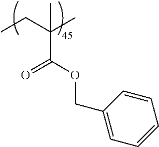 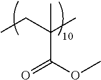 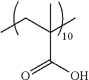 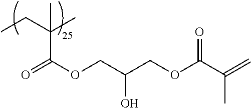
Binder polymer (C) (acid value: 70 mg/KOH, Mw = 11,000)

Preparation of Green Radiation-Sensitive Composition

The green radiation-sensitive composition was prepared by mixing the following components.

<Composition>

| | |
|---|---|
| Green pigment dispersion | 74.4 parts |
| Binder polymer (C) (40% PGMEA solution) | 0.5 parts |
| DPHA (KAYARAD DPHA, trade name, manufactured | 1.2 parts |
| by Nippon Kayaku Co., Ltd.) | |
| Photopolymerization initiator (IRGACURE OXE-01, trade | 0.5 parts |
| name, manufactured by BASF) | |
| Surfactant (MEGAFAC F-781, trade name, manufactured | 4.2 parts |
| by DIC Corporation, 1.0% PGMEA solution) | |
| Ultraviolet absorber (A) | 0.5 parts |
| PGMEA | 18.7 parts |

(Preparation of Blue Radiation-Sensitive Composition)

The blue radiation-sensitive composition was prepared by mixing the following components.

<Composition>

| | |
|---|---|
| Blue pigment dispersion | 45.6 parts |
| Binder polymer (C) (40% PGMEA solution) | 1.5 parts |
| DPHA (KAYARAD DPHA, trade name, manufactured | 1.5 parts |
| by Nippon Kayaku Co., Ltd.) | |
| Polymerizable compound (B) (above structure) | 0.6 parts |
| Photopolymerization initiator (IRGACURE OXE-01, trade | 1.0 part |
| name, manufactured by BASF) | |
| Surfactant (MEGAFAC F-781, trade name, manufactured | 4.2 parts |
| by DIC Corporation, 1.0% PGMEA solution) | |
| PGMEA | 45.5 parts |

### Example 27

A solid-state image sensor was prepared in accordance with the following process.

<Preparation of Device-Formed Silicon Wafer with Primer Layer>

A device-formed silicon wafer with a primer layer was prepared by forming a coating in accordance with the process as described above on a silicon wafer on which a device had been formed by a known method.

<Preparation and Evaluation of Solid-State Image Sensor>

The radiation-sensitive composition 7 used in Example 7 was applied onto a device-formed silicon wafer with a primer layer by spin coating to have a thickness of 0.6 μm. The coating was heated on a hot plate at 100° C. for 2 minutes, thereby forming a radiation-sensitive composition layer.

Subsequently, the radiation-sensitive composition layer was exposed to light via a mask to form a dot array pattern having the size of 1.0 μm with an i-line stepper (FPA-3000i5+, trade name, manufactured by Canon Inc.)

After the exposure, the radiation-sensitive composition layer was subjected to paddle development at 23° C. for 60 seconds with a 0.3% aqueous solution of tetramethyl ammonium hydroxide (TMAH). The radiation-sensitive composition layer was then rinsed with spin shower and washed with pure water, thereby obtaining a white (transparent) pattern.

Then, a green pattern was formed on the silicon wafer on which the white pattern was formed in a similar manner to the formation of the white pattern, except that the green radiation-sensitive composition was used.

Then, a red pattern was formed on the silicon wafer on which the white pattern and the green pattern were formed in a similar manner to the formation of the white pattern, except that the red radiation-sensitive composition was used.

Then, a blue pattern was formed on the silicon wafer on which the white pattern, the green pattern and the red pattern were formed in a similar manner to the formation of the white pattern, except that the blue radiation-sensitive composition was used.

A color filter for a solid-state image sensor having a white pattern, a green pattern, a red pattern and a blue pattern was thus obtained.

A solid-state image sensor including the color filter for a solid-state image sensor was obtained in accordance with a known method.

An image was taken with the obtained solid-state image sensor. It was confirmed that the image was favorable.

All publications, patent applications, and technical standards mentioned in this specification are herein incorporated by reference to the same extent as if each individual publication, patent application, or technical standard was specifically and individually indicated to be incorporated by reference. This application claims priority under 35 USC 119 from Japanese Patent Application No. 2011-189550 filed Aug. 31, 2011 and Japanese Patent Application No. 2012-114292, filed May 18, 2012, the disclosure of which is incorporated by reference herein.

What is claimed is:

1. A radiation-sensitive composition for forming pixels for a solid-state image sensor, the radiation-sensitive composition comprising:
titanium dioxide particles;
an oligoimine dispersant including a nitrogen atom in at least one of a main chain or a side chain;
a polymerizable compound;
a photopolymerization initiator; and
an organic solvent.

2. The radiation-sensitive composition according to claim 1, wherein the oligoimine dispersant is a dispersing resin that comprises:
a repeating unit having a substructure X that has a functional group with a pKa of 14 or less;
a side chain comprising an oligomer chain or polymer chain Y that includes from 40 atoms to 10,000 atoms; and
a basic nitrogen atom in at least one of a main chain or a side chain of the dispersing resin.

3. The radiation-sensitive composition according to claim 1, wherein the oligoimine dispersant is a dispersing resin that comprises:
a repeating unit that has a basic nitrogen atom that is bound to a substructure X that has a functional group with a pKa of 14 or less; and
a side chain comprising an oligomer chain or polymer chain Y that includes from 40 atoms to 10,000 atoms.

4. The radiation-sensitive composition according to claim 1, wherein the oligoimine dispersant is a dispersing resin that comprises:
(i) a repeating unit having a basic nitrogen atom that is at least one selected from the group consisting of a poly(lower alkyleneimine) repeating unit, a polyallylamine repeating unit, a polydiallylamine repeating unit, a metaxylenediamine-epichlorohydrin polycondensate repeating unit and a polyvinylamine repeating unit, wherein the basic nitrogen atom is bound to a substructure X that has a functional group with a pKa of 14 or less; and
(ii) a side chain comprising an oligomer chain or polymer chain Y that includes from 40 atoms to 10,000 atoms.

5. The radiation-sensitive composition according to claim 4, wherein the oligoimine dispersant is a dispersing resin that comprises:
a repeating unit represented by following Formula (I-1) and a repeating unit represented by following Formula (I-2); or
a repeating unit represented by following Formula (II-1) and a repeating unit represented by following Formula (II-2): 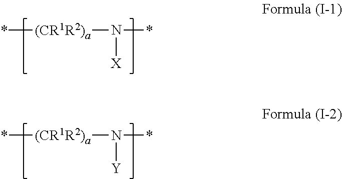
wherein, in Formula (I-1) and Formula (I-2), each of R¹ and R² independently represents a hydrogen atom, a halogen atom or an alkyl group; each “a” independently represents an integer from 1 to 5; * represents a linking moiety between repeating units; X represents a group that has a functional group with a pKa of 14 or less; and Y represents an oligomer chain or polymer chain that includes from 40 atoms to 10,000 atoms: 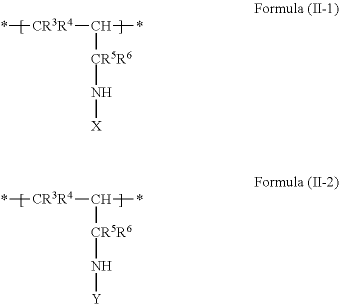
wherein, in Formula (II-1) and Formula (II-2), each of R³, R⁴, R⁵ and R⁶ independently represents a hydrogen atom, a halogen atom or an alkyl group; * represents a linking moiety between repeating units; X represents a group that has a functional group with a pKa of 14 or less; and Y represents an oligomer chain or polymer chain that includes from 40 atoms to 10,000 atoms.

6. The radiation-sensitive composition according to claim 1, wherein the polymerizable compound is a polymerizable compound having at least two terminal ethylenically unsaturated bonds.

7. The radiation-sensitive composition according to claim 1, wherein the photopolymerization initiator comprises an oxime compound.

8. The radiation-sensitive composition according to claim 1, used for forming pixels of a color filter for a solid-state image sensor.

9. A color filter obtained by using the radiation-sensitive composition according to claim 1.

10. A method of forming a pattern, the method comprising:
forming a coating layer by applying the radiation-sensitive composition according to claim 1 onto a substrate;
exposing the coating layer to light; and
forming a pattern by developing the coating layer that has been exposed, thereby obtaining a cured film having a patterned shape.

11. A method of producing a color filter, the method comprising forming, on a substrate, a cured film having a patterned shape by the method of forming a pattern according to claim 10.

12. A color filter produced by the method of producing a color filter according to claim 11.

13. A solid-state image sensor comprising the color filter according to claim 9.

14. A solid-state image sensor comprising the color filter according to claim 12.
